(19) United States
(12) Patent Application Publication
(10) Pub. No.: US 2026/0344211 A1
(43) Pub. Date: Oct. 29, 2026

(54) DISPLAY PANEL AND DISPLAY DEVICE

(71) Applicants: Chongqing BOE Display Technology Co.,Ltd., Chongqing (CN); BOE Technology Group Co., Ltd., Beijing (CN)

(72) Inventors: Rui WANG, Beijing (CN); Zhi HUANG, Beijing (CN); Ming HU, Beijing (CN); Haijun QIU, Beijing (CN); Jian GUO, Beijing (CN); Chao ZENG; Xueguang HAO; Lang LIU

(21) Appl. No.: 19/116,150

(22) PCT Filed: Nov. 20, 2023
(86) PCT No.: PCT/CN2023/132632

§ 371 Date: Mar. 27, 2025

(51) Int. Cl. H10K 59/131; G09G 3/3233; H10K 59/121

(52) U.S. Cl. CPC H10K 59/131; G09G 3/3233; H10K 59/1213; G09G 2300/0426; G09G 2300/0819; G09G 2300/0842; G09G 2300/0861; G09G 2310/08

(57) ABSTRACT

A display panel includes: a base substrate, at least one pixel driving circuit row group, and light-emitting units. Orthographic projections of two pixel driving circuit rows which are adjacent in a same pixel driving circuit row group on the base substrate are at least partially arranged in mirror symmetry with respect to a first symmetry axis, the first symmetry axis extends along the row direction, and the two pixel driving circuit rows which are adjacent in the same pixel driving circuit row group share a same second initialization signal line.

### TECHNICAL FIELD

The present disclosure relates to the display technical field, and in particular to a display panel and a display device.

### BACKGROUND

In a display panel with a high pixel density, a large number of pixel driving circuits need to be integrated in a limited space. Accordingly, the wiring density in the display panel is high and there are a large number of via holes. This arrangement leads to problem(s) such as high difficulty in manufacturing the display panel and low manufacturing yield.

It should be noted that the information disclosed in the background section is only used to enhance the understanding of the background of the present disclosure, and therefore may include information that does not constitute prior art known to those of ordinary skill in this art.

### SUMMARY

According to an aspect of the present disclosure, there is provided a display panel, including:
a base substrate;
a pixel driving circuit row group, wherein the pixel driving circuit row group includes two pixel driving circuit rows which are adjacent in a column direction, and the pixel driving circuit row includes a plurality of pixel driving circuits distributed in a row direction;
light-emitting units, wherein the pixel driving circuits are used to drive the light-emitting units, the pixel driving circuit includes a seventh transistor, a first electrode of the seventh transistor is connected to a second initialization signal line, a second electrode of the seventh transistor is connected to a first electrode of the light-emitting unit, a gate of the seventh transistor is formed by a partial structure of a second reset signal line, and an orthographic projection of the second reset signal line on the base substrate extends along the row direction;
wherein orthographic projections of two pixel driving circuit rows which are adjacent in a same pixel driving circuit row group on the base substrate are at least partially arranged in mirror symmetry with respect to a first symmetry axis, the first symmetry axis extends along the row direction, and the two pixel driving circuit rows which are adjacent in the same pixel driving circuit row group share a same second initialization signal line.

In an example embodiment of the present disclosure, the second initialization signal line forms the first symmetry axis, and the orthographic projections of the two pixel driving circuit rows which are adjacent in the same pixel driving circuit row group on the base substrate are at least partially arranged in mirror symmetry with respect to the second initialization signal line.

In an example embodiment of the present disclosure, the pixel driving circuit further includes a driving transistor and a fifth transistor, a first electrode of the fifth transistor is connected to a first power supply line, and a second electrode of the fifth transistor is connected to a first electrode of the driving transistor;
wherein the display panel further includes:
a first conductive portion, wherein the first conductive portion is used to form a gate of the driving transistor;
an enable signal line, wherein an orthographic projection of the enable signal line on the base substrate extends along the row direction, and a partial structure of the enable signal line is used to form a gate of the fifth transistor;
wherein in a same pixel driving circuit, an orthographic projection of the second reset signal line on the base substrate is located at a side of the orthographic projection of the enable signal line on the base substrate away from an orthographic projection of the first conductive portion on the base substrate;
wherein the orthographic projection of the second initialization signal line on the base substrate is at least partially located between two adjacent second reset signal lines in a same pixel driving circuit row group.

In an example embodiment of the present disclosure, the second initialization signal line includes:
a first main body portion, wherein an orthographic projection of the first main body portion on the base substrate extends along the row direction;
a first protrusion; and
a second protrusion, wherein the first protrusion and the second protrusion are connected to two sides of the first main body portion in the column direction, respectively;
wherein in two pixel driving circuit rows which share a same second initialization signal line, the first main body portion is connected to the two pixel driving circuit rows through the first protrusion and the second protrusion, respectively.

In an example embodiment of the present disclosure, the pixel driving circuit further includes a driving transistor and a second transistor, a first electrode of the second transistor is connected to a gate of the driving transistor, and a second electrode of the second transistor is connected to a second electrode of the driving transistor;
wherein the display panel further includes:
a first active layer located at a side of the base substrate, wherein the first active layer includes a third active portion, and the third active portion is used to form a channel region of the driving transistor;
a first conductive layer located at a side of the first active layer away from the base substrate, wherein the first conductive layer includes a first conductive portion, an orthographic projection of the first conductive portion on the base substrate covers an orthographic projection of the third active portion on the base substrate, and the first conductive portion is used to form the gate of the driving transistor;
a second active layer located at a side of the first conductive layer away from the base substrate, wherein the second active layer includes a second active portion, and the second active portion is used to form a channel region of the second transistor;
a third conductive layer located at a side of the second active layer away from the base substrate, wherein the third conductive layer includes a first gate line, an orthographic projection of the first gate line on the base substrate extends along the row direction and covers an orthographic projection of the second active portion on the base substrate, and a partial structure of the first gate line is used to form a top gate of the second transistor;
wherein the third conductive layer further includes the second initialization signal line.

In an example embodiment of the present disclosure, the pixel driving circuit further includes a driving transistor and a first transistor, a first electrode of the first transistor is connected to a first initialization signal line, and a second electrode of the first transistor is connected to a second electrode of the driving transistor;
wherein the display panel includes a plurality of pixel driving circuit row groups, the plurality of pixel driving circuit row groups are distributed in the column direction, and two pixel driving circuit rows, which are located in different pixel driving circuit row groups and are adjacent, share a same first initialization signal line.

In an example embodiment of the present disclosure, the display panel further includes:
a first conductive portion, wherein the first conductive portion is used to form a gate of the driving transistor;
a first reset signal line, wherein an orthographic projection of the first reset signal line on the base substrate extends along the row direction, and a partial structure of the first reset signal line is used to form a gate of the first transistor;
wherein the orthographic projection of the first reset signal line on the base substrate is located at a side of an orthographic projection of the first conductive portion on the base substrate away from the orthographic projection of the second reset signal line on the base substrate;
wherein in two adjacent pixel driving circuit rows which share a same first initialization signal line, an orthographic projection of the first initialization signal line on the base substrate is at least partially located between orthographic projections of first reset signal lines in the two adjacent pixel driving circuit rows on the base substrate.

In an example embodiment of the present disclosure, the display panel further includes:
a first active layer located at a side of the base substrate, wherein the first active layer including a first active portion and a ninth active portion, the first active portion is used to form a channel region of the first transistor, and in the two adjacent pixel driving circuit rows which share the same first initialization signal line, the ninth active portion is connected between two first active portions in the two adjacent pixel driving circuit rows;
wherein the first initialization signal line is connected to the ninth active portion through a via hole.

In an example embodiment of the present disclosure, the pixel driving circuit further includes a second transistor, a first electrode of the second transistor is connected to a gate of the driving transistor, and a second electrode of the second transistor is connected to the second electrode of the driving transistor;
wherein the display panel further includes:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor;
a third conductive layer located at a side of the second active layer away from the base substrate, wherein at least a partial structure of the third conductive layer is used to form a top gate of the second transistor; and
a fourth conductive layer located at a side of the third conductive layer away from the base substrate, wherein the fourth conductive layer includes the first initialization signal line.

In an example embodiment of the present disclosure, the pixel driving circuit further includes a driving transistor and an eighth transistor, a first electrode of the eighth transistor is connected to a third initialization signal line, and a second electrode of the eighth transistor is connected to a first electrode of the driving transistor;
wherein two pixel driving circuit rows which are adjacent in the same pixel driving circuit row group share a same third initialization signal line.

In an example embodiment of the present disclosure, the third initialization signal line includes:
a second main body portion, wherein an orthographic projection of the second main body portion on the base substrate extends along the row direction;
a third protrusion; and
a fourth protrusion, wherein the third protrusion and the fourth protrusion are connected to two sides of the second main body portion in the column direction, respectively;
wherein in two pixel driving circuit rows that share the same third initialization signal line, the second main body portion is connected to the two pixel driving circuit rows through the third protrusion and the fourth protrusion, respectively.

In an example embodiment of the present disclosure, an orthographic projection of the third initialization signal line on the base substrate at least partially overlaps with an orthographic projection of the second initialization signal line on the base substrate.

In an example embodiment of the present disclosure, the pixel driving circuit further includes a second transistor, a first electrode of the second transistor is connected to a gate of the driving transistor, and a second electrode of the second transistor is connected to a second electrode of the driving transistor;
wherein the display panel further includes:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer includes the third initialization signal line.

In an example embodiment of the present disclosure, the pixel driving circuit further includes a driving transistor and a second transistor, a first electrode of the second transistor is connected to a gate of the driving transistor, and a second electrode of the second transistor is connected to a second electrode of the driving transistor;
wherein the display panel further includes:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer further includes a first bridging portion, and the first bridging portion is connected to the gate of the driving transistor and the first electrode of the second transistor through via holes.

In an example embodiment of the present disclosure, the pixel driving circuit further includes a capacitor, a first electrode of the capacitor is connected to the gate of the driving transistor, and a second electrode of the capacitor is connected to the first power supply line;
wherein the first conductive layer includes a first conductive portion, and the first conductive portion is used to form the gate of the driving transistor, and the first conductive portion is reused as the first electrode of the capacitor;
wherein the display panel further includes:
a second conductive layer between the third conductive layer and the first conductive layer, wherein the second conductive layer includes a second conductive portion, an orthographic projection of the second conductive portion on the base substrate at least partially overlaps with an orthographic projection of the first conductive portion on the base substrate, and the second conductive portion is used to form the second electrode of the capacitor;
wherein the first bridging portion includes a main body portion and an extension portion, the main body portion is connected to the gate of the driving transistor and the first electrode of the second transistor through via holes, and an orthographic projection of the extension portion on the base substrate at least partially overlaps with the orthographic projection of the second conductive portion on the base substrate;
wherein the main body portion includes a first side, the extension includes a second side, the first side is connected to the second side, and an angle between an orthographic projection of the first side on the base substrate and an orthographic projection of the second side on the base substrate is less than 180 °.

In an example embodiment of the present disclosure, the pixel driving circuit further includes a driving transistor and a second transistor, a first electrode of the second transistor is connected to a gate of the driving transistor, and a second electrode of the second transistor is connected to a second electrode of the driving transistor;
wherein the display panel further includes:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer further includes a second bridging portion, and the second bridging portion is connected to the second electrode of the second transistor and the second electrode of the driving transistor through via holes.

In an example embodiment of the present disclosure, the pixel driving circuit further includes a driving transistor, a second transistor, a fifth transistor and an eighth transistor, wherein a first electrode of the second transistor is connected to a gate of the driving transistor, a second electrode of the second transistor is connected to a second electrode of the driving transistor, a first electrode of the fifth transistor is connected to the first power supply line, a second electrode of the fifth transistor is connected to a first electrode of the driving transistor, a first electrode of the eighth transistor is connected to a third initialization signal line, and a second electrode of the eighth transistor is connected to the first electrode of the driving transistor;
wherein the display panel further includes:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor;
a third conductive layer located at a side of the second active layer away from the base substrate, wherein at least a partial structure of the third conductive layer is used to form a top gate of the second transistor; and a third conductive layer located at a side of the base substrate, wherein the third conductive layer includes a first gate line, and a partial structure of the first gate line is used to form a top gate of the second transistor;
wherein the third conductive layer further includes a third bridging portion, and the third bridging portion is connected to the first electrode of the driving transistor, the second electrode of the fifth transistor, and the second electrode of the eighth transistor through via holes, respectively.

In an example embodiment of the present disclosure, the pixel driving circuit further includes a driving transistor and a second transistor, a first electrode of the second transistor is connected to a gate of the driving transistor, and a second electrode of the second transistor is connected to a second electrode of the driving transistor;
wherein the display panel further includes:
a third conductive layer located at a side of the base substrate, wherein the third conductive layer includes a first gate line, and a partial structure of the first gate line is used to form a top gate of the second transistor;
a fourth conductive layer located at a side of the third conductive layer away from the base substrate, wherein the fourth conductive layer includes a first gate connection line, an orthographic projection of the first gate connection line on the base substrate extends along the row direction, and the first gate connection line is connected to the first gate line through one or more via holes.

In an example embodiment of the present disclosure, the pixel driving circuit further includes a driving transistor, a second transistor and a fourth transistor, a first electrode of the second transistor is connected to a gate of the driving transistor, a second electrode of the second transistor is connected to a second electrode of the driving transistor, a first electrode of the fourth transistor is connected to a data line, and a second electrode of the fourth transistor is connected to a first electrode of the driving transistor;
wherein the display panel further includes:
a first active layer located at a side of the base substrate, wherein the first active layer includes a fourth active portion, and the fourth active portion is used to form a channel region of the fourth transistor;
a first conductive layer located at a side of the first conductive layer away from the base substrate, wherein the first conductive layer includes a second gate line, an orthographic projection of the second gate line on the base substrate covers an orthographic projection of the fourth active portion on the base substrate, and a partial structure of the second gate line is used to form a gate of the fourth transistor;
a second active layer located at a side of the first conductive layer away from the base substrate, wherein a partial structure of the second active layer is used to form a channel region of the second transistor;
a third conductive layer located at a side of the second active layer away from the base substrate, wherein a partial structure of the third conductive layer is used to form a top gate of the second transistor; and
a fourth conductive layer located at a side of the third conductive layer away from the base substrate, wherein the fourth conductive layer includes a second gate connection line, an orthographic projection of the second gate connection line on the base substrate extends along the row direction, and the second gate connection line is connected to the second gate line through one or more via holes.

In an example embodiment of the present disclosure, the pixel driving circuit further includes a driving transistor and a second transistor, a first electrode of the second transistor is connected to a gate of the driving transistor, and a second electrode of the second transistor is connected to a second electrode of the driving transistor;
wherein the display panel further includes: a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein the second active layer includes a second active portion, and a twentieth active portion and a twenty-first active portion connected to two ends of the second active portion in the row direction, the second active portion is used to form a channel region of the second transistor, the twentieth active portion is used to form the first electrode of the second transistor, and the twenty-first active portion is used to form the second electrode of the second transistor; and
a third conductive layer located at a side of the second active layer away from the base substrate, wherein the third conductive layer includes a first gate line, the first gate line includes a third main body portion and a fifth protrusion connected to a side of the third main body portion in the column direction, an orthographic projection of the third main body portion on the base substrate extends along the row direction, and an orthographic projection of the fifth protrusion on the base substrate covers an orthographic projection of the second active portion on the base substrate.

In an example embodiment of the present disclosure, the pixel driving circuit further includes a driving transistor, a fourth transistor and a fifth transistor, a first electrode of the fifth transistor is connected to the first power supply line, a second electrode of the fifth transistor is connected to a first electrode of the driving transistor, a first electrode of the fourth transistor is connected to a data line, and a second electrode of the fourth transistor is connected to the first electrode of the driving transistor;
wherein the display panel further includes:
a first active layer including a third active portion, a fourth active portion and a fifth active portion, wherein the third active portion is used to form a channel region of the driving transistor, the fourth active portion is used to form a channel region of the fourth transistor, and the fifth active portion is used to form a channel region of the fifth transistor;
a first conductive layer located at a side of the first active layer away from the base substrate, wherein the first conductive layer includes a first conductive portion, a second gate line and an enable signal line, an orthographic projection of the second gate line on the base substrate extends along the row direction and covers an orthographic projection of the fourth active portion on the base substrate, a partial structure of the second gate line is used to form a gate of the fourth transistor, an orthographic projection of the enable signal line on the base substrate extends along the row direction and covers an orthographic projection of the fifth active portion on the base substrate, and a partial structure of the enable signal line is used to form a gate of the fifth transistor;
wherein in a same pixel driving circuit, an orthographic projection of the second gate line on the base substrate is located between an orthographic projection of the first conductive portion on the base substrate and the orthographic projection of the enable signal line on the base substrate.

In an example embodiment of the present disclosure, the pixel driving circuit further includes a driving transistor and a first transistor, a first electrode of the first transistor is connected to the first initialization signal line, and a second electrode of the first transistor is connected to a second electrode of the driving transistor;
wherein the display panel further includes: a first active layer located at a side of the base substrate, wherein the first active layer includes a third active portion and a first active portion, the third active portion is used to form a channel region of the driving transistor, and the first active portion is used to form a channel region of the first transistor;
wherein in a same pixel driving circuit, the first active portion and the third active portion are connected in a same layer.

In an example embodiment of the present disclosure, orthographic projections of two adjacent pixel driving circuits in a same pixel driving circuit row on the base substrate are at least partially arranged in mirror symmetry with respect to a second symmetry axis, and the second symmetry axis extends along the column direction.

In an example embodiment of the present disclosure, the pixel driving circuit further includes:
a driving transistor;
a first transistor, wherein a first electrode of the first transistor is connected to a first initialization signal line, and a second electrode of the first transistor is connected to a second electrode of the driving transistor;
a second transistor, wherein a first electrode of the second transistor is connected to a gate of the driving transistor, and a second electrode of the second transistor is connected to a second electrode of the driving transistor;
a fourth transistor, wherein a first electrode of the fourth transistor is connected to a data line, and a second electrode of the fourth transistor is connected to a first electrode of the driving transistor;
a fifth transistor, wherein a first electrode of the fifth transistor is connected to the first power supply line, and a second electrode of the fifth transistor is connected to the first electrode of the driving transistor;
a sixth transistor, wherein a first electrode of the sixth transistor is connected to the second electrode of the driving transistor, and a second electrode of the sixth transistor is connected to a first electrode of a light-emitting unit;
an eighth transistor, wherein a first electrode of the eighth transistor is connected to a third initialization signal line, and a second electrode of the eighth transistor is connected to the first electrode of the driving transistor;
a capacitor, wherein a first electrode of the capacitor is connected to the gate of the driving transistor, and a second electrode of the capacitor is connected to the first power supply line;
wherein the first transistor, the driving transistor, the fourth transistor, the fifth transistor, the sixth transistor, the seventh transistor and the eighth transistor are P-type transistors, and the second transistor is an N-type transistor.

In an example embodiment of the present disclosure, the display panel further includes:
a first active layer located at a side of the base substrate, wherein at least a partial structure of the first active layer is used to form channel regions of the first transistor, the driving transistor, the fourth transistor, the fifth transistor, the sixth transistor, the seventh transistor, and the eighth transistor;
a first conductive layer located at a side of the first active layer away from the base substrate, wherein at least a partial structure of the first conductive layer is used to form gates of the first transistor, the driving transistor, the fourth transistor, the fifth transistor, the sixth transistor, the seventh transistor, and the eighth transistor;
a second active layer located at a side of the first conductive layer away from the base substrate, wherein at least a partial structure of the second active layer is used to form a channel region of the second transistor; and a third conductive layer located at a side of the second active layer away from the base substrate, wherein at least a partial structure of the third conductive layer is used to form a top gate of the second transistor.

According to an aspect of the present disclosure, there is provided a display device, including the display panel described above.

It is to be understood that the foregoing general description and the following detailed description are illustrative and explanatory only and are not restrictive of the present disclosure.

### BRIEF DESCRIPTION OF THE DRAWINGS

The accompanying drawings herein, which are incorporated into the specification and constitute a part of the specification, illustrate embodiments consistent with the present disclosure, and are used together with the specification to explain principles of the present disclosure. Obviously, the accompanying drawings described below are only some embodiments of the present disclosure and for those of ordinary skill in this art, other accompanying drawings can be obtained based on these accompanying drawings without creative work.

FIG. 1 is a schematic structural diagram of a pixel driving circuit according to an example embodiment of the present disclosure;

FIG. 2 is a timing diagram of a part of nodes in the pixel driving circuit shown in FIG. 1 according to an example embodiment;

FIG. 3 is a schematic structural diagram of a display panel according to an example embodiment of the present disclosure;

FIG. 4 is a structural layout diagram of a display panel according to an example embodiment of the present disclosure;

FIG. 5 is a structural layout diagram of a shielding layer in FIG. 4;

FIG. 6 is a structural layout diagram of a first active layer in FIG. 4;

FIG. 7 is a structural layout diagram of a first conductive layer in FIG. 4;

FIG. 8 is a structural layout diagram of a second conductive layer in FIG. 4;

FIG. 9 is a structural layout diagram of a second active layer in FIG. 4;

FIG. 10 is a structural layout diagram of a third conductive layer in FIG. 4;

FIG. 11 is a structural layout diagram of a fourth conductive layer in FIG. 4;

FIG. 12 is a structural layout diagram of a fifth conductive layer in FIG. 4;

FIG. 13 is a structural layout diagram of the shielding layer and the first active layer in FIG. 4;

FIG. 14 is a structural layout diagram of the shielding layer, the first active layer, and the first conductive layer in FIG. 4;

FIG. 15 is a structural layout diagram of the shielding layer, the first active layer, the first conductive layer, and the second conductive layer in FIG. 4;

FIG. 16 is a structural layout diagram of the shielding layer, the first active layer, the first conductive layer, the second conductive layer, and the second active layer in FIG. 4;

FIG. 17 is a structural layout diagram of the shielding layer, the first active layer, the first conductive layer, the second conductive layer, the second active layer, and the third conductive layer in FIG. 4;

FIG. 18 is a structural layout diagram of the shielding layer, the first active layer, the first conductive layer, the second conductive layer, the second active layer, the third conductive layer, and the fourth conductive layer in FIG. 4;

FIG. 19 is a partial cross-sectional view of the display panel shown in FIG. 4 taken along a dotted line CC;

FIG. 20 is an equivalent circuit diagram of a display panel according to another example embodiment of the present disclosure;

FIG. 21 is a structural layout diagram of a display panel according to an example embodiment of the present disclosure;

FIG. 22 is a structural layout diagram of a shielding layer in FIG. 21;

FIG. 23 is a structural layout diagram of a first active layer in FIG. 21;

FIG. 24 is a structural layout diagram of a first conductive layer in FIG. 21;

FIG. 25 is a structural layout diagram of a second conductive layer in FIG. 21;

FIG. 26 is a structural layout diagram of a second active layer in FIG. 21;

FIG. 27 is a structural layout diagram of a third conductive layer in FIG. 21;

FIG. 28 is a structural layout diagram of a fourth conductive layer in FIG. 21;

FIG. 29 is a structural layout diagram of a fifth conductive layer in FIG. 21;

FIG. 30 is a structural layout diagram of the shielding layer and the first active layer in FIG. 21;

FIG. 31 is a structural layout diagram of the shielding layer, the first active layer, and the first conductive layer in FIG. 21;

FIG. 32 is a structural layout diagram of the shielding layer, the first active layer, the first conductive layer, and the second conductive layer in FIG. 21;

FIG. 33 is a structural layout diagram of the shielding layer, the first active layer, the first conductive layer, the second conductive layer, and the second active layer in FIG. 21;

FIG. 34 is a structural layout diagram of the shielding layer, the first active layer, the first conductive layer, the second conductive layer, the second active layer, and the third conductive layer in FIG. 21;

FIG. 35 is a structural layout diagram of the shielding layer, the first active layer, the first conductive layer, the second conductive layer, the second active layer, the third conductive layer, and the fourth conductive layer in FIG. 21;

FIG. 36 is a partial cross-sectional view of the display panel shown in FIG. 21 taken along the dotted line CC;

FIG. 37 is a structural layout diagram of a display panel according to another example embodiment of the present disclosure;

FIG. 38 is a structural layout diagram of a shielding layer in FIG. 37;

FIG. 39 is a structural layout diagram of a first active layer in FIG. 37;

FIG. 40 is a structural layout diagram of a first conductive layer in FIG. 37;

FIG. 41 is a structural layout diagram of a second conductive layer in FIG. 37;

FIG. 42 is a structural layout diagram of a second active layer in FIG. 37;

FIG. 43 is a structural layout diagram of a third conductive layer in FIG. 37;

FIG. 44 is a structural layout diagram of a fourth conductive layer in FIG. 37;

FIG. 45 is a structural layout diagram of a fifth conductive layer in FIG. 37;

FIG. 46 is a structural layout diagram of the shielding layer and the first active layer in FIG. 37;

FIG. 47 is a structural layout diagram of the shielding layer, the first active layer, and the first conductive layer in FIG. 37;

FIG. 48 is a structural layout diagram of the shielding layer, the first active layer, the first conductive layer, and the second conductive layer in FIG. 37;

FIG. 49 is a structural layout diagram of the shielding layer, the first active layer, the first conductive layer, the second conductive layer, and the second active layer in FIG. 37;

FIG. 50 is a structural layout diagram of the shielding layer, the first active layer, the first conductive layer, the second conductive layer, the second active layer, and the third conductive layer in FIG. 37;

FIG. 51 is a structural layout diagram of the shielding layer, the first active layer, the first conductive layer, the second conductive layer, the second active layer, the third conductive layer, and the fourth conductive layer in FIG. 37;

FIG. 52 is a partial cross-sectional view of the display panel shown in FIG. 37 taken along a dotted line CC.

### DETAILED DESCRIPTION

Example embodiments will now be described more fully with reference to the accompanying drawings. However, example embodiments can be implemented in a variety of forms and should not be construed as limited to the examples set forth herein; rather, these embodiments are provided so that the present disclosure will be more comprehensive and complete and will fully convey the concepts of the example embodiments to those skilled in the art. The same reference numerals in the drawings represent the same or similar structures, and thus their detailed description will be omitted.

The term “a”, “an”, or “said/the” is used to indicate the presence of one or more elements/components/etc. ; the terms “comprise/include” and “have” are used to indicate an open-ended inclusive meaning and mean that additional elements/components/etc. may be present in addition to the listed elements/components/etc.

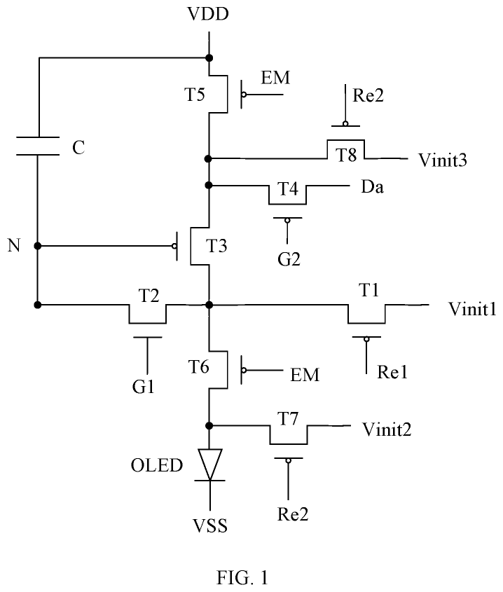

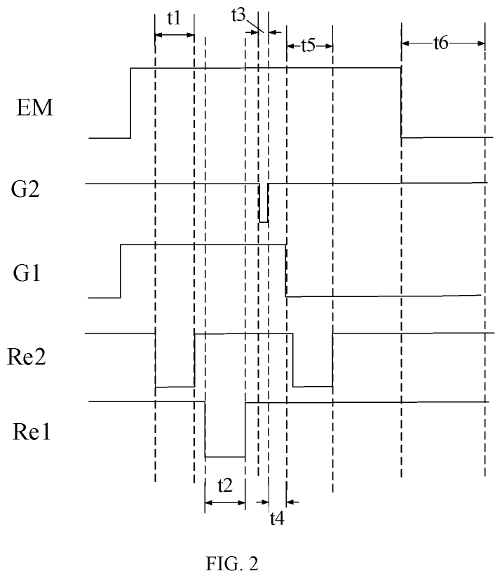

An example embodiment first provides a pixel driving circuit. As shown in FIGS. 1 and 2, FIG. 1 is a schematic structural diagram of a pixel driving circuit according to an example embodiment of the present disclosure, and FIG. 2 is a timing diagram of a part of nodes in the pixel driving circuit shown in FIG. 1 according to an example embodiment.

The pixel driving circuit may include: a driving transistor T3, a first transistor T1, a second transistor T2, a fourth transistor T4, a fifth transistor T5, a sixth transistor T6, a seventh transistor T7, an eighth transistor T8, and a capacitor C. A first electrode of the fourth transistor T4 is connected to a data signal terminal Da, a second electrode of the fourth transistor T4 is connected to a first electrode of the driving transistor T3, and a gate of the fourth transistor T4 is connected to a second gate driving signal terminal G2. A first electrode of the fifth transistor T5 is connected to a first power supply terminal VDD, a second electrode of the fifth transistor T5 is connected to the first electrode of the driving transistor T3, and a gate of the fifth transistor T5 is connected to an enable signal terminal EM. A gate of the driving transistor T3 is connected to a node N. A first electrode of the second transistor T2 is connected to the node N, a second electrode of the second transistor T2 is connected to a second electrode of the driving transistor T3, and a gate of the second transistor T2 is connected to a first gate driving signal terminal G1. A first electrode of the sixth transistor T6 is connected to the second electrode of the driving transistor T3, a second electrode of the sixth transistor T6 is connected to a second electrode of the seventh transistor T7, a gate of the sixth transistor T6 is connected to the enable signal terminal EM, a first electrode of the seventh transistor T7 is connected to a second initialization signal terminal Vinit2, and a gate of the seventh transistor T7 is connected to a second reset signal terminal Re2. A first electrode of the first transistor T1 is connected to a first initialization signal terminal Vinit1, a second electrode of the first transistor T1 is connected to the second electrode of the driving transistor T3, and a gate of the first transistor T1 is connected to a first reset signal terminal Re1. A first electrode of the eighth transistor T8 is connected to a third initialization signal terminal Vinit3, a second electrode of the eighth transistor T8 is connected to the first electrode of the driving transistor T3, and a gate of the eighth transistor T8 is connected to the second reset signal terminal Re2. A first electrode of the capacitor C is connected to the node N, and a second electrode of the capacitor C is connected to the first power supply terminal VDD. The pixel driving circuit may be used to drive a light-emitting unit OLED. A first electrode of the light-emitting unit OLED may be connected to the second electrode of the sixth transistor T6, and a second electrode of the light-emitting unit may be connected to a second power supply terminal VSS. The first electrode of the light-emitting unit may be an anode of the light-emitting unit, and the second electrode of the light-emitting unit may be a cathode of the light-emitting unit. The second transistor T2 may be an N-type transistor. For example, the second transistor T2 may be an N-type metal oxide transistor. The N-type transistor has relatively small leakage current, so that current leakage by the node N through the second transistor T2 during a light-emitting stage can be avoided. At the same time, the first transistor T1, the driving transistor T3, the fourth transistor T4, the fifth transistor T5, the sixth transistor T6, the seventh transistor T7, and the eighth transistor T8 may be P-type transistors. For example, the driving transistor T3, the fourth transistor T4, the fifth transistor T5, the sixth transistor T6, the seventh transistor T7, and the eighth transistor T8 may be P-type transistors, for example, P-type low-temperature polycrystalline silicon transistors. The P-type transistors have relatively high carrier mobility, which is conducive to realizing a display panel with high resolution, high response speed, high pixel density, and high aperture ratio. The first initialization signal terminal, the second initialization signal terminal, and the third initialization signal terminal may output the same or different voltage signals according to actual conditions.

As shown in FIG. 2, G1 represents the timing of the first gate driving signal terminal G1, G2 represents the timing of the second gate driving signal terminal G2, Re2 represents the timing of the second reset signal terminal Re2, Re1 represents the timing of the first reset signal terminal Re1, and EM represents the timing of the enable signal terminal EM. A driving cycle of the pixel driving circuit may include a first reset stage t1, a second reset stage t2, a data writing stage t3, a third reset stage t5, and a light-emitting stage t6.

In the first reset stage t1: the second reset signal terminal Re2 outputs a low-level signal, the seventh transistor T7 and the eighth transistor T8 are turned on, the second initialization signal terminal Vinit2 inputs the second initialization signal to the first electrode of the light-emitting unit OLED, and the third initialization signal terminal Vinit3 inputs the third initialization signal to the first electrode of the driving transistor T3 to improve the hysteresis problem of the driving transistor T3. In the second reset stage t2: the first gate driving signal terminal G1 outputs a high level, the first reset signal terminal Re1 outputs a low-level signal, the first transistor T1 and the second transistor T2 are turned on, and the first initialization signal terminal Vinit1 inputs the first initialization signal to the node N through the first transistor T1 and the second transistor T2. In the data writing stage t3: the second gate driving signal terminal G2 outputs a low-level signal, the first gate driving signal terminal G1 outputs a high-level signal, the fourth transistor T4 and the second transistor T2 are turned on, and the data signal terminal Da writes a compensation voltage Vdata+Vth to the node N through the fourth transistor T4 and the second transistor T2, where Vdata is the voltage of the data signal on the data signal terminal, and Vth is the threshold voltage of the driving transistor T3. In the third reset stage t5: the second reset signal terminal RE2 outputs a low-level signal, the seventh transistor T7 and the eighth transistor T8 are turned on, the second initialization signal terminal Vinit2 inputs the second initialization signal to the first electrode of the light-emitting unit OLED, and the third initialization signal terminal Vinit3 inputs the third initialization signal to the first electrode of the driving transistor T3. In the light-emitting stage t6: the enable signal terminal EM outputs a low-level signal, the sixth transistor T6 and the fifth transistor T5 are turned on, and the driving transistor T3 drives the light-emitting unit to emit light under the action of the compensation voltage Vdata+Vth stored in the capacitor C. The output current formula of the driving transistor is as follows:

I=(μWCox/2L)(Vgs−Vth)²

where I is the output current of the driving transistor; u is the carrier mobility; Cox is the gate capacitance per unit area, W is the width of the channel of the driving transistor, L is the length of the channel of the driving transistor, Vgs is the gate-source voltage difference of the driving transistor, and Vth is the threshold voltage of the driving transistor. The output current of the driving transistor in the above pixel driving circuit is: I=(μWCox/2L)(Vdata+Vth−Vdd−Vth)². The pixel driving circuit can avoid the influence of the threshold of the driving transistor on its output current.

It should be understood that in other example embodiments, the pixel driving circuit may have other driving methods. For example, in the third reset stage t5, the second reset signal terminal Re2 may not output a low-level pulse signal. For another example, in the light-emitting stage t6, the enable signal terminal EM may output multiple low-level pulse signals.

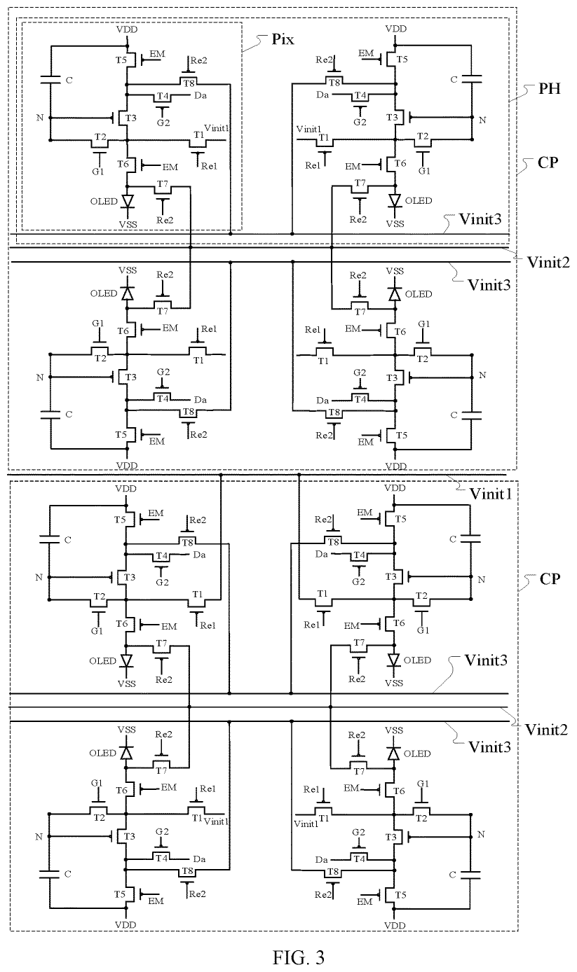

As shown in FIG. 3, it is a schematic structural diagram of a display panel according to an example embodiment of the present disclosure. The display panel includes: a substrate, pixel driving circuit row group(s) CP, and light-emitting unit(s) OLED. A pixel driving circuit row group CP includes two pixel driving circuit rows PH which are adjacent in a column direction. A pixel driving circuit row PH includes a plurality of pixel driving circuits Pix distributed in a row direction X. A pixel driving circuit Pix is used to drive a light-emitting unit OLED. The pixel driving circuit Pix includes a seventh transistor T7. A first electrode of the seventh transistor T7 is connected to a second initialization signal line Vinit2. A second electrode of the seventh transistor T7 is connected to a first electrode of the light-emitting unit OLED. A gate of the seventh transistor T7 is formed by a partial structure of a second reset signal line. An orthographic projection of the second reset signal line on the base substrate extends along the row direction X. Orthographic projections of two adjacent pixel driving circuit rows PH in the same pixel driving circuit row group CP on the base substrate are arranged in mirror symmetry with respect to a first symmetry axis. The first symmetry axis extends along the row direction X. The two adjacent pixel driving circuit rows in the same pixel driving circuit row group CP share the same second initialization signal line Vinit2.

In the display panel provided by the example embodiment, the integration of the display panel can be can improved by arranging two adjacent pixel driving circuit rows in the same pixel driving circuit row group CP in a mirror-symmetrical manner. In addition, in the example embodiment, two adjacent pixel driving circuit rows PH in the same pixel driving circuit row group CP can share the same second initialization signal line Vinit2, and this arrangement can reduce the number of lines and via holes in the display panel, thereby improving the manufacturing yield of the display panel.

In the example embodiment, the second initialization signal line Vinit2 may form the first symmetry axis. That is, the orthographic projections of two adjacent pixel driving circuit rows PH in the same pixel driving circuit row group CP on the base substrate are arranged in mirror symmetry with respect to the second initialization signal line Vinit2.

As shown in FIG. 3, the pixel driving circuit further includes a driving transistor T3 and a first transistor T1. A first electrode of the first transistor T1 is connected to a first initialization signal line Vinit1, and a second electrode of the first transistor T1 is connected to the second electrode of the driving transistor T3. The display panel includes a plurality of pixel driving circuit row groups CP, and the plurality of pixel driving circuit row groups CP are distributed in the column direction Y, and two pixel driving circuit rows PH, which are located in different pixel driving circuit row groups CP and are adjacent, share the same first initialization signal line Vinit1.

In the example embodiment, two pixel driving circuit rows PH, which are located in different pixel driving circuit row groups CP and are adjacent, share the same first initialization signal line Vinit1. This arrangement can also reduce the number of lines and via holes in the display panel, thereby improving the manufacturing yield of the display panel.

As shown in FIG. 3, the structure of the pixel driving circuit Pix may be as shown in FIG. 1, and accordingly, the second initialization signal line Vinit2 may be used to provide the second initialization signal terminal in FIG. 1, and the first initialization signal line Vinit1 may be used to provide the first initialization signal terminal in FIG. 1.

As shown in FIG. 3, the orthographic projections of two adjacent pixel driving circuits Pix in the same pixel driving circuit row PH on the base substrate may be arranged in mirror symmetry with respect to a second symmetry axis. The second symmetry axis extends along the column direction Y. This arrangement may also improve the integration of the display panel.

In addition, in other example embodiments, the orthographic projections of two adjacent pixel driving circuit rows PH in the same pixel driving circuit row group CP on the base substrate may also be partially arranged in mirror symmetry with respect to the first symmetry axis. Similarly, the orthographic projections of two adjacent pixel driving circuits Pix in the same pixel driving circuit row PH on the base substrate may also be at least partially arranged in mirror symmetry with respect to the second symmetry axis.

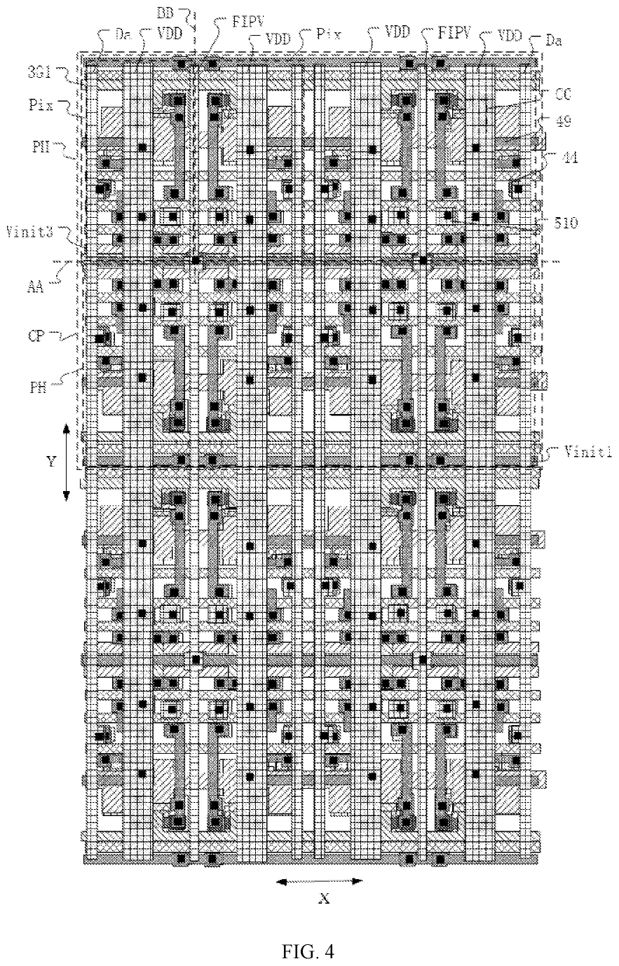

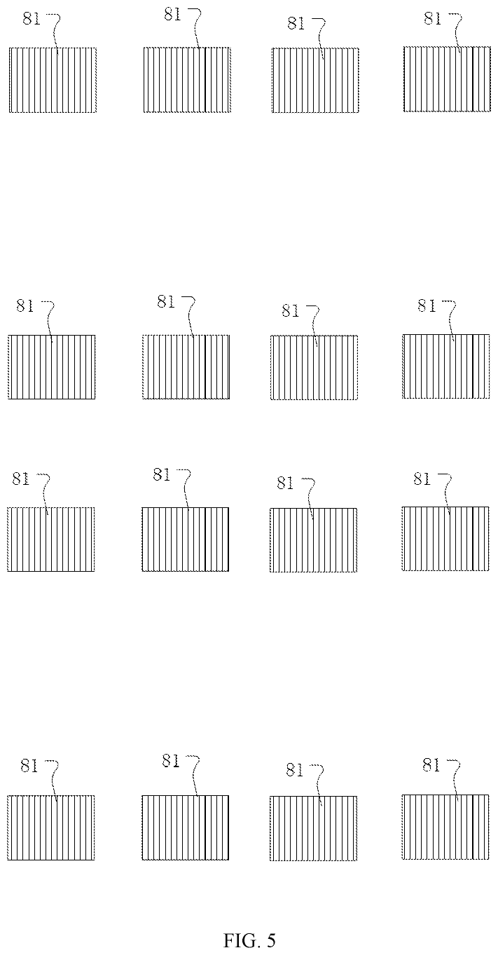

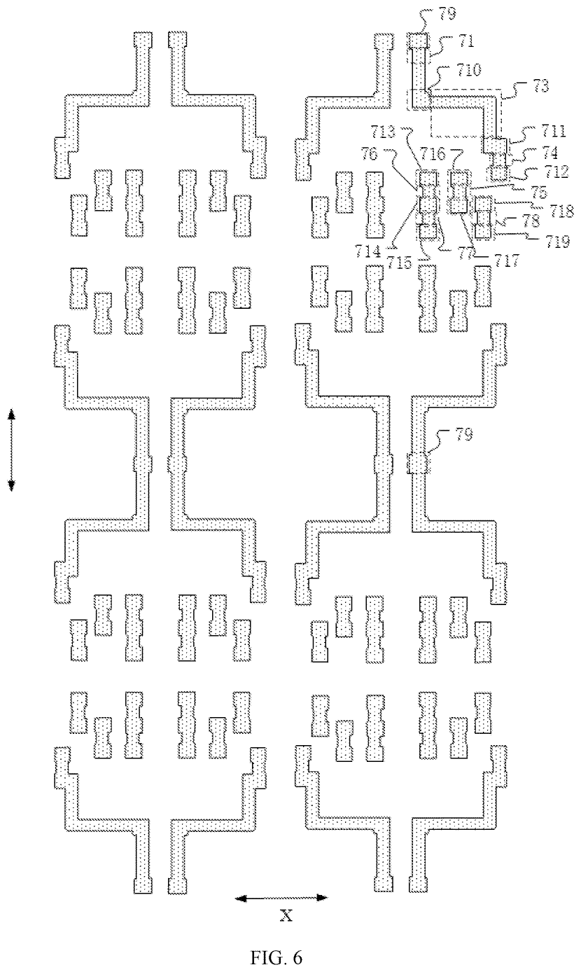

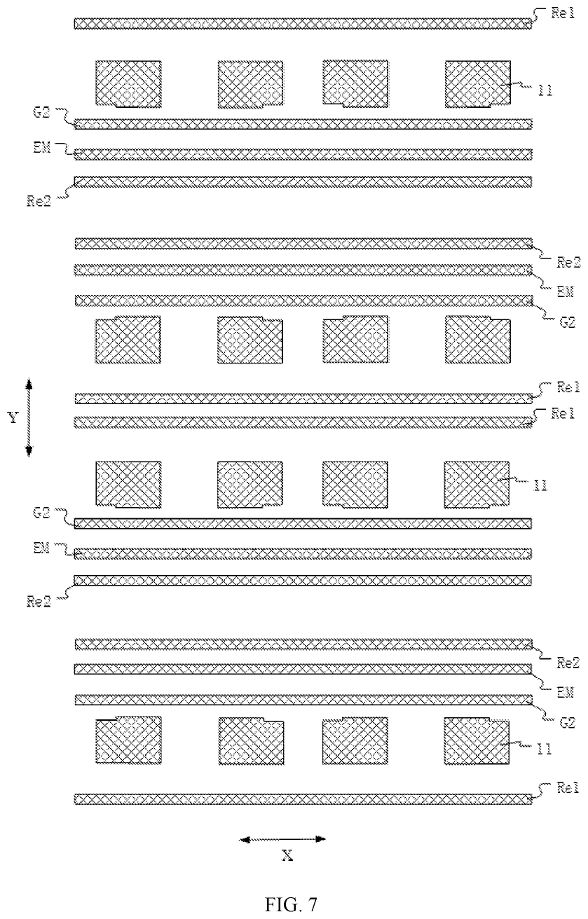

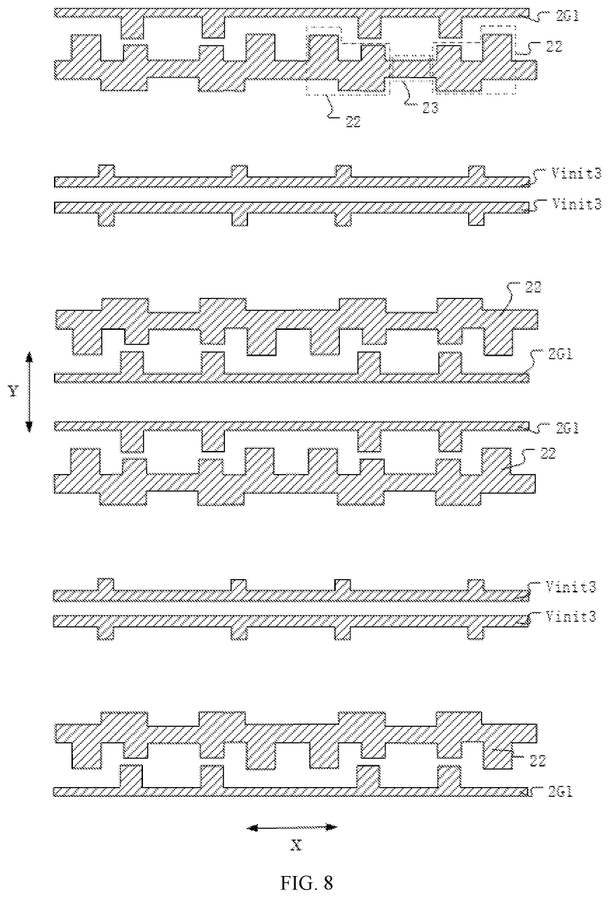

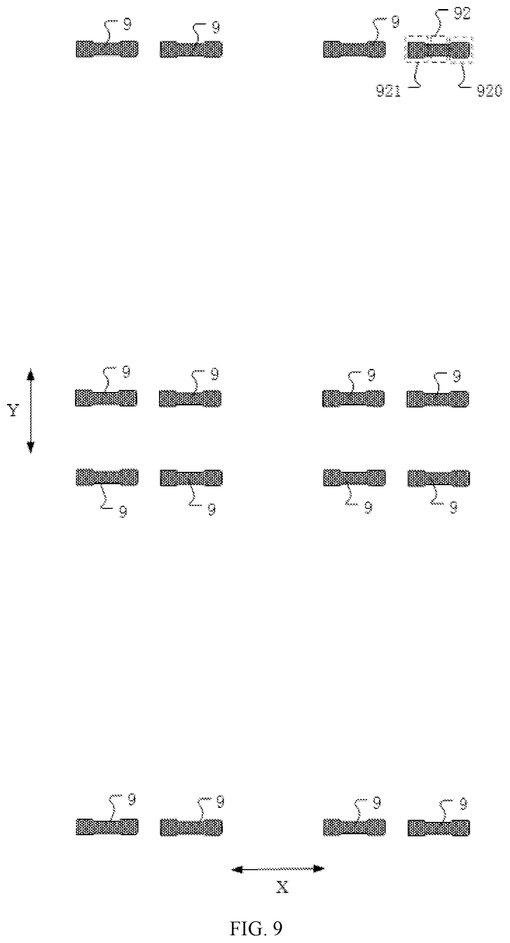

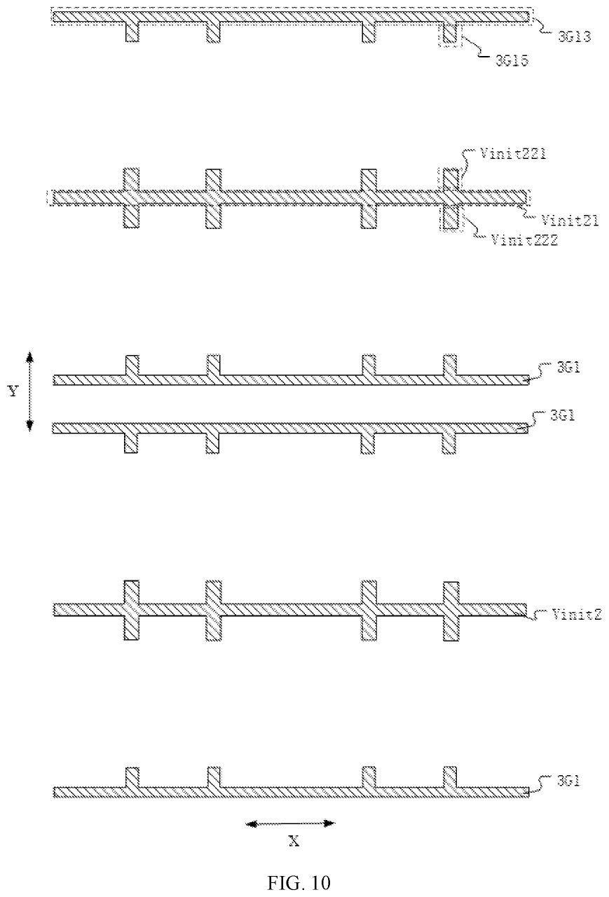

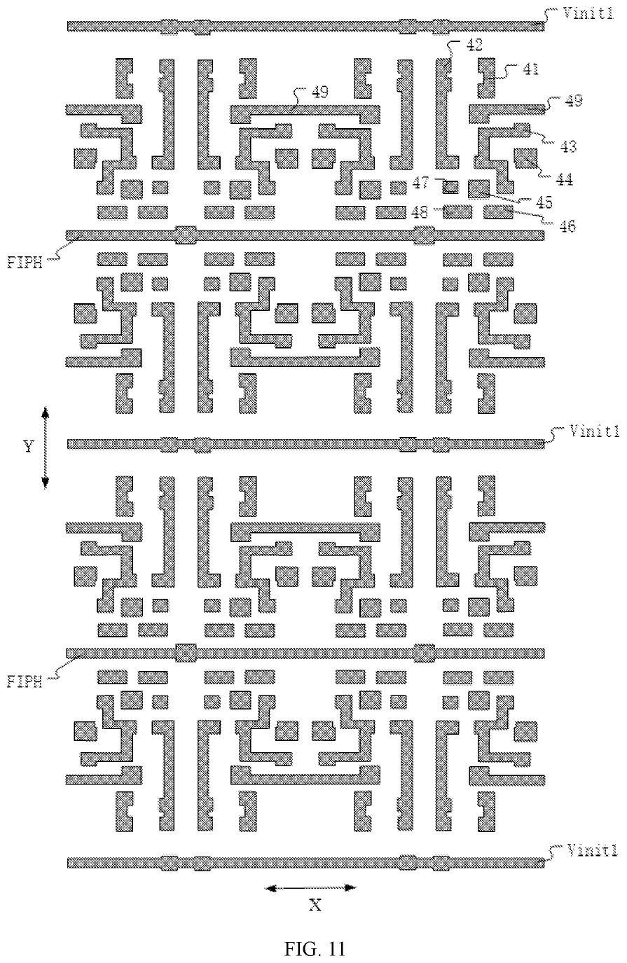

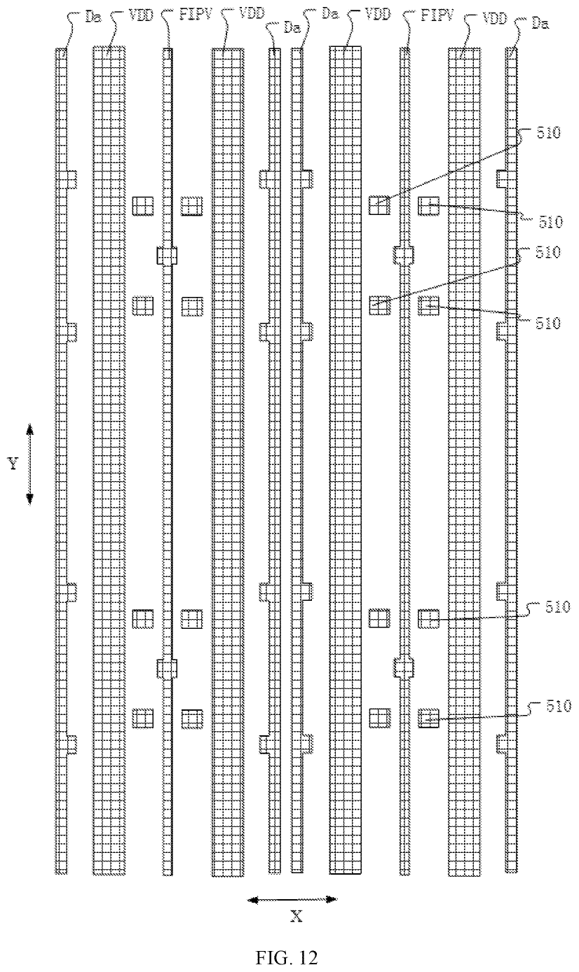

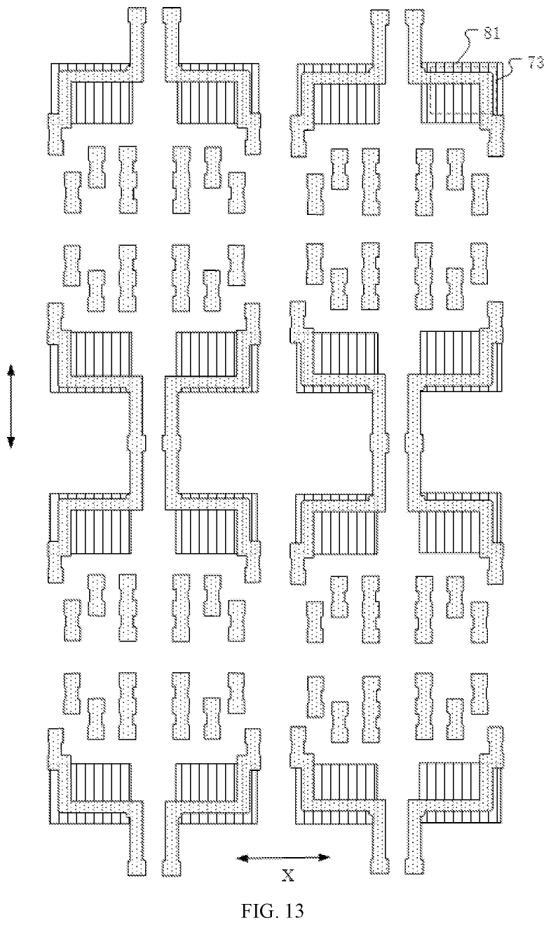

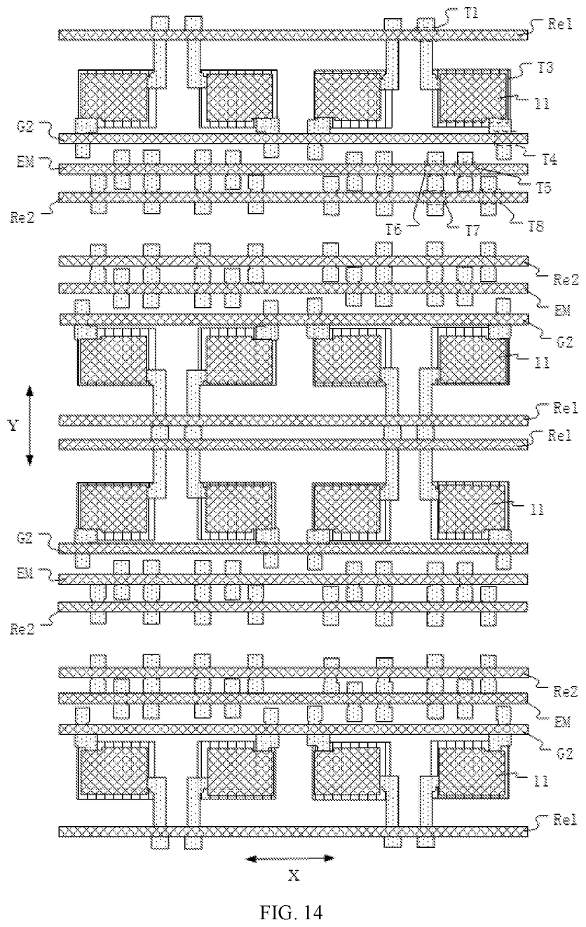

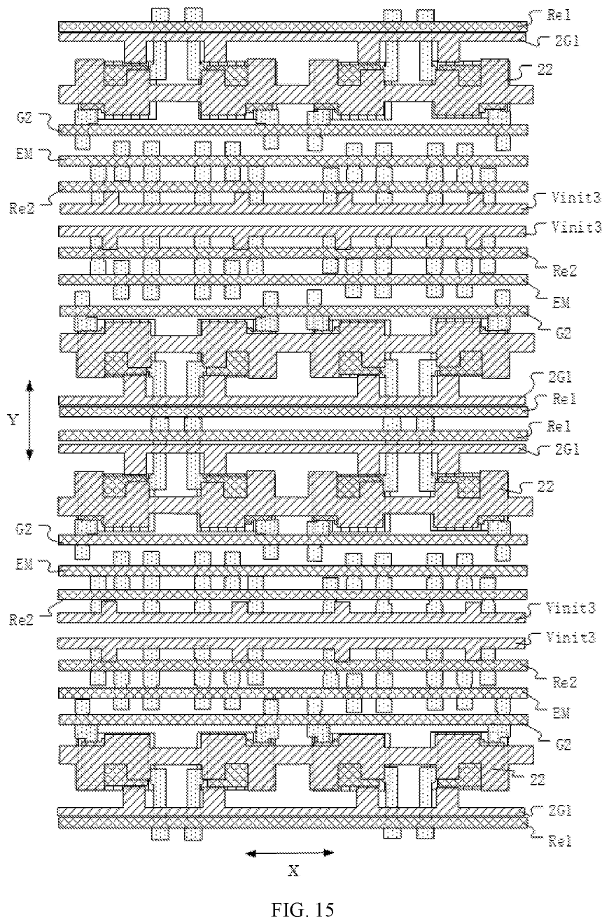

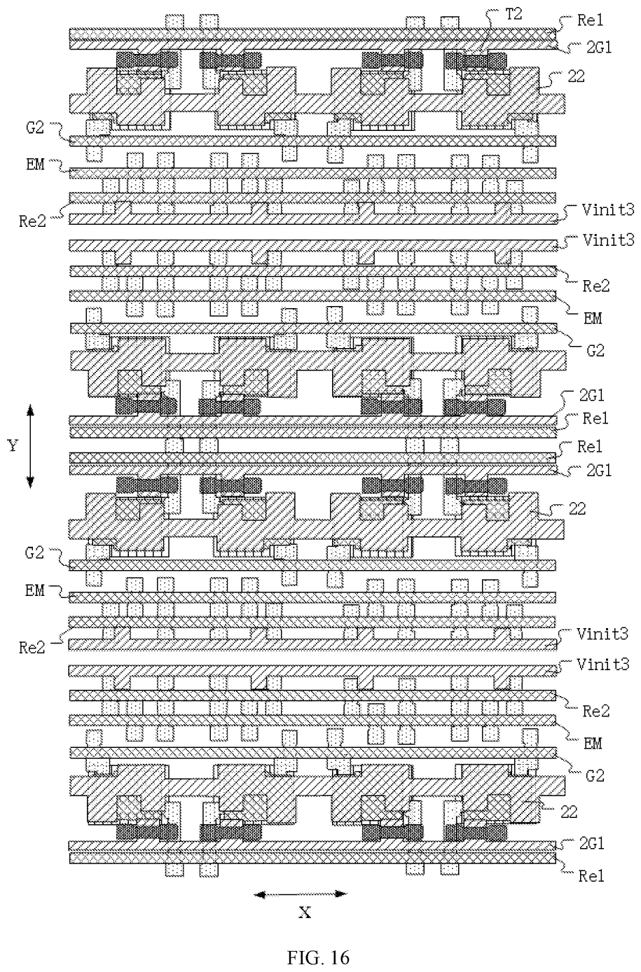

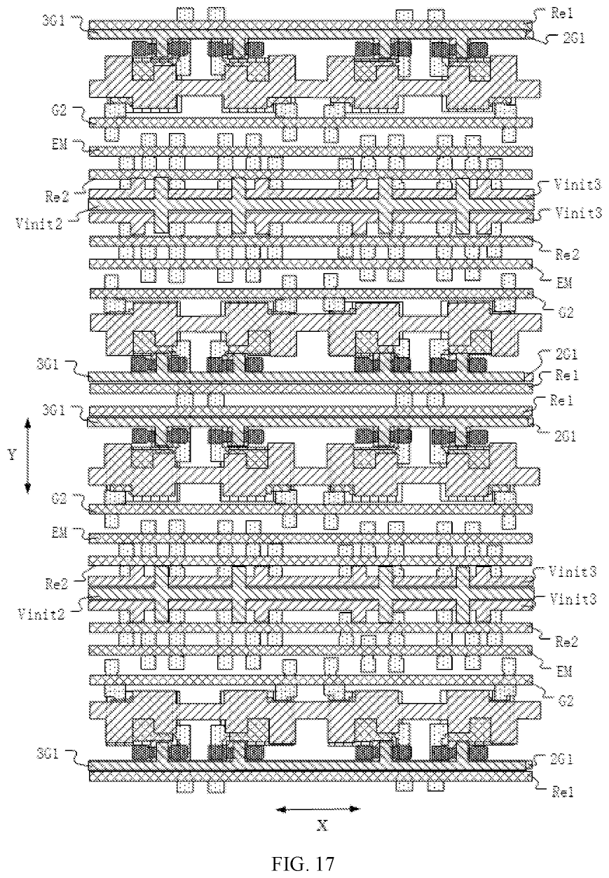

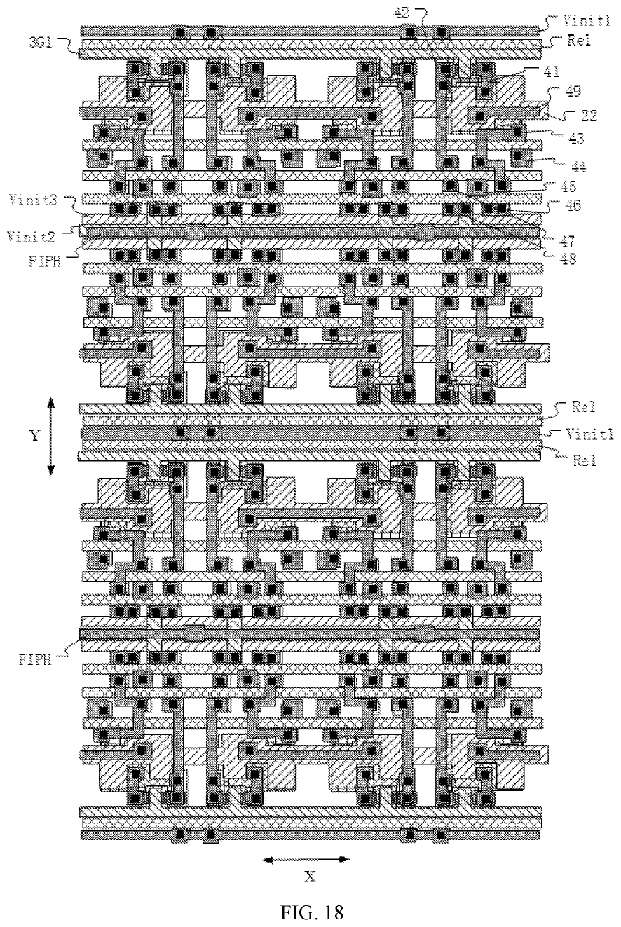

In the example embodiment, the display panel shown in FIG. 3 may include a base substrate, a shielding layer, a first active layer, a first conductive layer, a second conductive layer, a second active layer, a third conductive layer, a fourth conductive layer, and a fifth conductive layer which are stacked in sequence. An insulating layer may be provided between adjacent layers among the above layers. As shown in FIGS. 4 to 18, FIG. 4 is a structural layout diagram of a display panel according to an example embodiment of the present disclosure. FIG. 5 is a structural layout diagram of a shielding layer in FIG. 4. FIG. 6 is a structural layout diagram of a first active layer in FIG. 4. FIG. 7 is a structural layout diagram of a first conductive layer in FIG. 4. FIG. 8 is a structural layout diagram of a second conductive layer in FIG. 4. FIG. 9 is a structural layout diagram of a second active layer in FIG. 4. FIG. 10 is a structural layout diagram of a third conductive layer in FIG. 4. FIG. 11 is a structural layout diagram of a fourth conductive layer in FIG. 4. FIG. 12 is a structural layout diagram of a fifth conductive layer in FIG. 4. FIG. 13 is a structural layout diagram of the shielding layer and the first active layer in FIG. 4. FIG. 14 is a structural layout diagram of the shielding layer, the first active layer, and the first conductive layer in FIG. 4. FIG. 15 is a structural layout diagram of the shielding layer, the first active layer, the first conductive layer, and the second conductive layer in FIG. 4. FIG. 16 is a structural layout diagram of the shielding layer, the first active layer, the first conductive layer, the second conductive layer, and the second active layer in FIG. 4. FIG. 17 is a structural layout diagram of the shielding layer, the first active layer, the first conductive layer, the second conductive layer, the second active layer, and the third conductive layer in FIG. 4. FIG. 18 is a structural layout diagram of the shielding layer, the first active layer, the first conductive layer, the second conductive layer, the second active layer, the third conductive layer, and the fourth conductive layer in FIG. 4.

As shown in FIGS. 4 to 18, the orthographic projections of two adjacent pixel driving circuit rows PH in the same pixel driving circuit row group CP on the base substrate are at least partially arranged in mirror symmetry with respect to a first symmetry axis AA; the orthographic projections of two adjacent pixel driving circuits in the same pixel driving circuit row PH on the base substrate are at least partially arranged in mirror symmetry with respect to a second symmetry axis BB.

As shown in FIGS. 4, 5 and 13, the shielding layer may include a plurality of shielding portions 81, and the plurality of shielding portions 81 are distributed in an array in the row direction X and the column direction Y. It should be understood that in other example embodiments, the display panel may not include a shielding layer.

As shown in FIGS. 4, 6, 13, and 14, the first active layer may include a first active portion 71, a third active portion 73, a fourth active portion 74, a fifth active portion 75, a sixth active portion 76, a seventh active portion 77, an eighth active portion 78, a ninth active portion 79, a tenth active portion 710, an eleventh active portion 711, a twelfth active portion 712, a thirteenth active portion 713, a fourteenth active portion 714, a fifteenth active portion 715, a sixteenth active portion 716, a seventeenth active portion 717, an eighteenth active portion 718, and a nineteenth active portion 719. The first active portion 71 is used to form a channel region of the first transistor T1. The third active portion 73 may be used to form a channel region of the driving transistor T3. The fourth active portion 74 may be used to form a channel region of the fourth transistor T4. The fifth active portion 75 may be used to form a channel region of the fifth transistor T5. The sixth active portion 76 may be used to form a channel region of the sixth transistor T6. The seventh active portion 77 may be used to form a channel region of the seventh transistor T7. The eighth active portion 78 may be used to form a channel region of the eighth transistor T8. The ninth active portion 79 is connected to an end of the first active portion 71 away from the third active portion 73, and in two adjacent pixel driving circuit rows sharing the same first initialization signal line Vinit1, the ninth active portion 79 is connected between two first active portions 71 in the two adjacent pixel driving circuit rows. The tenth active portion 710 is connected between the first active portion 71 and the third active portion 73. The eleventh active portion 711 is connected between the third active portion 73 and the fourth active portion 74. The twelfth active portion 712 is connected to an end of the fourth active portion 74 away from the third active portion 73. The thirteenth active portion 713 is connected to an end of the sixth active portion away from the seventh active portion 77. The fourteenth active portion 714 is connected between the sixth active portion 76 and the seventh active portion 77. The fifteenth active portion 715 is connected to an end of the seventh active portion 77 away from the sixth active portion 76. The sixteenth active portion 716 and the seventeenth active portion 717 are connected to both ends of the fifth active portion 75. The eighteenth active portion 718 and the nineteenth active portion 719 are connected to both ends of the eighth active portion 78. In this example embodiment, the first active layer may be formed of a polysilicon material, and accordingly, the first transistor T1, the driving transistor T3, the fourth transistor T4, the fifth transistor T5, the sixth transistor T6, the seventh transistor T7, and the eighth transistor T8 may be P-type low temperature polysilicon thin film transistors.

In an example embodiment, as shown in FIGS. 4, 6, 13 and 14, the third active portion 73 is “L”-shaped. It should be understood that in other example embodiments, the third active portion 73 may also be other shape, for example, the third active portion 73 may also be “π”-shaped, “I”-shaped, etc.

It should be noted that, in other example embodiments, shielding portions 81 adjacent to each other in the row direction X may be connected by a connection portion located in the shielding layer, and shielding portions 81 adjacent to each other in the column direction Y may be connected by a connection portion located in the shielding layer. This arrangement can form a grid structure of the shielding layer. The shielding layer may also be connected to a stable power supply terminal. For example, the shielding layer may be connected to a stable voltage terminal such as the first power supply terminal VDD, the first initialization signal terminal Vinit1, the second initialization signal terminal Vinit2, the third initialization signal terminal Vinit3 or the like in FIG. 1. The shielding portions 81 can shield the noise influence of other signal(s) on the driving transistor T3.

As shown in FIGS. 4, 7 and 14, the first conductive layer may include: a first conductive portion 11, a second gate line G2, an enable signal line EM, a first reset signal line Re 1, and a second reset signal line Re2. The second gate line G2 may be used to provide the second gate driving signal terminal in FIG. 1. The enable signal line EM may be used to provide the enable signal terminal in FIG. 1. The first reset signal line Re1 may be used to provide the first reset signal terminal in FIG. 1. The second reset signal line Re2 may be used to provide the second reset signal terminal in FIG. The orthographic projection of the second gate line G2 on the base substrate, the orthographic projection of the enable signal line EM on the base substrate, the orthographic projection of the first reset signal line Re1 on the base substrate, and the orthographic projection of the second reset signal line Re2 on the base substrate may all extend along the row direction X. The orthographic projection of the second gate line G2 on the base substrate covers the orthographic projection of the fourth active portion 74 on the base substrate, and a partial structure of the second gate line G2 is used to form the gate of the fourth transistor T4. The orthographic projection of the enable signal line EM on the base substrate covers the orthographic projection of the fifth active portion 75 on the base substrate and the orthographic projection of the sixth active portion 76 on the base substrate, and a partial structure of the enable signal line EM may be used to form the gates of the fifth transistor T5 and the sixth transistor T6, respectively. The orthographic projection of the first reset signal line Re1 on the base substrate may cover the orthographic projection of the first active portion 71 on the base substrate, and a partial structure of the first reset signal line Re1 is used to form the gate of the first transistor T1. The orthographic projection of the second reset signal line Re2 on the base substrate may cover the orthographic projection of the seventh active portion 77 on the base substrate and the orthographic projection of the eighth active portion 78 on the base substrate, and a partial structure of the second reset signal line Re2 may be used to form the gates of the seventh transistor T7 and the eighth transistor T8, respectively. The orthographic projection of the first conductive portion 11 on the base substrate covers the orthographic projection of the third active portion 73 on the base substrate, and the first conductive portion 11 may be used to form the gate of the driving transistor T3, and meanwhile the first conductive portion 11 may be reused as the first electrode of the capacitor C. In the same pixel driving circuit, the orthographic projection of the first conductive portion 11 on the base substrate is located between the orthographic projection of the first reset signal line Re1 on the base substrate and the orthographic projection of the second gate line G2 on the base substrate. The orthographic projection of the enable signal line EM on the base substrate is located at a side of the orthographic projection of the second gate line G2 on the base substrate away from the orthographic projection of the first conductive portion 11 on the base substrate. The orthographic projection of the second reset signal line Re2 on the base substrate is located at a side of the orthographic projection of the enable signal line EM on the base substrate away from the orthographic projection of the first conductive portion 11 on the base substrate. In the display panel, the first conductive layer may be used as a mask to perform a process on the first active layer to make a part of the first active layer behave like a conductor, that is, a region of the first active layer covered by the first conductive layer may form a channel region of a transistor, and a region of the first active layer not covered by the first conductive layer forms a conductor structure.

As shown in FIGS. 4, 8 and 15, the second conductive layer may include: a third gate line 2G1, a second conductive portion 22 and a third initialization signal line Vinit3. The orthographic projection of the third gate line 2G1 on the base substrate extends along the row direction X, and the third gate line 2G1 may be used to provide the first gate driving signal terminal in FIG. 1. The orthographic projection of the second conductive portion 22 on the base substrate may at least partially overlap with the orthographic projection of the first conductive portion 11 on the base substrate, and the second conductive portion 22 is used to form the second electrode of the capacitor C. The second conductive layer may further include a second connection portion 23. Second conductive portions 22 adjacent to each other in the row direction X may be connected by a second connection portion 23. The third initialization signal line Vinit3 may be used to provide the third initialization signal terminal Vinit3 in FIG. 1, and the orthographic projection of the third initialization signal line Vinit3 on the base substrate may extend along the row direction X. The orthographic projection of the third initialization signal line Vinit3 on the base substrate is located between the orthographic projection of a second reset signal line Re2 in the current row of pixel driving circuits on the base substrate and the orthographic projection of a second reset signal line Re2 in a next adjacent row of pixel driving circuits on the base substrate. This setting can reduce the parasitic capacitance between the third initialization signal line Vinit3 and the enable signal line EM, or the second conductive portion 22 or other structure(s), thereby improving the display effect of the display panel.

As shown in FIGS. 4, 9 and 16, the second active layer may include an active portion 9. The active portion 9 may include: a second active portion 92, and a twentieth active portion 920 and a twenty-first active portion 921 connected to both ends of the second active portion 92. The second active portion 92 is used to form a channel region of the second transistor T2. The second active layer may be formed of indium gallium zinc oxide, and accordingly, the second transistor T2 may be an N-type metal oxide thin film transistor. The orthographic projection of the third gate line 2G1 on the base substrate may cover the orthographic projection of the second active portion 92 on the base substrate, and a partial structure of the third gate line 2G1 may be used to form a bottom gate of the second transistor T2. In addition, the twentieth active portion 920, the second active portion 92, and the twenty-first active portion 921 may be distributed in the row direction X.

As shown in FIGS. 4, 10 and 17, the third conductive layer may include a first gate line 3G1 and a second initialization signal line Vinit2. The orthographic projection of the first gate line 3G1 on the base substrate and the orthographic projection of the second initialization signal line Vinit2 on the base substrate may both extend along the row direction X. The first gate line 3G1 may be used to provide the first gate driving signal terminal in FIG. 1. The first gate line 3G1 includes a third main body portion 3G13 and a fifth protrusion 3G15 connected to a side of the third main body portion 3G13 in the column direction. The orthographic projection of the third main body portion 3G13 on the base substrate extends along the row direction X. The orthographic projection of the fifth protrusion 3G15 on the base substrate covers the orthographic projection of the second active portion 92 on the base substrate. A partial structure of the fifth protrusion 3G15 may be used to form a top gate of the second transistor T2. Also, the first gate line 3G1 may be connected to the third gate line 2G1 through a via hole located in a frame region of the display panel. The second initialization signal line Vinit2 may be used to provide the second initialization signal terminal in FIG. 1. As shown in FIGS. 4, 10 and 17, two adjacent pixel driving circuit rows PH in the same pixel driving circuit row group CP may share the same second initialization signal line Vinit2. The orthographic projection of the second initialization signal line Vinit2 on the base substrate is at least partially located between the orthographic projections of two adjacent third initialization signal lines Vinit3 in the same pixel driving circuit row group CP on the base substrate. This arrangement can reduce the parasitic battery between the third initialization signal line Vinit3 and the second initialization signal line Vinit2 by reducing the overlapping area between the third initialization signal line Vinit3 and the second initialization signal line Vinit2, thereby reducing the signal interference between the third initialization signal line Vinit3 and the second initialization signal line Vinit2. As shown in FIGS. 4, 10 and 17, the second initialization signal line Vinit2 may include a first main body portion Vinit21, a first protrusion Vinit221 and a second protrusion Vinit222. The first protrusion Vinit221 and the second protrusion Vinit222 are respectively connected to both sides of the first main body portion Vinit21 in the column direction Y. The orthographic projection of the first main body portion Vinit21 on the base substrate may extend along the row direction X and may be located between the orthographic projections of two adjacent third initialization signal lines Vinit3 in the same pixel driving circuit row group CP on the base substrate. In two pixel driving circuit rows that share the same second initialization signal line Vinit2, the first main body portion Vinit21 is connected to the two pixel driving circuit rows through the first protrusion Vinit221 and the second protrusion Vinit222, respectively.

In addition, in the display panel, the third conductive layer may be used as a mask to perform a process on the second active layer to make a part of the second active layer behave like a conductor, that is, a region of the second active layer covered by the third conductive layer may form a channel region of a transistor, and a region of the second active layer not covered by the third conductive layer forms a conductor structure.

As shown in FIGS. 4, 11 and 18, the fourth conductive layer may include a first bridging portion 41, a second bridging portion 42, a third bridging portion 43, a fourth bridging portion 44, a fifth bridging portion 45, a sixth bridging portion 46, a seventh bridging portion 47, an eighth bridging portion 48, a ninth bridging portion 49, a first initialization signal line Vinit1, and a first fan-out line FIPH. The first bridging portion 41 may be connected to the twentieth active portion 720 and the first conductive portion 11 through via holes, respectively, to connect the first electrode of the second transistor T2 and the gate of the driving transistor T3. The second bridging portion 42 may be connected to the twenty-first active portion 721, the tenth active portion 710, and the thirteenth active portion 713 through via holes, respectively, to connect the second electrode of the second transistor T2, the second electrode of the first transistor T1, and the first electrode of the sixth transistor T6. The third bridging portion 43 may be connected to the eleventh active portion 711, the sixteenth active portion 716, and the eighteenth active portion 718 through via holes, respectively, to connect the second electrode of the fourth transistor T4, the second electrode of the eighth transistor T8, the second electrode of the fifth transistor T5, and the first electrode of the driving transistor T3. The fourth bridging portion 44 may be connected to the twelfth active portion 712 through a via hole to connect the first electrode of the fourth transistor T4. The fifth bridging portion 45 may be connected to the seventeenth active portion 717 through a via hole to connect the first electrode of the fifth transistor. The sixth bridging portion 46 may be connected to the nineteenth active portion 719 and the third initialization signal line Vinit3 through via holes, respectively, to connect the first electrode of the eighth transistor T8 and the third initialization signal terminal. The seventh bridging portion 47 may be connected to the fourteenth active portion 714 through a via hole to connect the second electrode of the sixth transistor T6 and the second electrode of the seventh transistor T7. The eighth bridging portion 48 may be connected to the second initialization signal line Vinit2 and the fifteenth active portion 715 through via holes to connect the first electrode of the seventh transistor T7 and the second initialization signal terminal. The ninth bridging portion 49 is connected to two second conductive portions 22 which are adjacent in the row direction X through via holes to reduce the resistance of the second conductive portions 22 in the row direction X.

The first initialization signal line Vinit1 may be used to provide the first initialization signal terminal in FIG. 1, and the orthographic projection of the first initialization signal line Vinit1 on the base substrate extends along the row direction X. And in the same pixel driving circuit, the orthographic projection of the first initialization signal line Vinit1 on the base substrate is located at a side of the orthographic projection of the first reset signal line Re1 on the base substrate away from the orthographic projection of the first conductive portion 11 on the base substrate. This arrangement can reduce the parasitic capacitance between the first initialization signal line Vinit1 and the enable signal line EM, the first reset signal line Re1 or other alternating current signal line(s), thereby improving the voltage stability of the first initialization signal line Vinit1. The alternating current signal line is a signal line that outputs an alternating current signal.

In an example embodiment, as shown in FIGS. 4, 11 and 18, two pixel driving circuit rows PH, which are located in different pixel driving circuit row groups CP and are adjacent, share the same first initialization signal line Vinit1. This arrangement can also reduce the number of lines and via holes in the display panel, thereby improving the manufacturing yield of the display panel.

As shown in FIGS. 4, 11 and 18, the orthographic projection of the first fan-out line FIPH on the base substrate may extend along the row direction X, and the first fan-out line FIPH may be used as a row direction fan-out line connecting a data line in the FIP (Fanout In Pixel, the fan-out region in a pixel).

In an example embodiment, the square resistance of the fourth conductive layer may be smaller than the square resistance of the first conductive layer, the second conductive layer, and the third conductive layer. In the example embodiment, the first initialization signal line Vinit1 is set in the fourth conductive layer. This arrangement can reduce the voltage difference of the first initialization signal line(s) Vinit1 at different positions of the display panel, thereby improving the display uniformity of the display panel. As shown in FIGS. 4 and 12, the fifth conductive layer may include a tenth bridging portion 510, a data line Da, first power supply line(s) VDD, and a second fan-out line FIPV. The orthographic projection of the data line Da on the base substrate, the orthographic projection of the first power supply line VDD on the base substrate, and the orthographic projection of the second fan-out line FIPV on the base substrate may all extend along the column direction Y. The data line Da is used to provide the data signal terminal in FIG. 1, and the first power supply line VDD is used to provide the first power supply terminal in FIG. 1. The data line Da may be connected to the fourth bridging portion 44 through a via hole to connect the data signal terminal and the first electrode of the fourth transistor T4. There may be multiple first power supply lines VDD, and the orthographic projections of the multiple first power supply lines VDD on the base substrate extend along the column direction Y and are spaced apart along the row direction X. A first power supply line VDD may be connected, through a via hole, to a ninth bridging portion 49 whose orthographic projection on the base substrate intersects with the orthographic projection of the first power supply line VDD on the base substrate. The first power supply line(s) VDD and the second conductive portion(s) connected in the row direction X, and the ninth bridging portion(s) 49 may form a grid structure. This arrangement can reduce the voltage difference of the first power supply line(s) at different positions of the display panel, thereby improving the display uniformity of the display panel. In addition, the first power supply line VDD may also be connected to the fifth bridging portion 45 through a via hole to connect the first power supply terminal and the first electrode of the fifth transistor T5.

The second fan-out line FIPV may be used as a column direction fan-out line connecting a data line in FIP (Fanout In Pixel, fan-out region in a pixel). The first fan-out line and the second fan-out line may also be provided in a non-fan-out region of the display panel. In the non-fan-out region, the second fan-out line FIPV may be connected, through a via hole, to a first fan-out line FIPH whose orthographic projection on the base substrate intersects with the orthographic projection of the second fan-out line FIPV on the base substrate, and the first fan-out line(s) FIPH and the second fan-out line(s) FIPV may form a grid structure. The grid structure may be connected to a common electrode layer in the display panel through a via hole, and the common electrode layer may be used as the second electrode of the light-emitting unit. This arrangement can reduce the resistance of the common electrode layer, thereby reducing the voltage difference of the common electrode layer at different positions of the display panel, thereby improving the display uniformity of the display panel. The tenth bridging portion 510 may be connected to the seventh bridging portion 47 through a via hole to connect the second electrode of the sixth transistor T6 and the second electrode of the seventh transistor T7. The tenth bridging portion 510 may also be connected to a pixel electrode in the pixel electrode layer through a via hole. The pixel electrode layer may be located at a side of the fifth conductive layer away from the base substrate. The pixel electrode may be used to form the first electrode of the light-emitting unit.

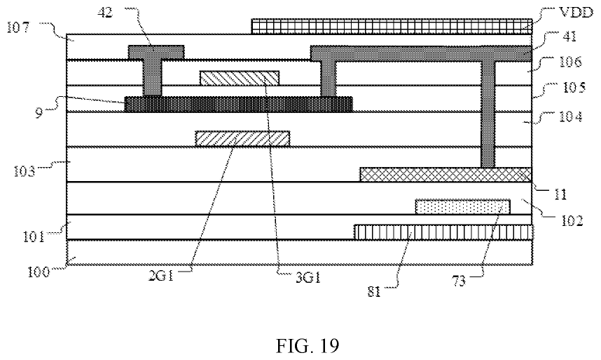

As shown in FIG. 19, it is a partial cross-sectional view of the display panel shown in FIG. 4 taken along a dotted line CC. The display panel may further include a first insulating layer 101, a second insulating layer 102, a third insulating layer 103, a fourth insulating layer 104, a fifth insulating layer 105, a first dielectric layer 106, and a first planarization layer 108. The base substrate 100, the shielding layer, the first insulating layer 101, the first active layer, the second insulating layer 102, the first conductive layer, the third insulating layer 103, the second conductive layer, the fourth insulating layer 104, the second active layer, the fifth insulating layer 105, the third conductive layer, the first dielectric layer 106, the fourth conductive layer, the first planarization layer 108, and the fifth conductive layer are stacked in sequence. The first insulating layer 101, the second insulating layer 102, the third insulating layer 103, the fourth insulating layer 104, and the fifth insulating layer 105 may be a single-layer structure or a multi-layer structure, and the materials of the first insulating layer 101, the second insulating layer 102, the third insulating layer 103, the fourth insulating layer 104, and the fifth insulating layer 105 may be at least one of silicon nitride, silicon oxide, or silicon oxynitride. The first dielectric layer 106 may be a silicon nitride layer. The material of the first planarization layer 108 may be an organic material, such as polyimide (PI), polyethylene terephthalate (PET), polyethylene naphthalate (PEN), silicon-glass bonding structure (SOG, silicon on glass) and the like. The base substrate 100 may include a glass substrate, a blocking layer, and a polyimide layer stacked in sequence, and the blocking layer may be an inorganic material. The material of the first conductive layer, the second conductive layer, and the third conductive layer may be one of molybdenum, aluminum, copper, titanium, and niobium, or an alloy, or a conductive layer such as a molybdenum/titanium alloy or laminated molybdenum/titanium, and so on. The material of the fourth conductive layer and the fifth conductive layer may include a metal material, for example, one of molybdenum, aluminum, copper, titanium, niobium or an alloy, or a molybdenum/titanium alloy or laminated molybdenum/titanium, or a conductive layer such as laminated titanium/aluminum/titanium. The square resistance of any one of the fourth conductive layer and the fifth conductive layer may be less than the square resistance of any one of the first conductive layer, the second conductive layer, and the third conductive layer. In addition, the display panel may further include a pixel electrode layer located at a side of the fifth conductive layer away from the base substrate, a light-emitting unit layer located at a side of the pixel electrode layer away from the base substrate, and a common electrode layer located at a side of the light-emitting unit layer away from the base substrate. The light-emitting unit layer may include a light-emitting material layer, a hole transport layer and an electron transport layer located at both sides of the light-emitting material layer, an electron injection layer located at a side of the electron transport layer away from the light-emitting material layer, and a hole injection layer located at a side of the hole transport layer away from the light-emitting material layer. Holes generated by the anode enter the light-emitting material layer through the hole injection layer and the hole transport layer, and electrons generated by the cathode enter the light-emitting material layer through the electron injection layer and the electron transport layer. When electrons and holes meet in the light-emitting material layer, energy excitons are generated, thereby exciting light-emitting molecules in the light-emitting material layer to generate visible light.

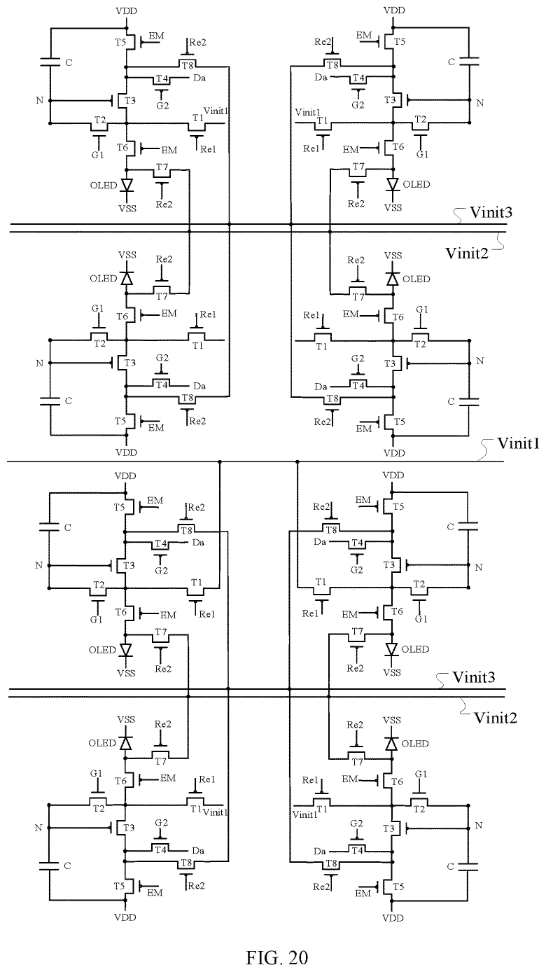

As shown in FIG. 20, it is an equivalent circuit diagram of a display panel according to another example embodiment of the present disclosure. Compared with the display panel shown in FIG. 3, the display panel shown in FIG. 20 also includes: a base substrate, pixel driving circuit row group(s) CP, and light-emitting unit(s) OLED. A pixel driving circuit row group CP includes two pixel driving circuit rows PH which are adjacent in the column direction. A pixel driving circuit row PH includes a plurality of pixel driving circuits Pix distributed in the row direction X. A pixel driving circuit Pix is used to drive a light-emitting unit OLED. The pixel driving circuit Pix includes a seventh transistor T7. A first electrode of the seventh transistor T7 is connected to a second initialization signal line Vinit2. A second electrode of the seventh transistor T7 is connected to a first electrode of the light-emitting unit OLED. A gate of the seventh transistor T7 is formed by a partial structure of a second reset signal line. The orthographic projection of the second reset signal line on the base substrate extends along the row direction X. Orthographic projections of two adjacent pixel driving circuit rows PH in the same pixel driving circuit row group CP on the base substrate are arranged in mirror symmetry with respect to a first symmetry axis. The first symmetry axis extends along the row direction X, and the two adjacent pixel driving circuit rows in the same pixel driving circuit row group CP share the same second initialization signal line Vinit2.

In an example embodiment, the second initialization signal line Vinit2 may form the first symmetry axis. That is, the orthographic projections of two adjacent pixel driving circuit rows PH in the same pixel driving circuit row group CP on the base substrate are arranged in mirror symmetry with respect to the second initialization signal line Vinit2.

As shown in FIG. 20, the pixel driving circuit further includes a driving transistor T3 and a first transistor T1. A first electrode of the first transistor T1 is connected to the first initialization signal line Vinit1, and a second electrode of the first transistor Tl is connected to the second electrode of the driving transistor T3. The display panel includes multiple rows of pixel driving circuit row groups CP, and the multiple rows of pixel driving circuit row groups CP are distributed in the column direction Y, and two pixel driving circuit rows PH, which are located in different pixel driving circuit row groups CP and are adjacent, share the same first initialization signal line Vinit1.

As shown in FIG. 20, the structure of the pixel driving circuit Pix may be as shown in FIG. 1, and accordingly, the second initialization signal line Vinit2 may be used to provide the second initialization signal terminal in FIG. 1, and the first initialization signal line Vinit1 may be used to provide the first initialization signal terminal in FIG. 1.

As shown in FIG. 20, the orthographic projections of two adjacent pixel driving circuits Pix in the same pixel driving circuit row PH on the base substrate may be arranged in mirror symmetry with respect to a second symmetry axis, and the second symmetry axis extends along the column direction Y. This arrangement can also improve the integration of the display panel.

As shown in FIG. 20, two adjacent pixel driving circuit rows PH in the same pixel driving circuit row group CP can share the same third initialization signal line. This arrangement can reduce the number of lines and via holes in the display panel, thereby improving the manufacturing yield of the display panel.

It should be understood that in other example embodiments, the pixel driving circuit Pix may also have other structures. For example, the pixel driving circuit Pix may not include the eighth transistor T8. For another example, one or more of the first transistor T1, the fourth transistor T4, the fifth transistor T5, the sixth transistor T6, the seventh transistor T7, and the eighth transistor T8 may be N-type transistor(s), and the second transistor T2 may also be a P-type transistor. For another example, the second electrode of the first transistor T1 may be directly connected to the node N.

In addition, in other example embodiments, the orthographic projections of two adjacent pixel driving circuit rows PH in the same pixel driving circuit row group CP on the base substrate may also be partially arranged in mirror symmetry with respect to the first symmetry axis. Similarly, the orthographic projections of two adjacent pixel driving circuits Pix in the same pixel driving circuit row PH on the base substrate may also be at least partially arranged in mirror symmetry with respect to the second symmetry axis.

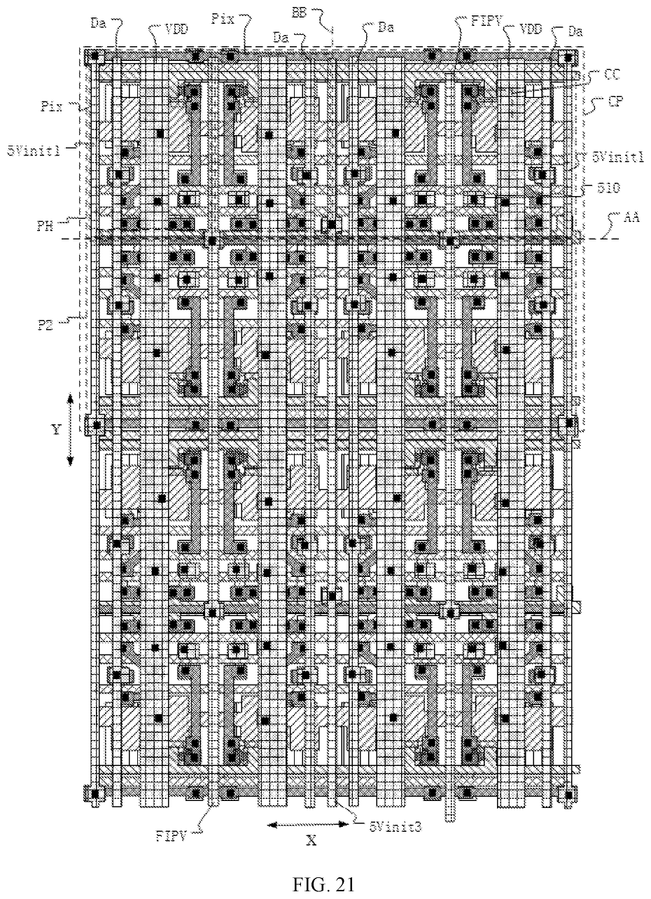

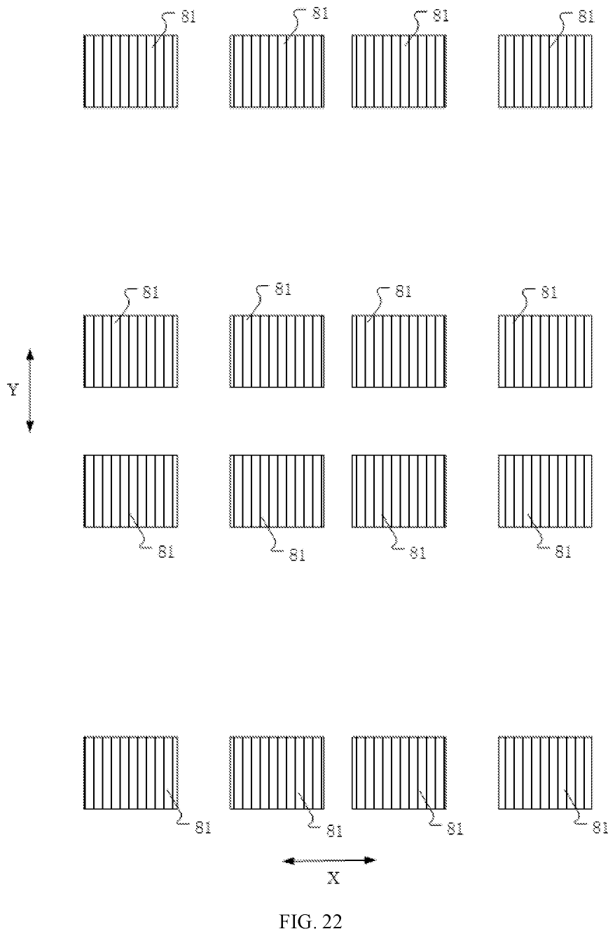

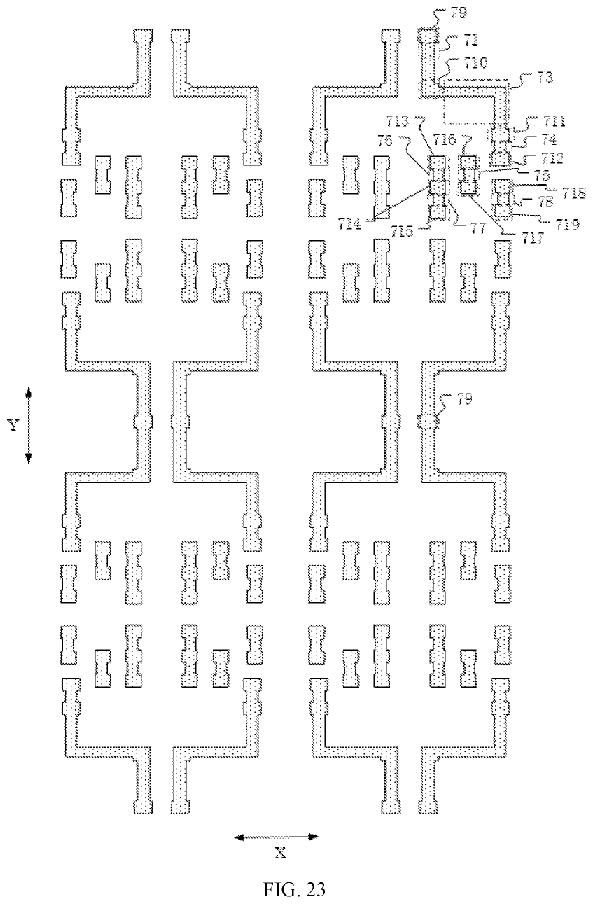

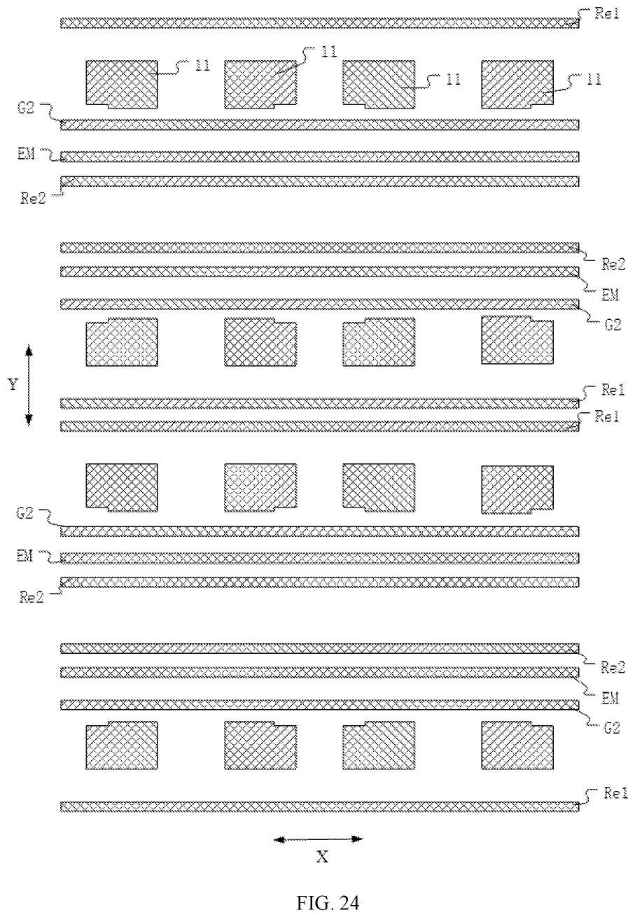

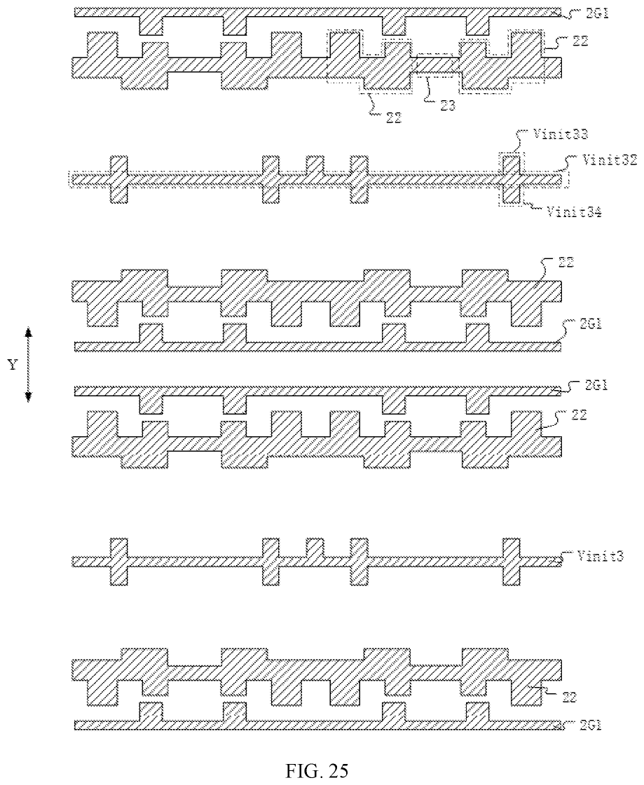

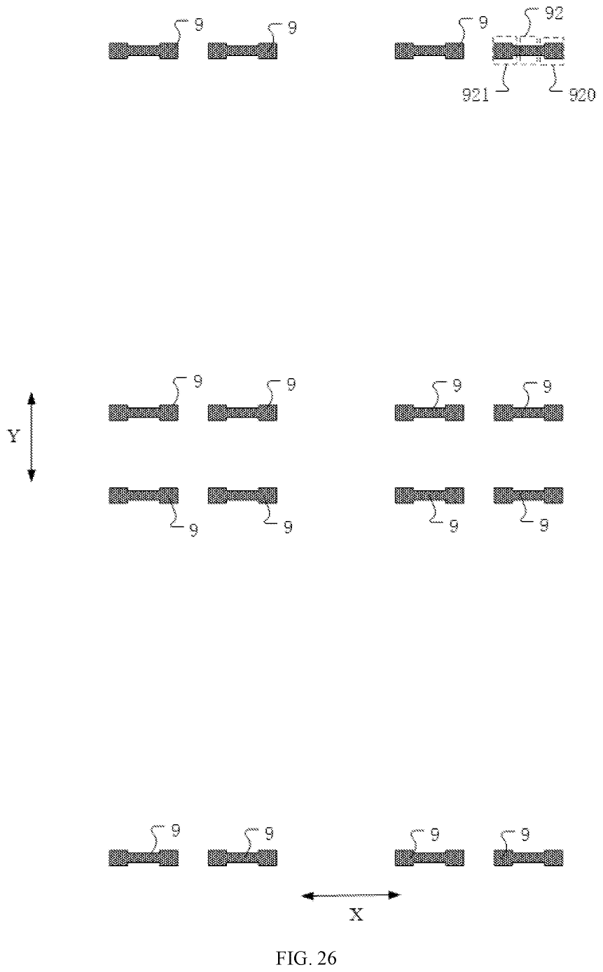

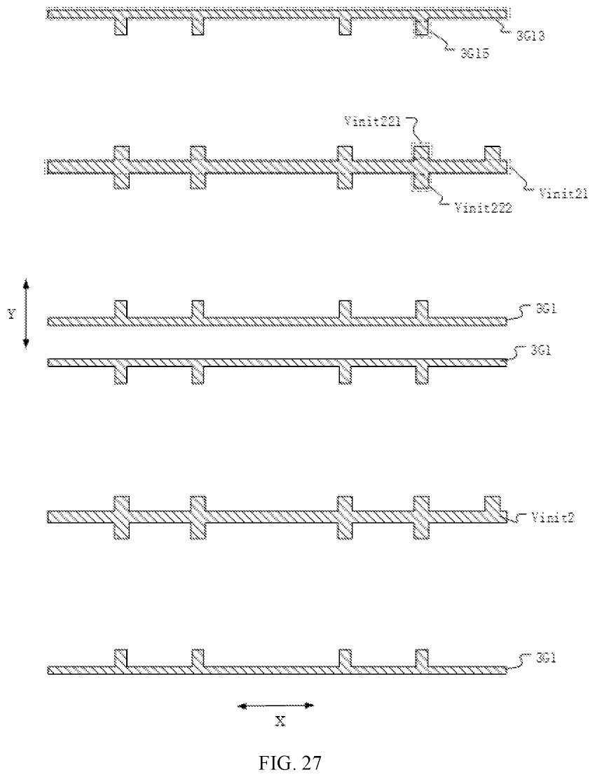

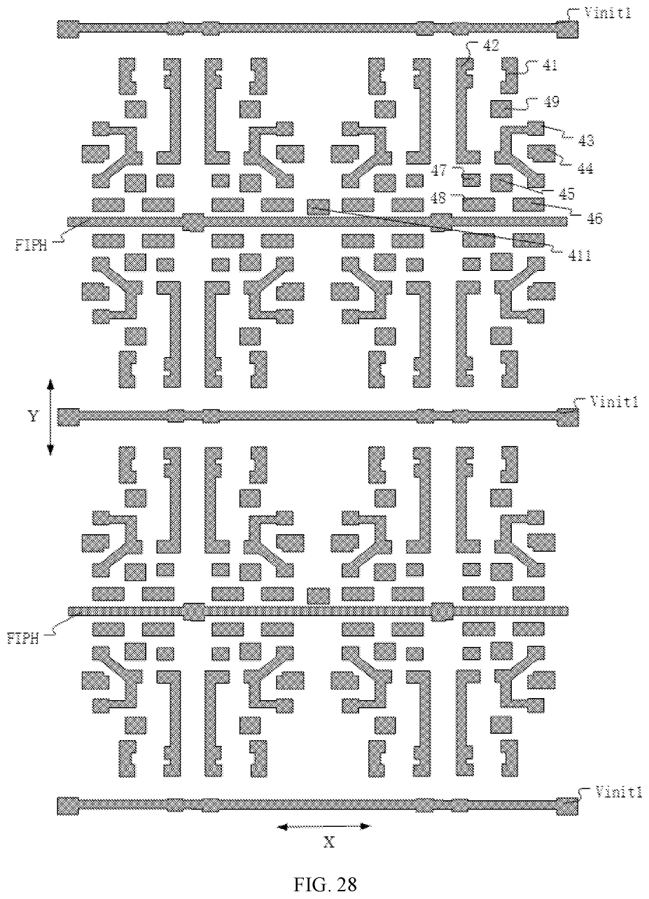

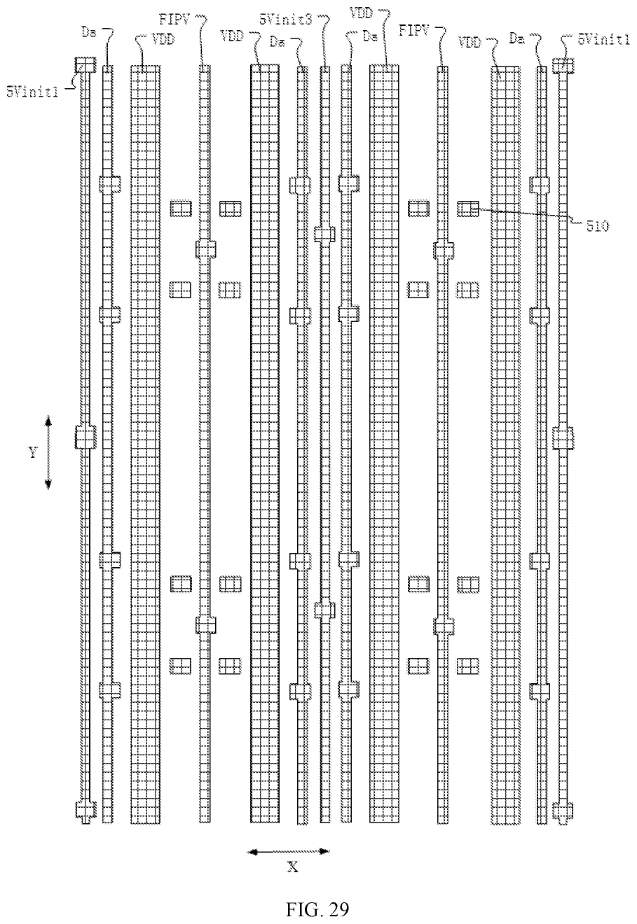

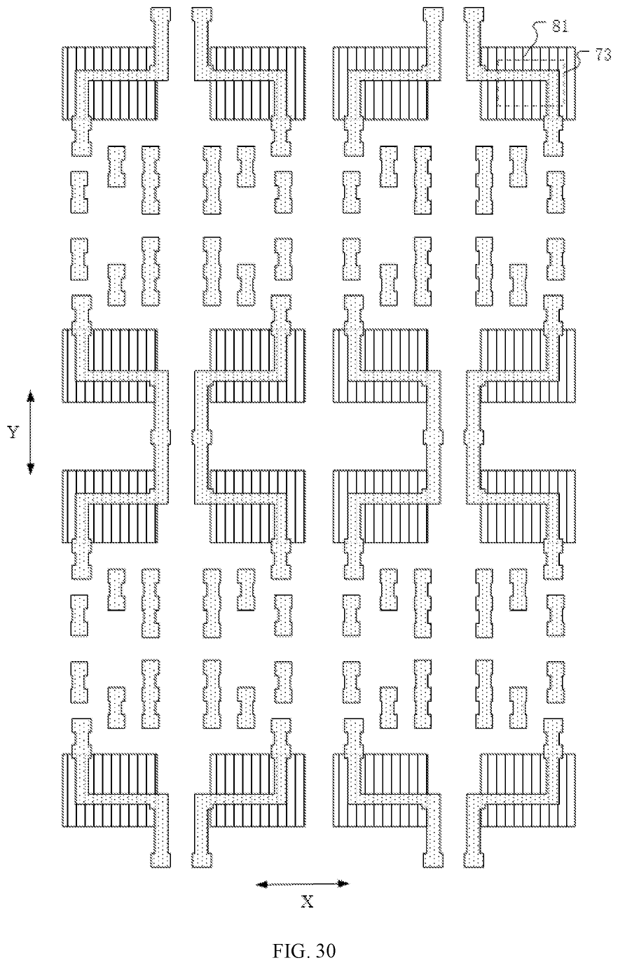

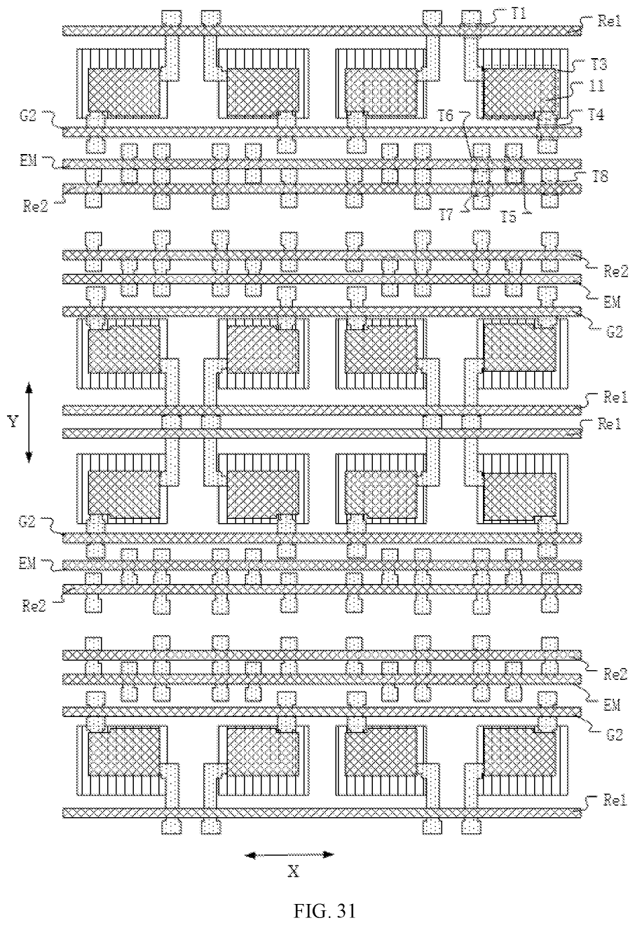

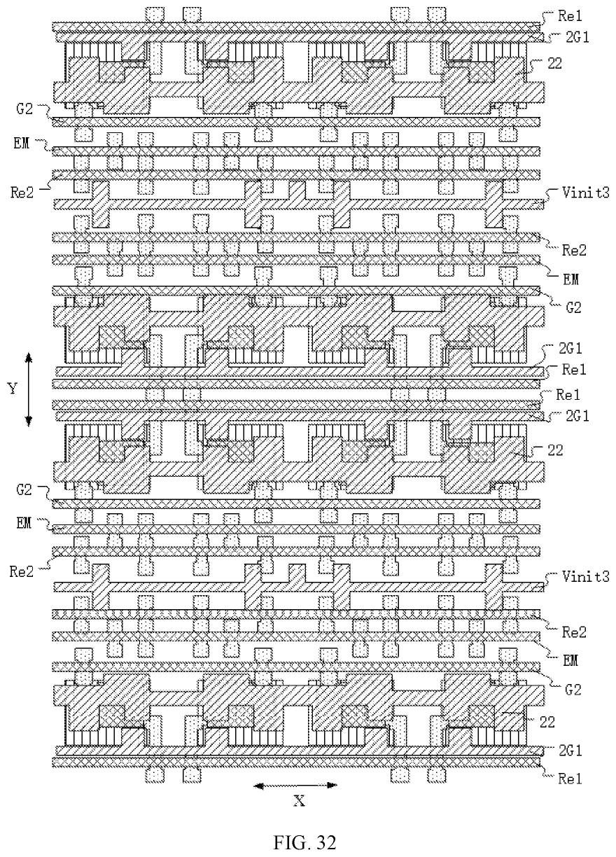

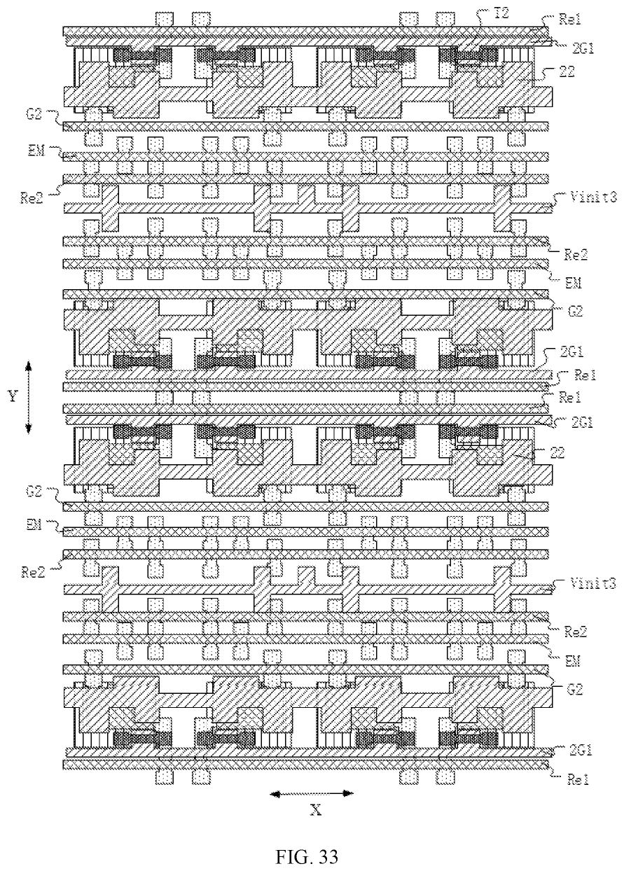

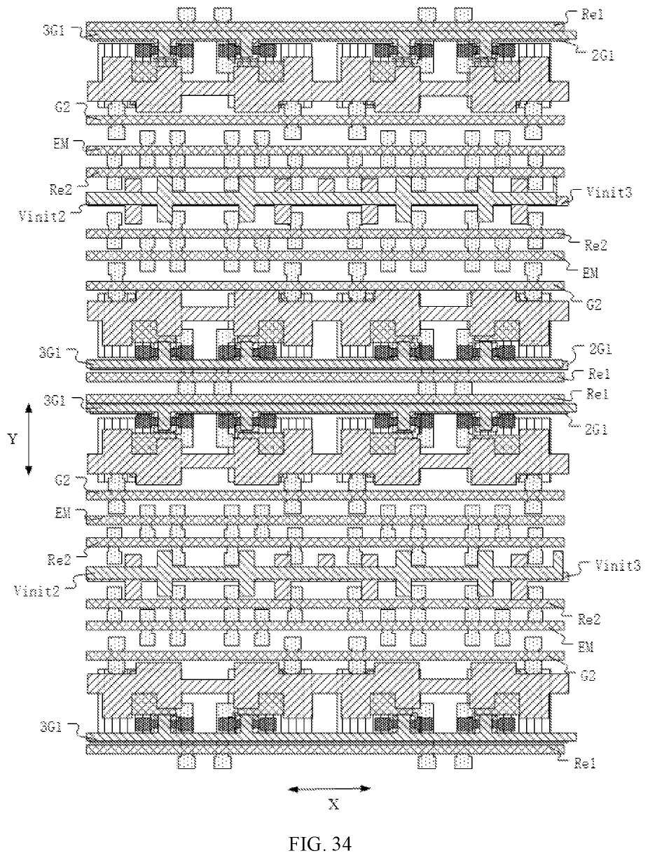

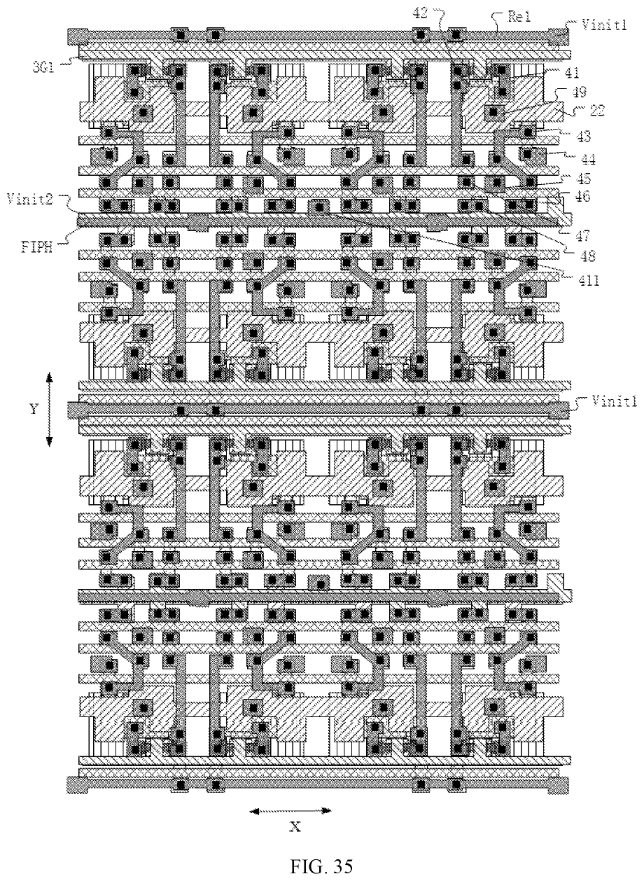

The display panel shown in FIG. 20 may include a base substrate, a shielding layer, a first active layer, a first conductive layer, a second conductive layer, a second active layer, a third conductive layer, a fourth conductive layer, and a fifth conductive layer which are stacked in sequence. An insulating layer may be provided between adjacent layers among the above layers. As shown in FIGS. 21 to 35, FIG. 21 is a structural layout diagram of a display panel according to an embodiment of the present disclosure. FIG. 22 is a structural layout diagram of a shielding layer in FIG. 21. FIG. 23 is a structural layout diagram of a first active layer in FIG. 21. FIG. 24 is a structural layout diagram of a first conductive layer in FIG. 21. FIG. 25 is a structural layout diagram of a second conductive layer in FIG. 21. FIG. 26 is a structural layout diagram of a second active layer in FIG. 21. FIG. 27 is a structural layout diagram of a third conductive layer in FIG. 21. FIG. 28 is a structural layout diagram of a fourth conductive layer in FIG. 21. FIG. 29 is a structural layout diagram of a fifth conductive layer in FIG. 21. FIG. 30 is a structural layout diagram of the shielding layer and the first active layer in FIG. 21. FIG. 31 is a structural layout diagram of the shielding layer, the first active layer, and the first conductive layer in FIG. 21. FIG. 32 is a structural layout diagram of the shielding layer, the first active layer, the first conductive layer, and the second conductive layer in FIG. 21. FIG. 33 is a structural layout diagram of the shielding layer, the first active layer, the first conductive layer, the second conductive layer, and the second active layer in FIG. 21. FIG. 34 is a structural layout diagram of the shielding layer, the first active layer, the first conductive layer, the second conductive layer, the second active layer, and the third conductive layer in FIG. 21. FIG. 35 is a structural layout diagram of the shielding layer, the first active layer, the first conductive layer, the second conductive layer, the second active layer, the third conductive layer, and the fourth conductive layer in FIG. 21.

As shown in FIGS. 21 to 35, the orthographic projections of two adjacent pixel driving circuit rows PH in the same pixel driving circuit row group CP on the base substrate may be at least partially arranged in mirror symmetry with respect to the first symmetry axis AA. The orthographic projections of two adjacent pixel driving circuits in the same pixel driving circuit row PH on the base substrate may be at least partially arranged in mirror symmetry with respect to the second symmetry axis BB.

As shown in FIGS. 21, 22, and 30, the shielding layer may include a plurality of shielding portions 81, and the plurality of shielding portions 81 are distributed in an array in the row direction X and the column direction Y. It should be understood that in other example embodiments, the display panel may not include the shielding layer.

As shown in FIGS. 21, 23, 31 and 32, the first active layer may include a first active portion 71, a third active portion 73, a fourth active portion 74, a fifth active portion 75, a sixth active portion 76, a seventh active portion 77, an eighth active portion 78, a ninth active portion 79, a tenth active portion 710, an eleventh active portion 711, a twelfth active portion 712, a thirteenth active portion 713, a fourteenth active portion 714, a fifteenth active portion 715, a sixteenth active portion 716, a seventeenth active portion 717, an eighteenth active portion 918, and a nineteenth active portion 719. The first active portion 71 is used to form a channel region of the first transistor T1. The third active portion 73 may be used to form a channel region of the driving transistor T3. The fourth active portion 74 may be used to form a channel region of the fourth transistor T4. The fifth active portion 75 may be used to form a channel region of the fifth transistor T5. The sixth active portion 76 may be used to form a channel region of the sixth transistor T6. The seventh active portion 77 may be used to form a channel region of the seventh transistor T7. The eighth active portion 78 may be used to form a channel region of the eighth transistor T8. The ninth active portion 79 is connected to an end of the first active portion 71 away from the third active portion 73, and in two adjacent pixel driving circuit rows sharing the same first initialization signal line Vinit1, the ninth active portion 79 is connected between two first active portions 71 in the two adjacent pixel driving circuit rows. The tenth active portion 710 is connected between the first active portion 71 and the third active portion 73. The eleventh active portion 711 is connected between the third active portion 73 and the fourth active portion 74. The twelfth active portion 712 is connected to an end of the fourth active portion 74 away from the third active portion 73. The thirteenth active portion 713 is connected to an end of the sixth active portion away from the seventh active portion 77. The fourteenth active portion 714 is connected between the sixth active portion 76 and the seventh active portion 77. The fifteenth active portion 715 is connected to an end of the seventh active portion 77 away from the sixth active portion 76. The sixteenth active portion 716 and the seventeenth active portion 717 are connected to both ends of the fifth active portion 75. The eighteenth active portion 718 and the nineteenth active portion 719 are connected to both ends of the eighth active portion 78. In an example embodiment, the first active layer may be formed of a polysilicon material, and accordingly, the first transistor T1, the driving transistor T3, the fourth transistor T4, the fifth transistor T5, the sixth transistor T6, the seventh transistor T7, and the eighth transistor T8 may be P-type low temperature polysilicon thin film transistors.

In an example embodiment, as shown in FIGS. 21, 23, 31, and 32, the third active portion 73 is “L”-shaped. It should be understood that in other example embodiments, the third active portion 73 may also be other shape(s), for example, the third active portion 73 may also be “π”-shaped, “I”-shaped, etc.

It should be noted that in other example embodiments, shielding portions adjacent to each other in the row direction X may be connected by a connection portion located in the shielding layer, and shielding portions adjacent to each other in the column direction Y may be connected by a connection portion located in the shielding layer. This arrangement can form a grid structure of the shielding layer. The shielding layer may also be connected to a stable power supply terminal. For example, the shielding layer may be connected to a stable voltage terminal, such as the first power supply terminal VDD, the first initialization signal terminal Vinit1, the second initialization signal terminal Vinit2, or the third initialization signal terminal Vinit3 in FIG. 1. The shielding portion 81 can shield the noise influence of other signal(s) on the driving transistor T3.

As shown in FIGS. 21, 24 and 32, the first conductive layer may include: a first conductive portion 11, a second gate line G2, an enable signal line EM, a first reset signal line Re1, and a second reset signal line Re2. The second gate line G2 may be used to provide the second gate driving signal terminal in FIG. 1. The enable signal line EM may be used to provide the enable signal terminal in FIG. 1. The first reset signal line Re1 may be used to provide the first reset signal terminal in FIG. 1. The second reset signal line Re2 may be used to provide the second reset signal terminal in FIG. 1. The orthographic projection of the second gate line G2 on the base substrate, the orthographic projection of the enable signal line EM on the base substrate, the orthographic projection of the first reset signal line Re1 on the base substrate, and the orthographic projection of the second reset signal line Re2 on the base substrate may all extend along the row direction X. The orthographic projection of the second gate line G2 on the base substrate covers the orthographic projection of the fourth active portion 74 on the base substrate, and a partial structure of the second gate line G2 is used to form the gate of the fourth transistor. The orthographic projection of the enable signal line EM on the base substrate covers the orthographic projection of the fifth active portion 75 on the base substrate and the orthographic projection of the sixth active portion 76 on the base substrate, and a partial structure of the enable signal line EM may be used to form the gates of the fifth transistor T5 and the sixth transistor T6, respectively. The orthographic projection of the first reset signal line Re1 on the base substrate may cover the orthographic projection of the first active portion 71 on the base substrate, and a partial structure of the first reset signal line Re1 is used to form the gate of the first transistor T1. The orthographic projection of the second reset signal line Re2 on the base substrate may cover the orthographic projection of the seventh active portion 77 on the base substrate and the orthographic projection of the eighth active portion 78 on the base substrate, and a partial structure of the second reset signal line Re2 may be used to form the gates of the seventh transistor T7 and the eighth transistor T8, respectively. The orthographic projection of the first conductive portion 11 on the base substrate covers the orthographic projection of the third active portion 73 on the base substrate, and the first conductive portion 11 may be used to form the gate of the driving transistor T3, and meanwhile the first conductive portion 11 may be reused as the first electrode of the capacitor C. In the same pixel driving circuit, the orthographic projection of the first conductive portion 11 on the base substrate is located between the orthographic projection of the first reset signal line Re1 on the base substrate and the orthographic projection of the second gate line G2 on the base substrate. The orthographic projection of the enable signal line EM on the base substrate is located at a side of the orthographic projection of the second gate line G2 on the base substrate away from the orthographic projection of the first conductive portion 11 on the base substrate. The orthographic projection of the second reset signal line Re2 on the base substrate is located at a side of the orthographic projection of the enable signal line EM on the base substrate away from the orthographic projection of the first conductive portion 11 on the base substrate. In the display panel, the first conductive layer may be used as a mask to perform a process on the first active layer to make a part of the first active layer behave like a conductor, that is, a region of the first active layer covered by the first conductive layer may form a channel region of a transistor, and a region of the first active layer not covered by the first conductive layer forms a conductor structure.

As shown in FIGS. 21, 25 and 33, the second conductive layer may include: a third gate line 2G1, a second conductive portion 22, and a third initialization signal line Vinit3. The orthographic projection of the third gate line 2G1 on the base substrate extends along the row direction X, and the third gate line 2G1 may be used to provide the first gate driving signal terminal in FIG. 1. The orthographic projection of the second conductive portion 22 on the base substrate may at least partially overlap with the orthographic projection of the first conductive portion 11 on the base substrate, and the second conductive portion 22 is used to form the second electrode of the capacitor C. The second conductive layer may also include a second connection portion 23. Second conductive portions 22 which are adjacent to each other in the row direction X may be connected through a second connection portion 23. The third initialization signal line Vinit3 may be used to provide the third initialization signal terminal Vinit3 in FIG. 1, and the orthographic projection of the third initialization signal line Vinit3 on the base substrate may extend along the row direction X. The orthographic projection of the third initialization signal line Vinit3 on the base substrate is at least partially located between the orthographic projection of a second reset signal line Re2 in the current row of pixel driving circuits on the base substrate and the orthographic projection of a second reset signal line Re2 in a next adjacent row of pixel driving circuits on the base substrate. This arrangement can reduce the parasitic capacitance between the third initialization signal line Vinit3 and the enable signal line EM, or the second conductive portion 22 or other structure(s), thereby improving the display effect of the display panel. In addition, two adjacent rows of pixel driving circuits in the same repeating unit can share the same third initialization signal line Vinit3. This arrangement can reduce the number of lines and via holes in the display panel, thereby improving the integration, pixel density, and manufacturing yield of the display panel. As shown in FIGS. 21, 25 and 33, the third initialization signal line Vinit3 may include: a second main body portion Vinit32, a third protrusion Vinit33 and a fourth protrusion Vinit34. The orthographic projection of the second main body portion Vinit32 on the base substrate may extend along the row direction X. The third protrusion Vinit33 and the fourth protrusion Vinit34 are located at both sides of the second main body portion Vinit32 in the column direction Y, respectively. The orthographic projection of the second main body portion Vinit32 on the base substrate is located between the orthographic projection of a second reset signal line Re2 in a current row of pixel driving circuits on the base substrate and the orthographic projection of a second reset signal line Re2 in a next adjacent row of pixel driving circuits on the base substrate. The third initialization signal line Vinit3 may be connected to two pixel driving circuit rows PH sharing the third initialization signal line Vinit3 through the third protrusion Vinit33 and the fourth protrusion Vinit34, respectively.

As shown in FIGS. 21, 26 and 34, the second active layer may include an active portion 9. The active portion 9 may include: a second active portion 92, and a twentieth active portion 920 and a twenty-first active portion 921 connected to both ends of the second active portion 92. The second active portion 92 is used to form a channel region of the second transistor T2. The second active layer may be formed of indium gallium zinc oxide, and accordingly, the second transistor T2 may be an N-type metal oxide thin film transistor. The orthographic projection of the third gate line 2G1 on the base substrate may cover the orthographic projection of the second active portion 92 on the base substrate, and a partial structure of the third gate line 2G1 may be used to form a bottom gate of the second transistor T2. In addition, the twentieth active portion 920, the second active portion 92, and the twenty-first active portion 921 may be distributed in the row direction X.

As shown in FIGS. 21, 27 and 35, the third conductive layer may include a first gate line 3G1 and a second initialization signal line Vinit2. The orthographic projection of the first gate line 3G1 on the base substrate and the orthographic projection of the second initialization signal line Vinit2 on the base substrate may both extend along the row direction X. The first gate line 3G1 may be used to provide the first gate driving signal terminal in FIG. 1. The first gate line 3G1 includes a third main body portion 3G13 and a fifth protrusion 3G15 connected to a side of the third main body portion 3G13 in the column direction. The orthographic projection of the third main body portion 3G13 on the base substrate extends along the row direction X. The orthographic projection of the fifth protrusion 3G15 on the base substrate covers the orthographic projection of the second active portion 92 on the base substrate. A partial structure of the fifth protrusion 3G15 may be used to form a top gate of the second transistor T2. Also, the first gate line 3G1 may be connected to the third gate line 2G 1 through a via hole located in the frame region of the display panel. The second initialization signal line Vinit2 may be used to provide the second initialization signal terminal in FIG. 1. As shown in FIGS. 21, 27 and 35, the orthographic projection of the second initialization signal line Vinit2 on the base substrate at least partially overlaps with the orthographic projection of the third initialization signal line Vinit3 on the base substrate. This arrangement can improve the transmittance of the display panel. As shown in FIGS. 21, 27 and 35, the second initialization signal line Vinit2 may include a first main body portion Vinit2 1, a first protrusion Vinit221 and a second protrusion Vinit222. The first protrusion Vinit221 and the second protrusion Vinit222 are connected to both sides of the first main body portion Vinit2 1 in the column direction, respectively. The orthographic projection of the first main body portion Vinit2 1 on the base substrate may extend along the row direction X and at least partially overlap with the orthographic projection of the third initialization signal line Vinit3 on the base substrate. In two pixel driving circuit rows that share the same second initialization signal line Vinit2, the first main body portion Vinit21 is connected to the two pixel driving circuit rows PH through the first protrusion Vinit221 and the second protrusion Vinit222, respectively.

In addition, in the display panel, the third conductive layer may be used as a mask to perform a process on the second active layer to make a part of the second active layer behave like a conductor, that is, a region of the second active layer covered by the third conductive layer may form a channel region of a transistor, and a region of the second active layer not covered by the third conductive layer forms a conductor structure.

As shown in FIGS. 21, 28 and 36, the fourth conductive layer may include a first bridging portion 41, a second bridging portion 42, a third bridging portion 43, a fourth bridging portion 44, a fifth bridging portion 45, a sixth bridging portion 46, a seventh bridging portion 47, an eighth bridging portion 48, a ninth bridging portion 49, a first initialization signal line Vinit1, a first fan-out line FIPH, and an eleventh bridging portion 411. The first bridging portion 41 may be connected to the twentieth active portion 720 and the first conductive portion 11 through via holes, respectively, so as to connect the first electrode of the second transistor T2 and the gate of the driving transistor T3. The second bridging portion 42 may be connected to the twenty-first active portion 721, the tenth active portion 710 and the thirteenth active portion 713 through via holes, respectively, so as to connect the second electrode of the second transistor T2, the second electrode of the first transistor T1 and the first electrode of the sixth transistor T6. The third bridging portion 43 may be connected to the eleventh active portion 711, the sixteenth active portion 716, and the eighteenth active portion 718 through via holes, respectively, to connect the second electrode of the fourth transistor T4, the second electrode of the eighth transistor T8, the second electrode of the fifth transistor T5, and the first electrode of the driving transistor T3. The fourth bridging portion 44 may be connected to the twelfth active portion 712 through a via hole to connect the first electrode of the fourth transistor T4. The fifth bridging portion 45 may be connected to the seventeenth active portion 717 through a via hole to connect the first electrode of the fifth transistor. The sixth bridging portion 46 may be connected to the nineteenth active portion 719 and the third initialization signal line Vinit3 through via holes, respectively, to connect the first electrode of the eighth transistor T8 and the third initialization signal terminal. The seventh bridging portion 47 may be connected to the fourteenth active portion 714 through a via hole to connect the second electrode of the sixth transistor T6 and the second electrode of the seventh transistor T7. The eighth bridging portion 48 may be connected to the second initialization signal line Vinit2 and the fifteenth active portion 715 through via holes to connect the first electrode of the seventh transistor T7 and the second initialization signal terminal. The ninth bridging portion 49 is connected to the second conductive portion 22 through a via hole. The eleventh bridging portion 411 may be connected to the third initialization signal line Vinit3 through a via hole.

The first initialization signal line Vinit1 may be used to provide the first initialization signal terminal in FIG. 1, and the orthographic projection of the first initialization signal line Vinit1 on the base substrate extends along the row direction X. And in the same pixel driving circuit, the orthographic projection of the first initialization signal line Vinit1 on the base substrate is located at a side of the orthographic projection of the first reset signal line Re1 on the base substrate away from the orthographic projection of the first conductive portion 11 on the base substrate. This arrangement can reduce the parasitic capacitance between the first initialization signal line Vinit1 and the enable signal line EM, or the first reset signal line Re1 or other alternating current signal line(s), thereby improving the voltage stability of the first initialization signal line Vinit1. The alternating current signal line is a signal line that outputs an alternating current signal.

In an example embodiment, as shown in FIGS. 21, 28 and 36, two pixel driving circuit rows PH, which are located in different pixel driving circuit row groups CP and are adjacent, share the same first initialization signal line Vinit1. This arrangement can also reduce the number of lines and via holes in the display panel, thereby improving the manufacturing yield of the display panel.

As shown in FIGS. 21, 28 and 37, the orthographic projection of the first fan-out line FIPH on the base substrate may extend along the row direction X, and the first fan-out line FIPH may be used as a row direction fan-out line connecting a data line in the FIP (Fanout In Pixel, fan-out region in a pixel).

In an example embodiment, the square resistance of the fourth conductive layer may be smaller than the square resistance of the first conductive layer, the second conductive layer, and the third conductive layer. In this example embodiment, the first initialization signal line Vinit1 is set in the fourth conductive layer, thereby reducing the voltage difference of the first initialization signal line Vinit1 at different positions of the display panel, and thus improving the display uniformity of the display panel. Similarly, in this example embodiment, the second initialization connection line 4Vinit2 is set in the fourth conductive layer, which can also reduce the voltage difference of the second initialization signal line Vinit2 at different positions of the display panel, thereby improving the display uniformity of the display panel.

As shown in FIGS. 21 and 29, the fifth conductive layer may include a tenth bridging portion 510, a data line Da, first power supply line(s) VDD, a second fan-out line FIPV, a first initialization connection line 5Vinit1, and a third initialization connection line 5Vinit3. The orthographic projection of the data line Da on the base substrate, the orthographic projection of the first power supply line(s) VDD on the base substrate, the orthographic projection of the second fan-out line FIPV on the base substrate, the orthographic projection of the first initialization connection line 5Vinit1 on the base substrate, and the orthographic projection of the third initialization connection line 5Vinit3 on the base substrate may all extend along the column direction Y. The data line Da is used to provide the data signal terminal in FIG. 1, and the first power supply line VDD is used to provide the first power supply terminal in FIG. 1. The data line Da may be connected to the fourth bridging portion 44 through a via hole to connect the data signal terminal and the first electrode of the fourth transistor T4. There may be a plurality of first power supply lines VDD, and the orthographic projections of the plurality of first power supply lines VDD on the base substrate extend along the column direction Y and are spaced apart along the row direction X. A first power supply line VDD may be connected, through a via hole, to a ninth bridging portion 49 whose orthographic projection on the base substrate intersects with the orthographic projection of the first power supply line VDD on the base substrate. The first power supply line(s) VDD and the second conductive portion(s) 22 connected in the row direction X may form a grid structure, which can reduce the voltage difference of the first power supply line(s) at different positions of the display panel, thereby improving the display uniformity of the display panel. In addition, the first power supply line VDD may also be connected to the fifth bridging portion 45 through a via hole to connect the first power supply terminal and the first electrode of the fifth transistor T5.

The second fan-out line FIPV may be used as a column direction fan-out line connecting a data line in FIP (Fanout In Pixel, fan-out region in a pixel). The first fan-out line and the second fan-out line may also be provided in a non-fan-out region of the display panel. In the non-fan-out region, the second fan-out line FIPV may be connected, through a via hole, to a first fan-out line FIPH which intersects with the second fan-out line FIPV, and the first fan-out line(s) FIPH and the second fan-out line(s) FIPV may form a grid structure. The grid structure may be connected to a common electrode layer in the display panel through a via hole. The common electrode layer may be used as the second electrode of the light-emitting unit. This arrangement can reduce the resistance of the common electrode layer, thereby reducing the voltage difference of the common electrode layer at different positions of the display panel, and thus improving the display uniformity of the display panel.

The first initialization connection line 5Vinit1 may be connected, through a via hole, to a first initialization signal line Vinit1 whose orthographic projection on the base substrate intersects with the orthographic projection of the first initialization connection line 5Vinit1 on the base substrate. This arrangement can make the first initialization signal line form a grid structure. The initialization signal line of the grid structure has relatively small resistance, thereby reducing the voltage difference of the first initialization signal line at different positions of the display panel, and thus improving the display uniformity of the display panel.

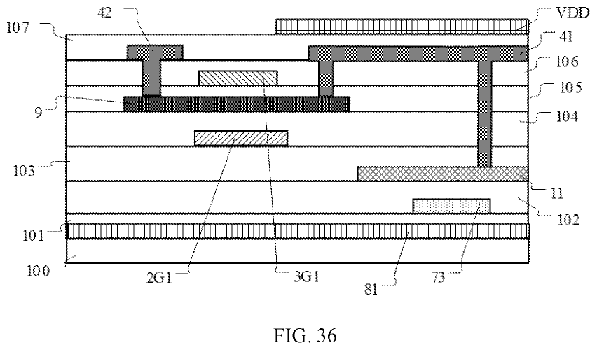

The third initialization connection line 5Vinit3 may be connected to the eleventh bridging portion 411 through a via hole to connect the third initialization signal line Vinit3 whose orthographic projection on the base substrate intersects with the orthographic projection of the third initialization connection line 5Vinit3 on the base substrates. This arrangement can make the third initialization signal line(s) form a grid structure. The initialization signal line of the grid structure has relatively small resistance, so that the voltage difference of the third initialization signal line(s) at different positions of the display panel can be reduced, thereby improving the display uniformity of the display panel. It should be understood that in other example embodiments, the display panel may not be provided with the eleventh bridging portion 411, and the third initialization connection line 5Vinit3 may also be directly connected to the third initialization signal line Vinit3 through a via hole. The tenth bridging portion 510 may be connected to the seventh bridging portion 47 through a via hole to connect the second electrode of the sixth transistor T6 and the second electrode of the seventh transistor T7. The tenth bridging portion 510 may also be connected to a pixel electrode in the pixel electrode layer through a via hole. The pixel electrode layer may be located at a side of the fifth conductive layer away from the base substrate. The pixel electrode may be used to form a first electrode of the light-emitting unit. As shown in FIG. 36, it is a partial cross-sectional view of the display panel shown in FIG. 21 cut along a dotted line CC. The display panel may also include a first insulating layer 101, a second insulating layer 102, a third insulating layer 103, a fourth insulating layer 104, a fifth insulating layer 105, a first dielectric layer 106, and a first planarization layer 108. The base substrate 100, the shielding layer, the first insulating layer 101, the first active layer, the second insulating layer 102, the first conductive layer, the third insulating layer 103, the second conductive layer, the fourth insulating layer 104, the second active layer, the fifth insulating layer 105, the third conductive layer, the first dielectric layer 106, the fourth conductive layer, the first planarization layer 108, and the fifth conductive layer are stacked in sequence. The first insulating layer 101, the second insulating layer 102, the third insulating layer 103, the fourth insulating layer 104, and the fifth insulating layer 105 may be a single-layer structure or a multi-layer structure, and the materials of the first insulating layer 101, the second insulating layer 102, the third insulating layer 103, the fourth insulating layer 104, and the fifth insulating layer 105 may be at least one of silicon nitride, silicon oxide, or silicon oxynitride. The first dielectric layer 106 may be a silicon nitride layer. The material of the first planarization layer 108 may be an organic material, such as polyimide (PI), polyethylene terephthalate (PET), polyethylene naphthalate (PEN), silicon-glass bonding structure (SOG, silicon on glass) and the like. The base substrate 100 may include a glass substrate, a blocking layer, and a polyimide layer stacked in sequence, and the blocking layer may be an inorganic material. The material of the first conductive layer, the second conductive layer, and the third conductive layer may be one of molybdenum, aluminum, copper, titanium, or niobium, or an alloy, or a conductive layer such as a molybdenum/titanium alloy or laminated molybdenum/titanium. The materials of the fourth conductive layer and the fifth conductive layer may include a metal material, for example, one of molybdenum, aluminum, copper, titanium, niobium or an alloy, or molybdenum/titanium alloy or laminated molybdenum/titanium, or a conductive layer such as laminated titanium/aluminum/titanium. The square resistance of any one of the fourth conductive layer and the fifth conductive layer may be smaller than the square resistance of any one of the first conductive layer, the second conductive layer, and the third conductive layer. In addition, the display panel may also include a pixel electrode layer located at a side of the sixth conductive layer away from the base substrate, a light-emitting unit layer located at a side of the pixel electrode layer away from the base substrate, and a common electrode layer located at a side of the light-emitting unit layer away from the base substrate. The light-emitting unit layer may include a light-emitting material layer, and the holes generated by the anode of the light-emitting unit and the electrons generated by the cathode may generate energy excitons when the holes and the electrons meet in the light-emitting material layer, thereby exciting the light-emitting molecules in the light-emitting material layer to generate visible light.

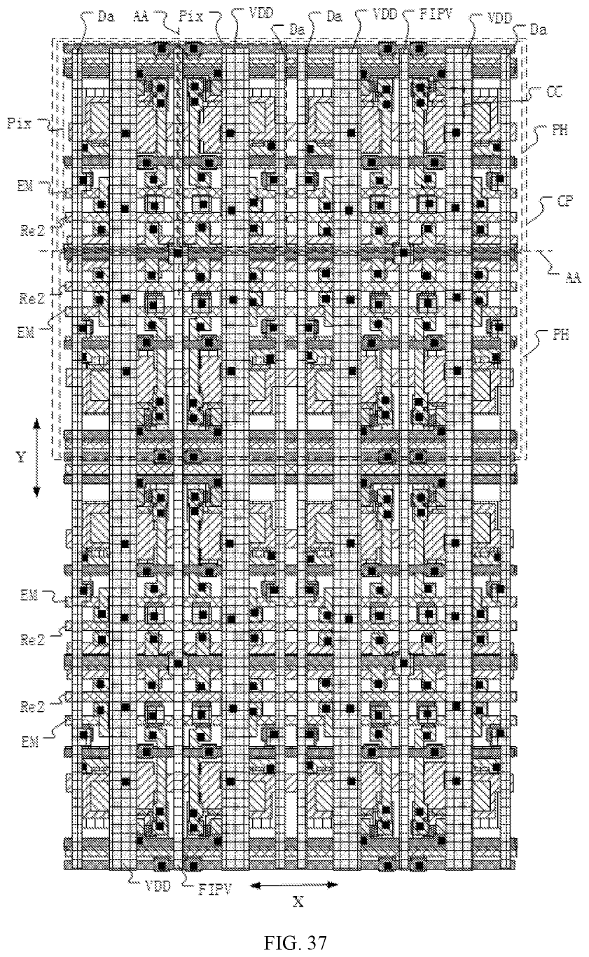

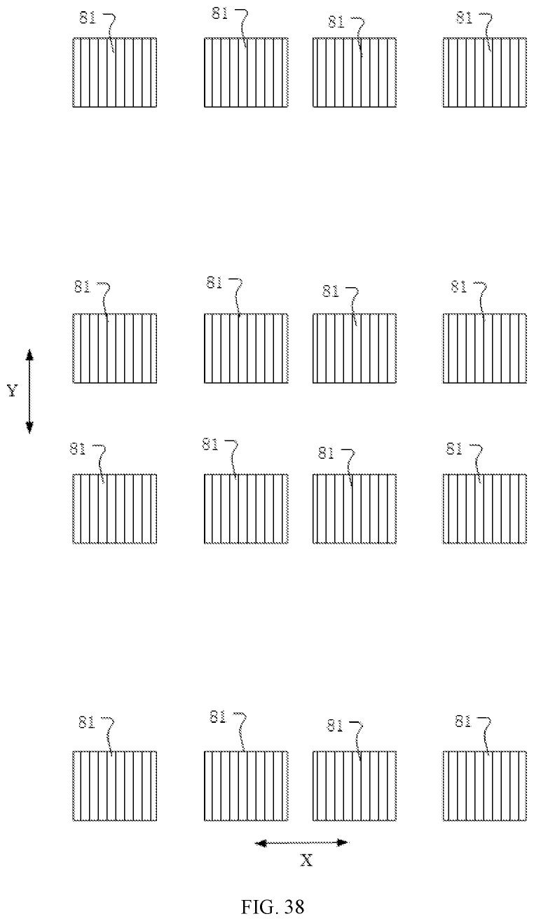

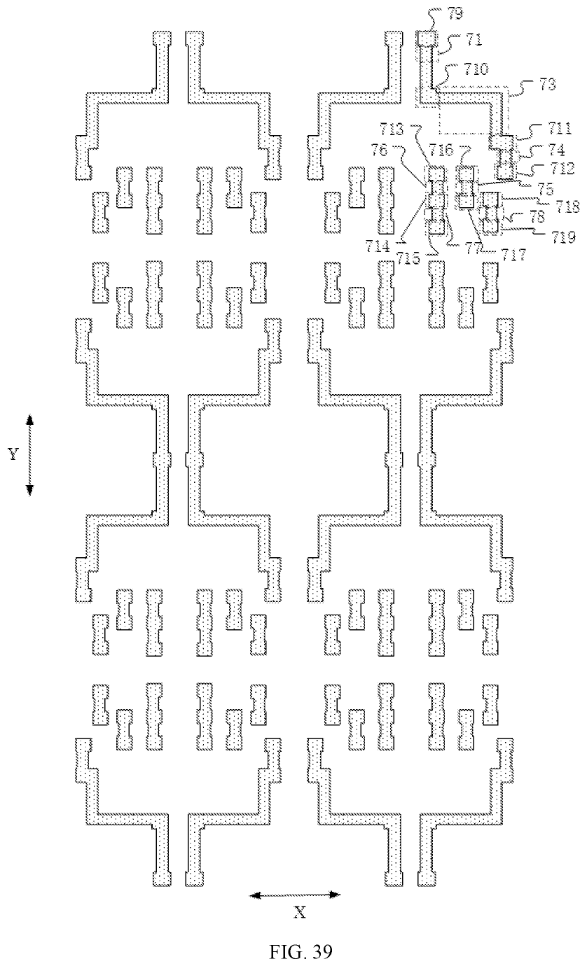

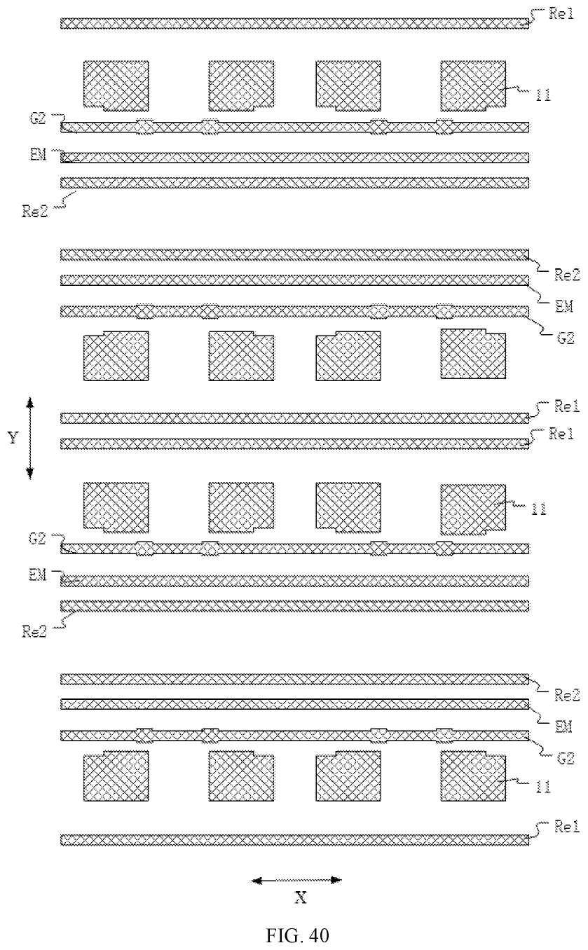

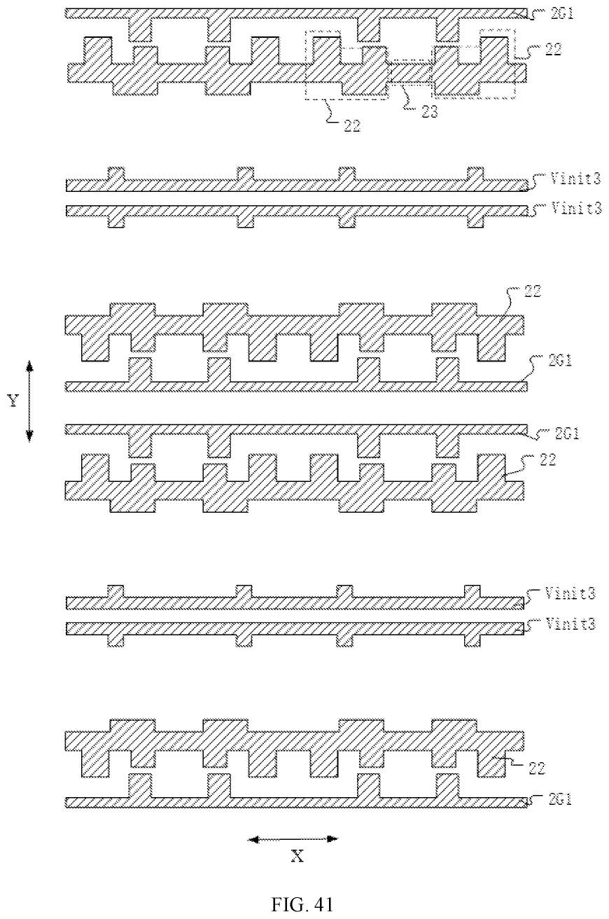

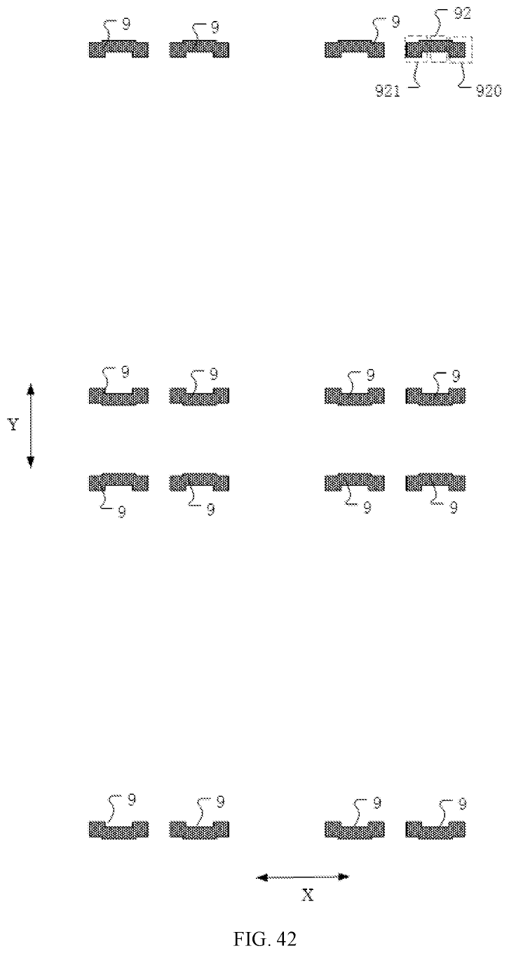

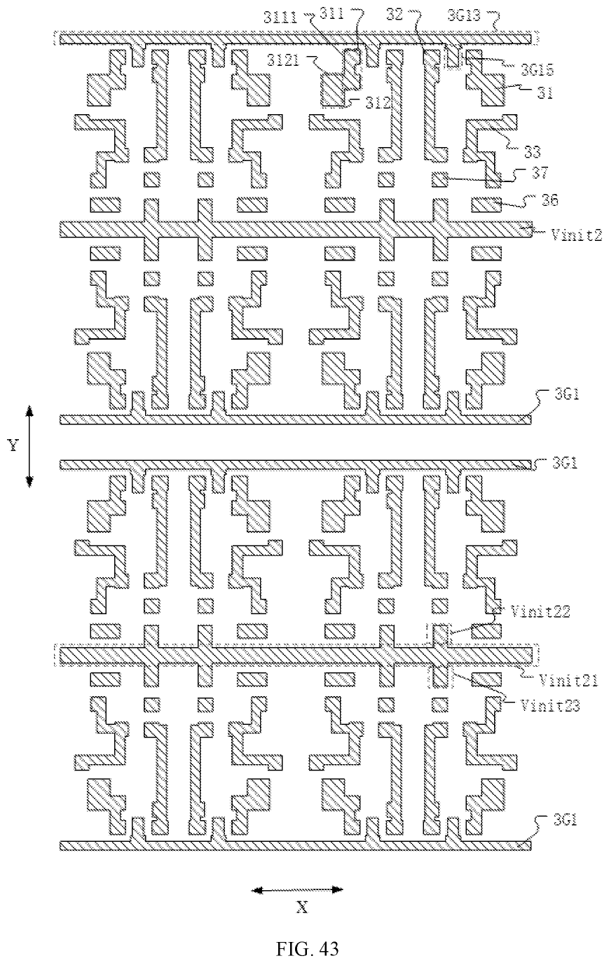

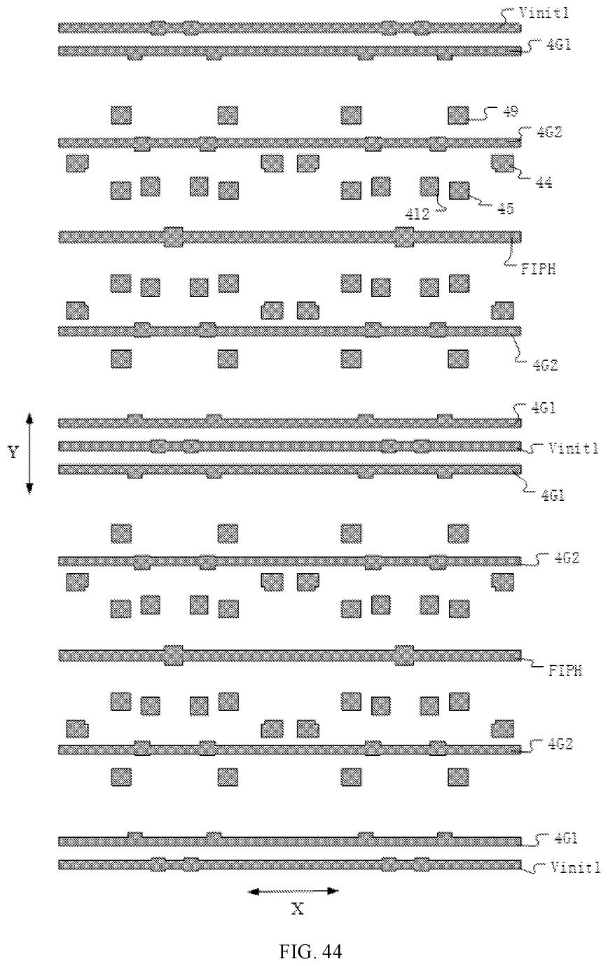

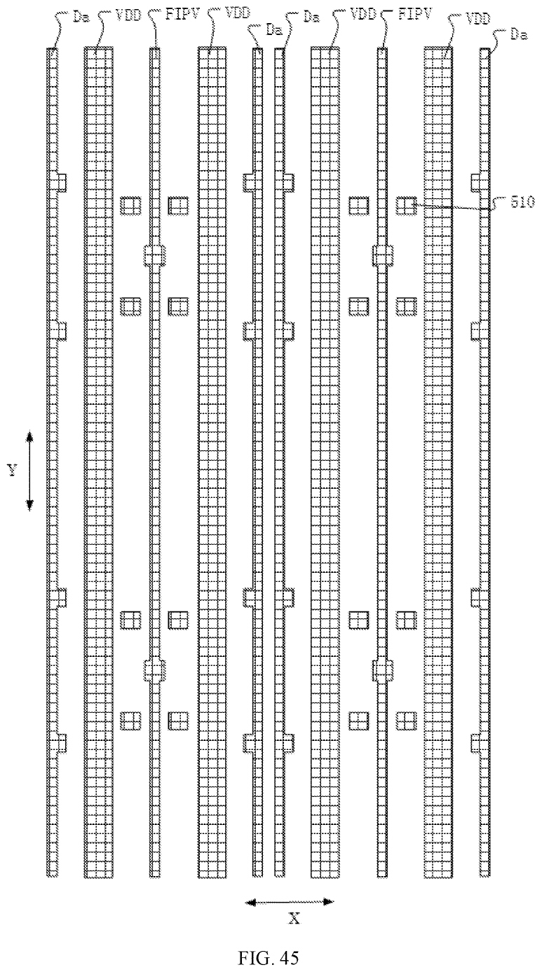

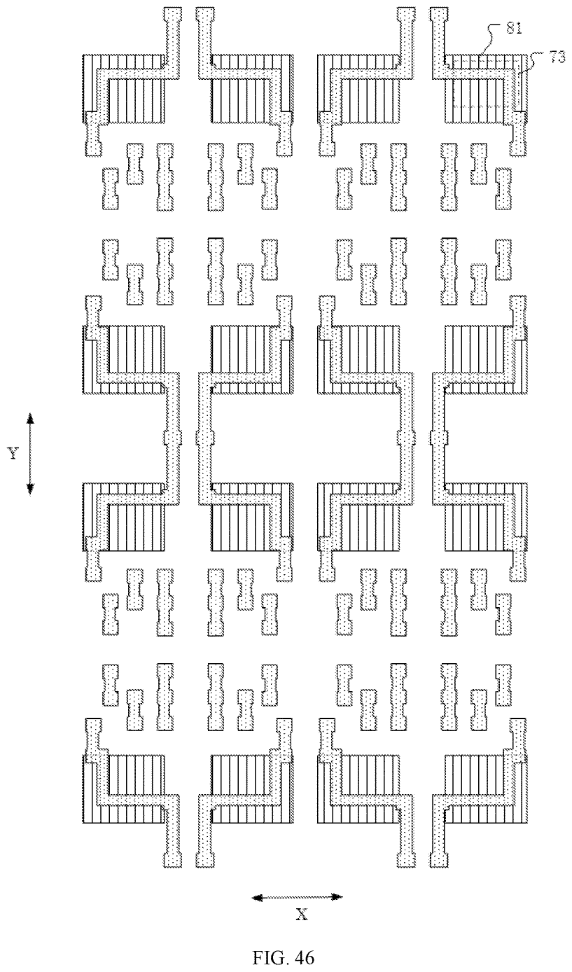

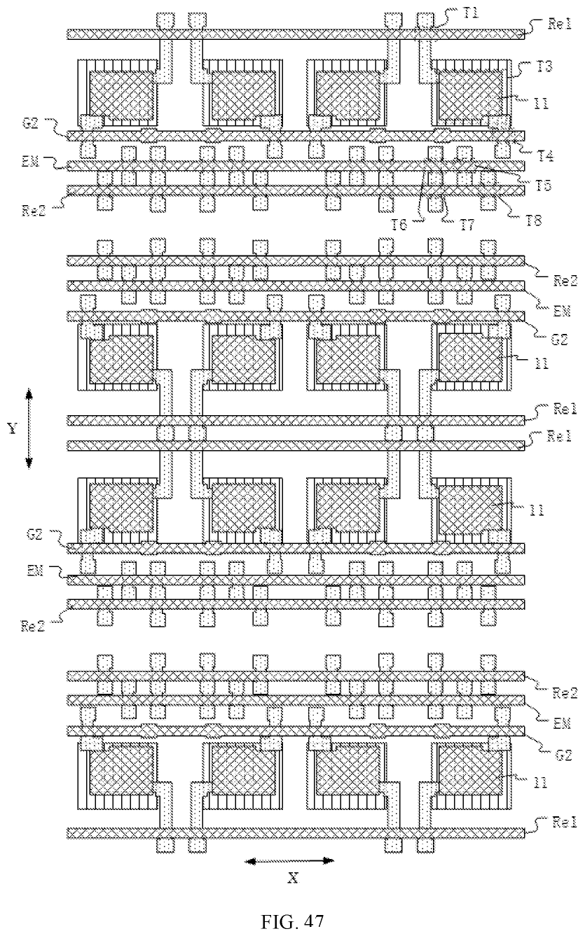

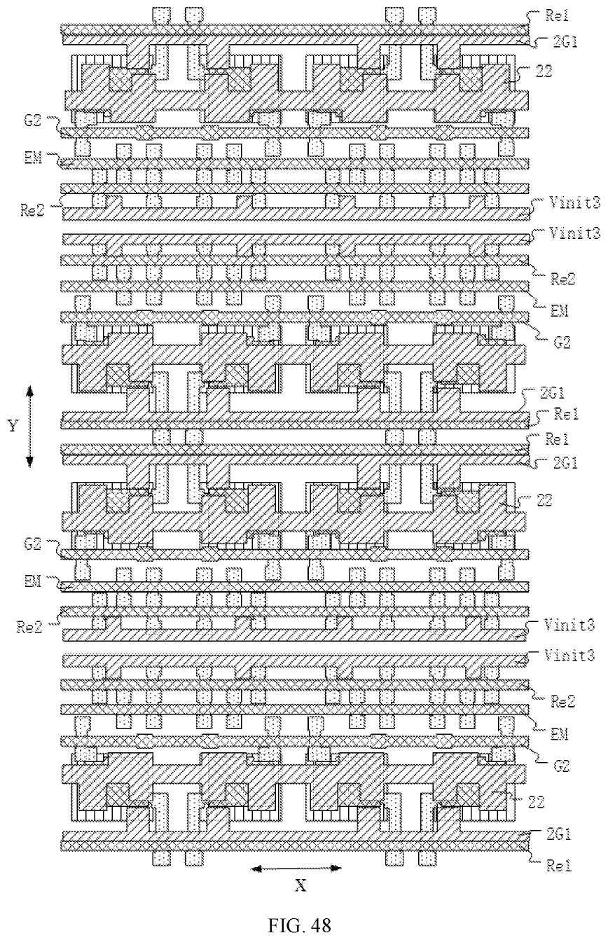

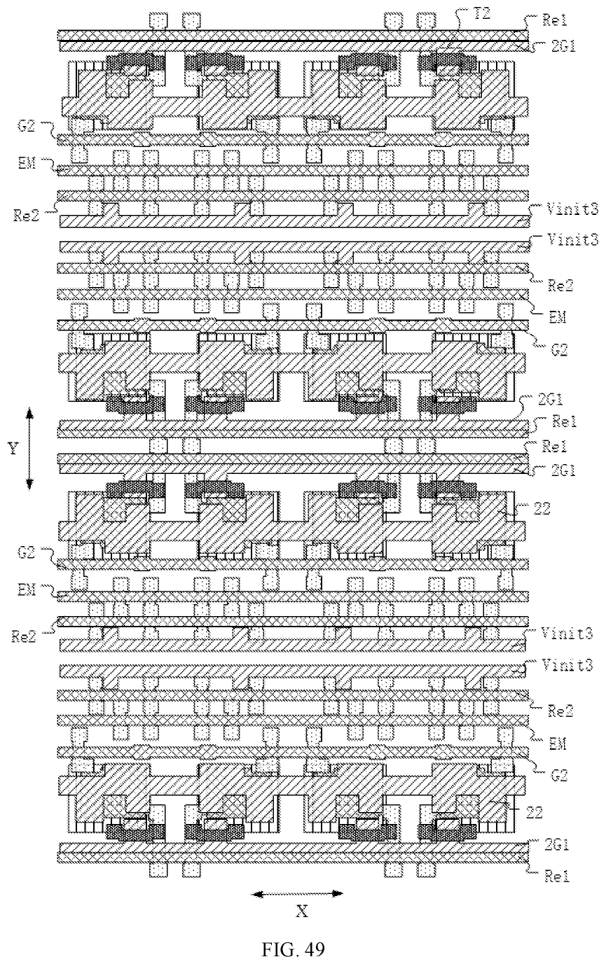

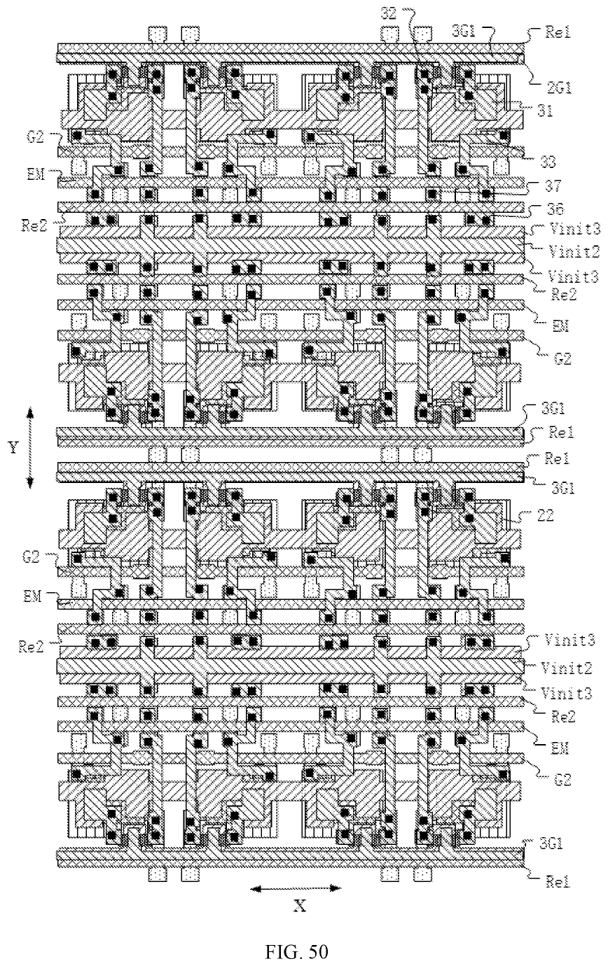

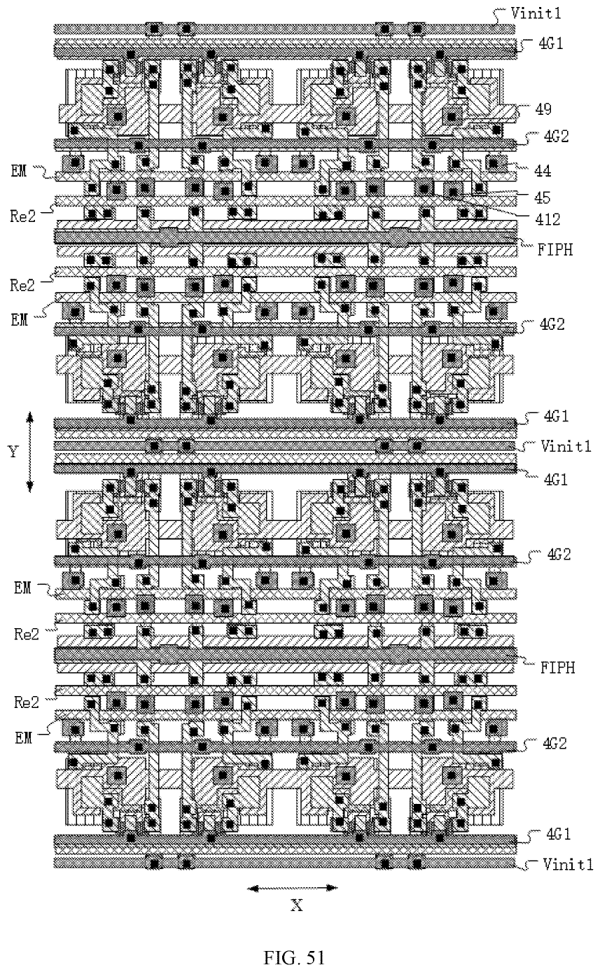

In an example embodiment, the display panel shown in FIG. 3 may also have other layout structure. As shown in FIGS. 37 to 51, FIG. 37 is a structural layout diagram of a display panel according to another example embodiment of the present disclosure. FIG. 38 is a structural layout diagram of a shielding layer in FIG. 37. FIG. 39 is a structural layout diagram of a first active layer in FIG. 37. FIG. 40 is a structural layout diagram of a first conductive layer in FIG. 37. FIG. 41 is a structural layout diagram of a second conductive layer in FIG. 37. FIG. 42 is a structural layout diagram of a second active layer in FIG. 37. FIG. 43 is a structural layout diagram of a third conductive layer in FIG. 37. FIG. 44 is a structural layout diagram of a fourth conductive layer in FIG. 37. FIG. 45 is a structural layout diagram of a fifth conductive layer in FIG. 37. FIG. 46 is a structural layout diagram of the shielding layer and the first active layer in FIG. 37. FIG. 47 is a structural layout diagram of the shielding layer, the first active layer, and the first conductive layer in FIG. 37. FIG. 48 is a structural layout diagram of the shielding layer, the first active layer, the first conductive layer, and the second conductive layer in FIG. 37. FIG. 49 is a structural layout diagram of the shielding layer, the first active layer, the first conductive layer, the second conductive layer, and the second active layer in FIG. 37. FIG. 50 is a structural layout diagram of the shielding layer, the first active layer, the first conductive layer, the second conductive layer, the second active layer, and the third conductive layer in FIG. 37. FIG. 51 is a structural layout diagram of the shielding layer, the first active layer, the first conductive layer, the second conductive layer, the second active layer, the third conductive layer, and the fourth conductive layer in FIG. 37.

As shown in FIGS. 37 to 51, the orthographic projections of two adjacent pixel driving circuit rows PH in the same pixel driving circuit row group CP on the base substrate are at least partially arranged in mirror symmetry with respect to the first symmetry axis AA. The orthographic projections of two adjacent pixel driving circuits in the same pixel driving circuit row PH on the base substrate are at least partially arranged in mirror symmetry with respect to the second symmetry axis BB.

As shown in FIGS. 37, 38 and 46, the shielding layer may include a plurality of shielding portions 81. The plurality of shielding portions 81 are distributed in an array in the row direction X and the column direction Y. It should be understood that in other example embodiments, the display panel may not include the shielding layer.

As shown in FIGS. 37, 39, 46 and 47, the first active layer may include a first active portion 71, a third active portion 73, a fourth active portion 74, a fifth active portion 75, a sixth active portion 76, a seventh active portion 77, an eighth active portion 78, a ninth active portion 79, a tenth active portion 710, an eleventh active portion 711, a twelfth active portion 712, a thirteenth active portion 713, a fourteenth active portion 714, a fifteenth active portion 715, a sixteenth active portion 716, a seventeenth active portion 717, an eighteenth active portion 918, and a nineteenth active portion 719. The first active portion 71 is used to form a channel region of the first transistor T1. The third active portion 73 may be used to form a channel region of the driving transistor T3. The fourth active portion 74 may be used to form a channel region of the fourth transistor T4. The fifth active portion 75 may be used to form a channel region of the fifth transistor T5. The sixth active portion 76 may be used to form a channel region of the sixth transistor T6. The seventh active portion 77 may be used to form a channel region of the seventh transistor T7. The eighth active portion 78 may be used to form a channel region of the eighth transistor T8. The ninth active portion 79 is connected to an end of the first active portion 71 away from the third active portion 73, and in two adjacent pixel driving circuit rows sharing the same first initialization signal line Vinit1, the ninth active portion 79 is connected between two first active portions 71 in the two adjacent pixel driving circuit rows. The tenth active portion 710 is connected between the first active portion 71 and the third active portion 73. The eleventh active portion 711 is connected between the third active portion 73 and the fourth active portion 74. The twelfth active portion 712 is connected to an end of the fourth active portion 74 away from the third active portion 73. The thirteenth active portion 713 is connected to an end of the sixth active portion away from the seventh active portion 77. The fourteenth active portion 714 is connected between the sixth active portion 76 and the seventh active portion 77. The fifteenth active portion 715 is connected to an end of the seventh active portion 77 away from the sixth active portion 76. The sixteenth active portion 716 and the seventeenth active portion 717 are connected to both ends of the fifth active portion 75. The eighteenth active portion 718 and the nineteenth active portion 719 are connected to both ends of the eighth active portion 78. In an example embodiment, the first active layer may be formed of a polysilicon material, and accordingly, the first transistor T1, the driving transistor T3, the fourth transistor T4, the fifth transistor T5, the sixth transistor T6, the seventh transistor T7, and the eighth transistor T8 may be P-type low temperature polysilicon thin film transistors.

In an example embodiment, as shown in FIGS. 37, 39, 46 and 47, the third active portion 73 is “L”-shaped. It should be understood that in other example embodiments, the third active portion 73 may also be other shape, for example, the third active portion 73 can also be “π”-shaped, “I”-shaped, etc.

It should be noted that, in other example embodiments, shielding portions 81 adjacent to each other in the row direction X may be connected by a connection portion located in the shielding layer, and shielding portions 81 adjacent to each other in the column direction Y may be connected by a connection portion located in the shielding layer. This arrangement can form a grid structure of the shielding layer. The shielding layer may also be connected to a stable power supply terminal. For example, the shielding layer may be connected to a stable voltage terminal such as the first power supply terminal VDD, the first initialization signal terminal Vinit1, the second initialization signal terminal Vinit2, or the third initialization signal terminal Vinit3 in FIG. 1. The shielding portion 81 can shield the noise influence of other signal(s) on the driving transistor T3.

As shown in FIGS. 37, 40 and 47, the first conductive layer may include: a first conductive portion 11, a second gate line G2, an enable signal line EM, a first reset signal line Re1, and a second reset signal line Re2. The second gate line G2 may be used to provide the second gate driving signal terminal in FIG. 1. The enable signal line EM may be used to provide the enable signal terminal in FIG. 1. The first reset signal line Re1 may be used to provide the first reset signal terminal in FIG. 1. The second reset signal line Re2 may be used to provide the second reset signal terminal in FIG. 1. The orthographic projection of the second gate line G2 on the base substrate, the orthographic projection of the enable signal line EM on the base substrate, the orthographic projection of the first reset signal line Re1 on the base substrate, and the orthographic projection of the second reset signal line Re2 on the base substrate may all extend along the row direction X. The orthographic projection of the second gate line G2 on the base substrate covers the orthographic projection of the fourth active portion 74 on the base substrate, and a partial structure of the second gate line G2 is used to form the gate of the fourth transistor T4. The orthographic projection of the enable signal line EM on the base substrate covers the orthographic projection of the fifth active portion 75 on the base substrate and the orthographic projection of the sixth active portion 76 on the base substrate, and a partial structure of the enable signal line EM may be used to form the gates of the fifth transistor T5 and the sixth transistor T6, respectively. The orthographic projection of the first reset signal line Re1 on the base substrate may cover the orthographic projection of the first active portion 71 on the base substrate, and a partial structure of the first reset signal line Re1 is used to form the gate of the first transistor T1. The orthographic projection of the second reset signal line Re2 on the base substrate may cover the orthographic projection of the seventh active portion 77 on the base substrate and the orthographic projection of the eighth active portion 78 on the base substrate, and a partial structure of the second reset signal line Re2 may be used to form the gates of the seventh transistor T7 and the eighth transistor T8, respectively. The orthographic projection of the first conductive portion 11 on the base substrate covers the orthographic projection of the third active portion 73 on the base substrate, and the first conductive portion 11 may be used to form the gate of the driving transistor T3, and meanwhile the first conductive portion 11 may be reused as the first electrode of the capacitor C. In the same pixel driving circuit, the orthographic projection of the first conductive portion 11 on the base substrate is located between the orthographic projection of the first reset signal line Re1 on the base substrate and the orthographic projection of the second gate line G2 on the base substrate. The orthographic projection of the enable signal line EM on the base substrate is located at a side of the orthographic projection of the second gate line G2 on the base substrate away from the orthographic projection of the first conductive portion 11 on the base substrate. The orthographic projection of the second reset signal line Re2 on the base substrate is located at a side of the orthographic projection of the enable signal line EM on the base substrate away from the orthographic projection of the first conductive portion 11 on the base substrate. In the display panel, the first conductive layer may be used as a mask to perform a process on the first active layer to make a part of the first active layer behave like a conductor, that is, a region of the first active layer covered by the first conductive layer may form a channel region of a transistor, and a region of the first active layer not covered by the first conductive layer forms a conductor structure.

As shown in FIGS. 37, 41 and 48, the second conductive layer may include: a third gate line 2G1, a second conductive portion 22, and a third initialization signal line Vinit3. The orthographic projection of the third gate line 2G1 on the base substrate extends along the row direction X, and the third gate line 2G1 may be used to provide the first gate driving signal terminal in FIG. 1. The orthographic projection of the second conductive portion 22 on the base substrate may at least partially overlap with the orthographic projection of the first conductive portion 11 on the base substrate, and the second conductive portion 22 is used to form a second electrode of the capacitor C. The second conductive layer may also include a second connection portion 23. Second conductive portions 22 adjacent to each other in the row direction X may be connected by a second connection portion 23. The third initialization signal line Vinit3 may be used to provide the third initialization signal terminal Vinit3 in FIG. 1, and the orthographic projection of the third initialization signal line Vinit3 on the base substrate may extend along the row direction X. The orthographic projection of the third initialization signal line Vinit3 on the base substrate is located between the orthographic projection of a second reset signal line Re2 in the current row of pixel driving circuits on the base substrate and the orthographic projection of a second reset signal line Re2 in a next adjacent row of pixel driving circuits on the base substrate. This arrangement can reduce the parasitic capacitance between the third initialization signal line Vinit3 and the enable signal line EM, the second conductive portion 22 or other structure(s), thereby improving the display effect of the display panel.

As shown in FIGS. 37, 42 and 49, the second active layer may include an active portion 9. The active portion 9 may include: a second active portion 92, and a twentieth active portion 920 and a twenty-first active portion 921 connected to both ends of the second active portion 92. The second active portion 92 is used to form a channel region of the second transistor T2. The second active layer may be formed of indium gallium zinc oxide, and accordingly, the second transistor T2 may be an N-type metal oxide thin film transistor. The orthographic projection of the third gate line 2G1 on the base substrate may cover the orthographic projection of the second active portion 92 on the base substrate, and a partial structure of the third gate line 2G1 may be used to form the bottom gate of the second transistor T2. In addition, the twentieth active portion 920, the second active portion 92, and the twenty-first active portion 921 may be distributed in the row direction X.

As shown in FIGS. 37, 43 and 50, the third conductive layer may include a first bridging portion 31, a second bridging portion 32, a third bridging portion 33, a sixth bridging portion 36, a seventh bridging portion 37, a first gate line 3G1 and a second initialization signal line Vinit2. The orthographic projection of the first gate line 3G1 on the base substrate and the orthographic projection of the second initialization signal line Vinit2 on the base substrate may extend along the row direction X. The first gate line 3G1 may be used to provide the first gate driving signal terminal in FIG. 1. The first gate line 3G1 includes a third main body portion 3G13, and a fifth protrusion 3G15 connected to a side of the third main body portion 3G13 in the column direction. The orthographic projection of the third main body portion 3G13 on the base substrate extends along the row direction X. The orthographic projection of the fifth protrusion 3G15 on the base substrate covers the orthographic projection of the second active portion 92 on the base substrate, and a partial structure of the fifth protrusion 3G15 may be used to form a top gate of the second transistor T2. Also, the first gate line 3G1 may be connected to the third gate line 2G1 through a via hole located in the frame region of the display panel. The second initialization signal line Vinit2 may be used to provide the second initialization signal terminal in FIG. 1. As shown in FIGS. 4, 10 and 17, two adjacent pixel driving circuit rows PH in the same pixel driving circuit row group CP may share the same second initialization signal line Vinit2. The orthographic projection of the second initialization signal line Vinit2 on the base substrate is at least partially located between the orthographic projections of two adjacent third initialization signal lines Vinit3 in the same pixel driving circuit row group CP on the base substrate. This arrangement can reduce the parasitic battery between the third initialization signal line Vinit3 and the second initialization signal line Vinit2 by reducing the overlapping area between the third initialization signal line Vinit3 and the second initialization signal line Vinit2, thereby reducing the signal interference between the third initialization signal line Vinit3 and the second initialization signal line Vinit2. As shown in FIGS. 37, 43 and 50, the second initialization signal line Vinit2 may include a first main body portion Vinit21, a first protrusion Vinit221, and a second protrusion Vinit222. The first protrusion Vinit221 and the second protrusion Vinit222 are connected to two sides of the first main body portion Vinit21 in the column direction Y, respectively. The orthographic projection of the first main body portion Vinit21 on the base substrate may extend along the row direction X and may be located between the orthographic projections of two adjacent third initialization signal lines Vinit3 in the same pixel driving circuit row group CP on the base substrate. In the two pixel driving circuit rows sharing the same second initialization signal line Vinit2, the first main body portion Vinit21 is connected, through via holes, to the fifteenth active portions 715 in the two pixel driving circuit rows through the first protrusion Vinit221 and the second protrusion Vinit222.

As shown in FIGS. 37, 43 and 50, the first bridging portion 31 may include a main body portion 311 and an extension portion 31. The main body portion 311 is connected to the gate of the driving transistor T3 and the first electrode of the second transistor T2 through via holes, respectively. The orthographic projection of the extension portion 312 on the base substrate at least partially overlaps with the orthographic projection of the second conductive portion 22 on the base substrate. The main body portion includes a first side 3111, and the extension portion 312 includes a second side 3122, and the first side 3111 is connected with the second side 3122. An angle between the orthographic projection of the first side 3111 on the base substrate and the orthographic projection of the second side 3122 on the base substrate is smaller than 180°. For example, the angle between the orthographic projection of the first side 3111 on the base substrate and the orthographic projection of the second side 3122 on the base substrate may be equal to 80°, 90°, 95°, etc. This arrangement can increase the capacitance value of the capacitor C, so that the node N in the pixel driving circuit has a relatively stable voltage value, thereby improving the stability of the brightness of the light-emitting unit within a frame period.

As shown in FIGS. 37, 43 and 50, the first bridging portion 31 may be connected to the twentieth active portion 720 and the first conductive portion 11 through via holes, respectively, to connect the first electrode of the second transistor T2 and the gate of the driving transistor T3. The second bridging portion 32 may be connected to the twenty-first active portion 721, the tenth active portion 710, and the thirteenth active portion 713 through via holes, respectively, to connect the second electrode of the second transistor T2, the second electrode of the first transistor T1, and the first electrode of the sixth transistor T6. The third bridging portion 33 may be connected to the eleventh active portion 711, the sixteenth active portion 716, and the eighteenth active portion 718 through via holes, respectively, to connect the second electrode of the fourth transistor T4, the second electrode of the eighth transistor T8, the second electrode of the fifth transistor T5, and the first electrode of the driving transistor T3. The sixth bridging portion 36 may be connected to the nineteenth active portion 719 and the third initialization signal line Vinit3 through via holes respectively to connect the first electrode of the eighth transistor T8 and the third initialization signal terminal. The seventh bridging portion 37 may be connected to the fourteenth active portion 714 through a via hole to connect the second electrode of the sixth transistor T6 and the second electrode of the seventh transistor T7.

In addition, in the display panel, the third conductive layer may be used as a mask to perform a process on the second active layer to make a part of the second active layer behave like a conductor, that is, a region of the second active layer covered by the third conductive layer may form a channel region of a transistor, and a region of the second active layer not covered by the third conductive layer forms a conductor structure.

As shown in FIGS. 37, 44 and 51, the fourth conductive layer may include a fourth bridging portion 44, a fifth bridging portion 45, a ninth bridging portion 49, a twelfth bridging portion 412, a first initialization signal line Vinit1, a first fan-out line FIPH, a second gate connection line 4G2, and a first gate connection line 4G1. The fourth bridging portion 44 may be connected to the twelfth active portion 712 through a via hole to connect the first electrode of the fourth transistor T4. The fifth bridging portion 45 may be connected to the seventeenth active portion 717 through a via hole to connect the first electrode of the fifth transistor. The ninth bridging portion 49 may be connected to the second conductive portion 22 through a via hole. The twelfth bridging portion 412 may be connected to the seventh bridging portion 37 through a via hole.

The first initialization signal line Vinit1 may be used to provide the first initialization signal terminal in FIG. 1, and the orthographic projection of the first initialization signal line Vinit1 on the base substrate extends along the row direction X. And in the same pixel driving circuit, the orthographic projection of the first initialization signal line Vinit1 on the base substrate is located at a side of the orthographic projection of the first reset signal line Re1 on the base substrate away from the orthographic projection of the first conductive portion 11 on the base substrate. This arrangement can reduce the parasitic capacitance between the first initialization signal line Vinit1 and the enable signal line EM, the first reset signal line Re1 or other alternating current signal line(s), thereby improving the voltage stability of the first initialization signal line Vinit1. An alternating current signal line is a signal line that outputs an alternating current signal.

In an example embodiment, as shown in FIGS. 37, 44 and 51, two pixel driving circuit rows PH, which are adjacent and are located in different pixel driving circuit row groups CP, share the same first initialization signal line Vinit1. This arrangement can also reduce the number of lines and via holes in the display panel, thereby improving the manufacturing yield of the display panel.

As shown in FIGS. 37, 44 and 51, the orthographic projection of the first fan-out line FIPH on the base substrate may extend along the row direction X, and the first fan-out line FIPH may be used as a row direction fan-out line connecting a data line in the FIP (Fanout In Pixel, fan-out region in a pixel).

As shown in FIGS. 37, 44 and 51, the orthographic projection of the first gate connection line 4G1 on the base substrate may extend along the row direction X, and the first gate connection line 4G1 may be connected to the first gate line 3G1 through a via hole. The orthographic projection of the second gate connection line 4G2 on the base substrate may extend along the row direction X, and the second gate connection line 4G2 may be connected to the second gate line G2 through a via hole. In an example embodiment, the square resistance of the fourth conductive layer may be smaller than the square resistance of the first conductive layer, the second conductive layer, and the third conductive layer. In an example embodiment, the first gate connection line 4G1 and the second gate connection line 4G2 are arranged in the fourth conductive layer, and this arrangement can greatly reduce the resistance of the first gate line 3G1 and the second gate line G2, thereby improving the response speed of a corresponding transistor.

As shown in FIGS. 37 and 45, the fifth conductive layer may include a tenth bridging portion 510, a data line Da, a first power supply line VDD, and a second fan-out line FIPV. The orthographic projection of the data line Da on the base substrate, the orthographic projection of the first power supply line VDD on the base substrate, and the orthographic projection of the second fan-out line FIPV on the base substrate may all extend along the column direction Y. The data line Da is used to provide the data signal terminal in FIG. 1, and the first power supply line VDD is used to provide the first power supply terminal in FIG. 1. The data line Da may be connected to the fourth bridging portion 44 through a via hole to connect the data signal terminal and the first electrode of the fourth transistor T4. There may be multiple first power supply lines VDD, and the orthographic projections of the multiple first power supply lines VDD on the base substrate extend along the column direction Y and are spaced apart along the row direction X. A first power supply line VDD may be connected, through a via hole, to a ninth bridging portion 49 whose orthographic projection on the base substrate intersects with the orthographic projection of the first power supply line VDD on the base substrate. The first power supply line(s) VDD and the second conductive portion(s) 22 connected in the row direction X may form a grid structure, and this arrangement can reduce the voltage difference on the first power supply line(s) at different positions of the display panel, thereby improving the display uniformity of the display panel. In addition, the first power supply line VDD may also be connected to the fifth bridging portion 45 through a via hole to connect the first power supply terminal and the first electrode of the fifth transistor T5.

The second fan-out line FIPV may be used as a column direction fan-out line connecting a data line in FIP (Fanout In Pixel, fan-out region in a pixel). The first fan-out line and the second fan-out line may also be provided in a non-fan-out region of the display panel. In the non-fan-out region, the second fan-out line FIPV may be connected, through a via hole, to a first fan-out line FIPH whose orthographic projection on the base substrate intersects with the orthographic projection of the second fan-out line FIPV on the base substrate. The first fan-out line(s) FIPH and the second fan-out line(s) FIPV may form a grid structure, and the grid structure may be connected to a common electrode layer in the display panel through a via hole, and the common electrode layer may be used as the second electrode of the light-emitting unit. This arrangement can reduce the resistance of the common electrode layer, thereby reducing the voltage difference of the common electrode layer at different positions of the display panel, and thus improving the display uniformity of the display panel.

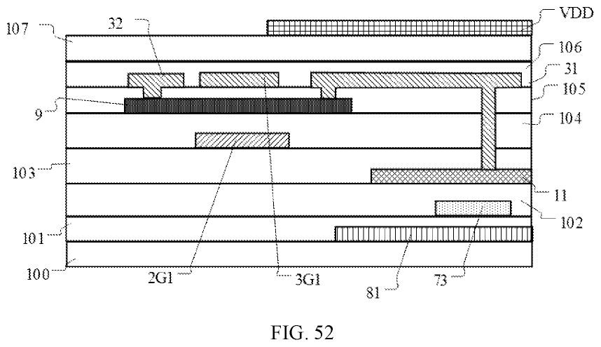

The tenth bridging portion 510 may be connected to the twelfth bridging portion 412 through a via hole to connect the second electrode of the sixth transistor T6 and the second electrode of the seventh transistor T7. The tenth bridging portion 510 may also be connected to a pixel electrode in the pixel electrode layer through a via hole. The pixel electrode layer may be located at a side of the fifth conductive layer away from the base substrate. The pixel electrode may be used to form a first electrode of the light-emitting unit. As shown in FIG. 52, it is a partial cross-sectional view of the display panel shown in FIG. 37 taken along a dotted line CC. The display panel may also include a first insulating layer 101, a second insulating layer 102, a third insulating layer 103, a fourth insulating layer 104, a fifth insulating layer 105, a first dielectric layer 106, and a first planarization layer 108. The base substrate 100, the shielding layer, the first insulating layer 101, the first active layer, the second insulating layer 102, the first conductive layer, the third insulating layer 103, the second conductive layer, the fourth insulating layer 104, the second active layer, the fifth insulating layer 105, the third conductive layer, the first dielectric layer 106, the fourth conductive layer, the first planarization layer 108, and the fifth conductive layer are stacked in sequence. The first insulating layer 101, the second insulating layer 102, the third insulating layer 103, the fourth insulating layer 104, and the fifth insulating layer 105 may be a single-layer structure or a multi-layer structure, and the materials of the first insulating layer 101, the second insulating layer 102, the third insulating layer 103, the fourth insulating layer 104, and the fifth insulating layer 105 may be at least one of silicon nitride, silicon oxide, or silicon oxynitride. The first dielectric layer 106 may be a silicon nitride layer. The material of the first planarization layer 108 may be an organic material, such as polyimide (PI), polyethylene terephthalate (PET), polyethylene naphthalate (PEN), silicon-glass bonding structure (SOG, silicon on glass) and the like. The base substrate 100 may include a glass substrate, a blocking layer, and a polyimide layer stacked in sequence, and the blocking layer may be an inorganic material. The materials of the first conductive layer, the second conductive layer, and the third conductive layer may be one of molybdenum, aluminum, copper, titanium, or niobium, or an alloy, or a conductive layer such as a molybdenum/titanium alloy or laminated molybdenum/titanium. The material of the fourth conductive layer and the fifth conductive layer may include a metal material, for example, one of molybdenum, aluminum, copper, titanium, niobium or an alloy, or a molybdenum/titanium alloy or laminated molybdenum/titanium, or a conductive layer such as laminated titanium/aluminum/titanium. The square resistance of any one of the fourth conductive layer and the fifth conductive layer may be smaller than the square resistance of any one of the first conductive layer, the second conductive layer, and the third conductive layer.

In addition, the display panel may further include a pixel electrode layer located at a side of the fifth conductive layer away from the base substrate, a light-emitting unit layer located at a side of the pixel electrode layer away from the base substrate, and a common electrode layer located at a side of the light-emitting unit layer away from the base substrate.

It should be understood that in other example embodiments, the pixel driving circuit Pix in the display panel shown in FIG. 3 and FIG. 20 may also be other structure(s). For example, the pixel driving circuit Pix may not include the eighth transistor T8. For another example, one or more of the first transistor T1, the fourth transistor T4, the fifth transistor T5, the sixth transistor T6, the seventh transistor T7, and the eighth transistor T8 may be N-type transistor(s), and the second transistor T2 may also be a P-type transistor. For another example, the second electrode of the first transistor T1 may be directly connected to the node N.

It should be noted that, as shown in FIGS. 4, 18, 21, 35, 37 and 51, the black square drawn at a side of the fourth conductive layer away from the base substrate indicate via holes connecting the fourth conductive layer to other layers at a side facing the base substrate; the black square drawn at a side of the fifth conductive layer away from the base substrate indicates via holes connecting the fifth conductive layer to other layers at a side facing the base substrate. Different via holes represented by black squares at different positions may run through different insulating layers.

In addition, in the display panels shown in FIGS. 4, 21 and 37, when one or more of the first transistor T1, the fourth transistor T4, the fifth transistor T5, the sixth transistor T6, the seventh transistor T7, and the eighth transistor T8 are N-type transistors, the channel regions of the N-type transistors may be located in the second active layer, the bottom gates of the N-type transistors may be located in the second conductive layer, and the top gates of the N-type transistors may be located in the third conductive layer. When the second transistor T2 is a P-type transistor, the channel region of the second transistor T2 may be located in the first active layer, and the gate of the second transistor may be located in the first conductive layer.

In the display panels shown in FIGS. 4, 21 and 37, in the same pixel driving circuit, the first active portion 71 and the third active portion 73 may be connected in the same layer. This arrangement can reduce the number of via holes and bridging portions and improve the stability of the connection between the first active portion 71 and the third active portion 73.

In the display panels shown in FIGS. 4, 21 and 37, the first initialization signal line Vinit1, the second initialization signal line Vinit2 and the third initialization signal line Vinit3 may also be located in other conductive layers. For example, the first initialization signal line Vinit1 may also be located in the second conductive layer or the third conductive layer, the second initialization signal line Vinit2 may also be located in the second conductive layer or the fourth conductive layer, and the third initialization signal line Vinit3 may also be located in the third conductive layer or the fourth conductive layer.

The scales of the drawings in the present disclosure may be used as a reference in the actual processes, but the present disclosure is not limited to the scales. For example, the width-to-length ratio of a channel, the thickness and spacing of respective film layers, and the width and spacing of respective signal lines may be adjusted according to actual needs. The number of pixels in the display substrate and the number of sub-pixels in each pixel are not limited to the numbers shown in the drawings. The drawings described in the present disclosure are only structural schematic diagrams. In addition, qualifiers such as first and second are only used to define different structural names, and they do not mean a specific order. The same structural layer may be formed by the same patterning process. In an example embodiment, the orthographic projection of a certain structure on the base substrate extends in a certain direction, which can be understood as: the orthographic projection of the structure on the base substrate extends in a straight line or extends in a bent manner along this direction.

An example embodiment also provides a display device. The display device includes the above described display panel. The display device may be a display device such as a mobile phone, a tablet computer, a television, etc.

Those skilled in the art will readily appreciate other embodiments of the present disclosure after considering the specification and practicing what is disclosed herein. The present disclosure is intended to cover any variations, uses, or adaptations of the present disclosure that follow the general principles of the present disclosure and include common knowledge or customary technical means in the art that are not disclosed in the present disclosure. The specification and embodiments are to be considered merely as illustrative, and the true scope and spirit of the present disclosure are indicated by the claims.

Those skilled in the art will readily appreciate other embodiments of the present disclosure after considering the specification and practicing what is disclosed herein. The present disclosure is intended to cover any variations, uses, or adaptations of the present disclosure that follow the general principles of the present disclosure and include common knowledge or customary technical means in the art that are not disclosed in the present disclosure. The specification and embodiments are to be considered merely as illustrative, and the true scope and spirit of the present disclosure are indicated by the claims.

It should be understood that the present disclosure is not limited to the exact structures that have been described above and shown in the drawings, and that various modifications and changes may be made without departing from the scope of the present disclosure. The scope of the present disclosure is limited only by the appended claims.

What is claimed is:

1. A display panel, comprising:
a base substrate;
at least one pixel driving circuit row group, wherein one of the at least one pixel driving circuit row group comprises two pixel driving circuit rows which are adjacent in a column direction, and one of the two pixel driving circuit rows comprises a plurality of pixel driving circuits distributed in a row direction;
light-emitting units, wherein one of the pixel driving circuits is used to drive a corresponding light-emitting unit in the light-emitting units, the one of pixel driving circuits comprises a seventh transistor, a first electrode of the seventh transistor is connected to a second initialization signal line, a second electrode of the seventh transistor is connected to a first electrode of the corresponding light-emitting unit, a gate of the seventh transistor is formed by a partial structure of a second reset signal line, and an orthographic projection of the second reset signal line on the base substrate extends along the row direction;
wherein orthographic projections of two pixel driving circuit rows which are adjacent in a same pixel driving circuit row group on the base substrate are at least partially arranged in mirror symmetry with respect to a first symmetry axis, the first symmetry axis extends along the row direction, and the two pixel driving circuit rows which are adjacent in the same pixel driving circuit row group share a same second initialization signal line.

2. The display panel according to claim 1, wherein the second initialization signal line forms the first symmetry axis, and the orthographic projections of the two pixel driving circuit rows which are adjacent in the same pixel driving circuit row group on the base substrate are at least partially arranged in mirror symmetry with respect to the second initialization signal line.

3. The display panel according to claim 1, wherein the one of the pixel driving circuits further comprises a driving transistor and a fifth transistor, a first electrode of the fifth transistor is connected to a first power supply line, and a second electrode of the fifth transistor is connected to a first electrode of the driving transistor;
wherein the display panel further comprises:
a first conductive portion, wherein the first conductive portion is used to form a gate of the driving transistor;
an enable signal line, wherein an orthographic projection of the enable signal line on the base substrate extends along the row direction, and a partial structure of the enable signal line is used to form a gate of the fifth transistor;
wherein in a same pixel driving circuit, an orthographic projection of the second reset signal line on the base substrate is located at a side of the orthographic projection of the enable signal line on the base substrate away from an orthographic projection of the first conductive portion on the base substrate;
wherein the orthographic projection of the second initialization signal line on the base substrate is at least partially located between two adjacent second reset signal lines in a same pixel driving circuit row group.

4. The display panel according to claim 1, wherein the second initialization signal line comprises:
a first main body portion, wherein an orthographic projection of the first main body portion on the base substrate extends along the row direction;
a first protrusion; and
a second protrusion, wherein the first protrusion and the second protrusion are connected to two sides of the first main body portion in the column direction, respectively;
wherein in two pixel driving circuit rows which share a same second initialization signal line, the first main body portion is connected to the two pixel driving circuit rows through the first protrusion and the second protrusion, respectively.

5. The display panel according to claim 1, wherein the one of the pixel driving circuits further comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer located at a side of the base substrate, wherein the first active layer comprises a third active portion, and the third active portion is used to form a channel region of the driving transistor;
a first conductive layer located at a side of the first active layer away from the base substrate, wherein the first conductive layer comprises a first conductive portion, an orthographic projection of the first conductive portion on the base substrate covers an orthographic projection of the third active portion on the base substrate, and the first conductive portion is used to form the gate of the driving transistor;
a second active layer located at a side of the first conductive layer away from the base substrate, wherein the second active layer comprises a second active portion, and the second active portion is used to form a channel region of the second transistor;
a third conductive layer located at a side of the second active layer away from the base substrate, wherein the third conductive layer comprises a first gate line, an orthographic projection of the first gate line on the base substrate extends along the row direction and covers an orthographic projection of the second active portion on the base substrate, and a partial structure of the first gate line is used to form a top gate of the second transistor;
wherein the third conductive layer further comprises the second initialization signal line.

6. The display panel according to claim 1, wherein the one of the pixel driving circuits further comprises a driving transistor and a first transistor, a first electrode of the first transistor is connected to a first initialization signal line, and a second electrode of the first transistor is connected to a second electrode of the driving transistor;
wherein the at least one pixel driving circuit row group comprises a plurality of pixel driving circuit row groups, the plurality of pixel driving circuit row groups are distributed in the column direction, and two pixel driving circuit rows, which are located in different pixel driving circuit row groups and are adjacent, share a same first initialization signal line.

7. The display panel according to claim 6, further comprising:
a first conductive portion, wherein the first conductive portion is used to form a gate of the driving transistor;
a first reset signal line, wherein an orthographic projection of the first reset signal line on the base substrate extends along the row direction, and a partial structure of the first reset signal line is used to form a gate of the first transistor;
wherein the orthographic projection of the first reset signal line on the base substrate is located at a side of an orthographic projection of the first conductive portion on the base substrate away from the orthographic projection of the second reset signal line on the base substrate;
wherein in two adjacent pixel driving circuit rows which share a same first initialization signal line, an orthographic projection of the first initialization signal line on the base substrate is at least partially located between orthographic projections of first reset signal lines in the two adjacent pixel driving circuit rows on the base substrate.

8. The display panel according to claim 7, further comprising:
a first active layer located at a side of the base substrate, wherein the first active layer comprising a first active portion and a ninth active portion, the first active portion is used to form a channel region of the first transistor, and in the two adjacent pixel driving circuit rows which share the same first initialization signal line, the ninth active portion is connected between two first active portions in the two adjacent pixel driving circuit rows;
wherein the first initialization signal line is connected to the ninth active portion through a via hole.

9. The display panel according to claim 6, wherein the one of the pixel driving circuits further comprises a second transistor, a first electrode of the second transistor is connected to a gate of the driving transistor, and a second electrode of the second transistor is connected to the second electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor;
a third conductive layer located at a side of the second active layer away from the base substrate, wherein at least a partial structure of the third conductive layer is used to form a top gate of the second transistor; and
a fourth conductive layer located at a side of the third conductive layer away from the base substrate, wherein the fourth conductive layer comprises the first initialization signal line; or wherein the one of the pixel driving circuits further comprises a driving transistor and an eighth transistor, a first electrode of the eighth transistor is connected to a third initialization signal line, and a second electrode of the eighth transistor is connected to a first electrode of the driving transistor;
wherein two pixel driving circuit rows which are adjacent in the same pixel driving circuit row group share a same third initialization signal line.

10. (canceled)

11. The display panel according to claim 9, wherein the third initialization signal line comprises:
a second main body portion, wherein an orthographic projection of the second main body portion on the base substrate extends along the row direction;
a third protrusion; and
a fourth protrusion, wherein the third protrusion and the fourth protrusion are connected to two sides of the second main body portion in the column direction, respectively;
wherein in two pixel driving circuit rows that share the same third initialization signal line, the second main body portion is connected to the two pixel driving circuit rows through the third protrusion and the fourth protrusion, respectively.

12. The display panel according to claim 9, wherein an orthographic projection of the third initialization signal line on the base substrate at least partially overlaps with an orthographic projection of the second initialization signal line on the base substrate; or
wherein the one of the pixel driving circuits further comprises a second transistor, a first electrode of the second transistor is connected to a gate of the driving transistor, and a second electrode of the second transistor is connected to a second electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer comprises the third initialization signal line.

13. (canceled)

14. The display panel according to claim 1, wherein the one of the pixel driving circuits further comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer further comprises a first bridging portion, and the first bridging portion is connected to the gate of the driving transistor and the first electrode of the second transistor through via holes.

15. The display panel according to claim 14, wherein the one of the pixel driving circuits further comprises a capacitor, a first electrode of the capacitor is connected to the gate of the driving transistor, and a second electrode of the capacitor is connected to the first power supply line;
wherein the first conductive layer comprises a first conductive portion, and the first conductive portion is used to form the gate of the driving transistor, and the first conductive portion is reused as the first electrode of the capacitor;
wherein the display panel further comprises:
a second conductive layer between the third conductive layer and the first conductive layer, wherein the second conductive layer comprises a second conductive portion, an orthographic projection of the second conductive portion on the base substrate at least partially overlaps with an orthographic projection of the first conductive portion on the base substrate, and the second conductive portion is used to form the second electrode of the capacitor;
wherein the first bridging portion comprises a main body portion and an extension portion, the main body portion is connected to the gate of the driving transistor and the first electrode of the second transistor through via holes, and an orthographic projection of the extension portion on the base substrate at least partially overlaps with the orthographic projection of the second conductive portion on the base substrate;
wherein the main body portion comprises a first side, the extension comprises a second side, the first side is connected to the second side, and an angle between an orthographic projection of the first side on the base substrate and an orthographic projection of the second side on the base substrate is less than 180°.

16. The display panel according to claim 1, wherein the one of the pixel driving circuits further comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor;
wherein the third conductive layer further comprises a second bridging portion, and the second bridging portion is connected to the second electrode of the second transistor and the second electrode of the driving transistor through via holes; or wherein the pixel driving circuit further comprises a driving transistor, a second transistor, a fifth transistor and an eighth transistor, wherein a first electrode of the second transistor is connected to a gate of the driving transistor, a second electrode of the second transistor is connected to a second electrode of the driving transistor, a first electrode of the fifth transistor is connected to the first power supply line, a second electrode of the fifth transistor is connected to a first electrode of the driving transistor, a first electrode of the eighth transistor is connected to a third initialization signal line, and a second electrode of the eighth transistor is connected to the first electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein the third conductive layer comprises a first gate line, and a partial structure of the first gate line is used to form a top gate of the second transistor;
wherein the third conductive layer further comprises a third bridging portion, and the third bridging portion is connected to the first electrode of the driving transistor, the second electrode of the fifth transistor, and the second electrode of the eighth transistor through via holes, respectively.

17. (canceled)

18. The display panel according to claim 1, wherein the one of the pixel driving circuits further comprises a driving transistor and a second transistor, a first electrode of the second transistor is connected to a gate of the driving transistor, and a second electrode of the second transistor is connected to a second electrode of the driving transistor;
wherein the display panel further comprises:
a third conductive layer located at a side of the base substrate, wherein the third conductive layer comprises a first gate line, and a partial structure of the first gate line is used to form a top gate of the second transistor;
a fourth conductive layer located at a side of the third conductive layer away from the base substrate, wherein the fourth conductive layer comprises a first gate connection line, an orthographic projection of the first gate connection line on the base substrate extends along the row direction, and the first gate connection line is connected to the first gate line through one or more via holes; or
wherein the one of the pixel driving circuits further comprises a driving transistor, a second transistor and a fourth transistor, a first electrode of the second transistor is connected to a gate of the driving transistor, a second electrode of the second transistor is connected to a second electrode of the driving transistor, a first electrode of the fourth transistor is connected to a data line, and a second electrode of the fourth transistor is connected to a first electrode of the driving transistor;
wherein the display panel further comprises:
a first active layer located at a side of the base substrate, wherein the first active layer comprises a fourth active portion, and the fourth active portion is used to form a channel region of the fourth transistor;
a first conductive layer located at a side of the first active layer away from the base substrate, wherein the first conductive layer comprises a second gate line, an orthographic projection of the second gate line on the base substrate covers an orthographic projection of the fourth active portion on the base substrate, and a partial structure of the second gate line is used to form a gate of the fourth transistor;
a second active layer located at a side of the first conductive layer away from the base substrate, wherein a partial structure of the second active layer is used to form a channel region of the second transistor;
a third conductive layer located at a side of the second active layer away from the base substrate, wherein a partial structure of the third conductive layer is used to form a top gate of the second transistor; and
a fourth conductive layer located at a side of the third conductive layer away from the base substrate, wherein the fourth conductive layer comprises a second gate connection line, an orthographic projection of the second gate connection line on the base substrate extends along the row direction, and the second gate connection line is connected to the second gate line through one or more via holes.

19. (canceled)

20. The display panel according to claim 1, wherein the one of the pixel driving circuits further comprises a driving transistor and a second transistor, a first electrode of the second transistor is connected to a gate of the driving transistor, and a second electrode of the second transistor is connected to a second electrode of the driving transistor;
wherein the display panel further comprises:
a first active layer located at a side of the base substrate, wherein at least a partial structure of the first active layer is used to form a channel region of the driving transistor;
a first conductive layer located at a side of the first active layer away from the base substrate, wherein at least a partial structure of the first conductive layer is used to form the gate of the driving transistor;
a second active layer located at a side of the first conductive layer away from the base substrate, wherein the second active layer comprises a second active portion, and a twentieth active portion and a twenty-first active portion connected to two ends of the second active portion in the row direction, the second active portion is used to form a channel region of the second transistor, the twentieth active portion is used to form the first electrode of the second transistor, and the twenty-first active portion is used to form the second electrode of the second transistor; and
a third conductive layer located at a side of the second active layer away from the base substrate, wherein the third conductive layer comprises a first gate line, the first gate line comprises a third main body portion and a fifth protrusion connected to a side of the third main body portion in the column direction, an orthographic projection of the third main body portion on the base substrate extends along the row direction, and an orthographic projection of the fifth protrusion on the base substrate covers an orthographic projection of the second active portion on the base substrate; or wherein the one of the pixel driving circuits further comprises a driving transistor, a fourth transistor and a fifth transistor, a first electrode of the fifth transistor is connected to the first power supply line, a second electrode of the fifth transistor is connected to a first electrode of the driving transistor, a first electrode of the fourth transistor is connected to a data line, and a second electrode of the fourth transistor is connected to the first electrode of the driving transistor;
wherein the display panel further comprises:
a first active layer comprising a third active portion, a fourth active portion and a fifth active portion, wherein the third active portion is used to form a channel region of the driving transistor, the fourth active portion is used to form a channel region of the fourth transistor, and the fifth active portion is used to form a channel region of the fifth transistor;
a first conductive layer located at a side of the first active layer away from the base substrate, wherein the first conductive layer comprises a first conductive portion, a second gate line and an enable signal line, an orthographic projection of the second gate line on the base substrate extends along the row direction and covers an orthographic projection of the fourth active portion on the base substrate, a partial structure of the second gate line is used to form a gate of the fourth transistor, an orthographic projection of the enable signal line on the base substrate extends along the row direction and covers an orthographic projection of the fifth active portion on the base substrate, and a partial structure of the enable signal line is used to form a gate of the fifth transistor;
wherein in a same pixel driving circuit, an orthographic projection of the second gate line on the base substrate is located between an orthographic projection of the first conductive portion on the base substrate and the orthographic projection of the enable signal line on the base substrate.

21. (canceled)

22. The display panel according to claim 1, wherein the one of the pixel driving circuits further comprises a driving transistor and a first transistor, a first electrode of the first transistor is connected to the first initialization signal line, and a second electrode of the first transistor is connected to a second electrode of the driving transistor;
wherein the display panel further comprises:
a first active layer located at a side of the base substrate, wherein the first active layer comprises a third active portion and a first active portion, the third active portion is used to form a channel region of the driving transistor, and the first active portion is used to form a channel region of the first transistor;
wherein in a same pixel driving circuit, the first active portion and the third active portion are connected in a same layer; or wherein orthographic projections of two adjacent pixel driving circuits in a same pixel driving circuit row on the base substrate are at least partially arranged in mirror symmetry with respect to a second symmetry axis, and the second symmetry axis extends along the column direction.

23. (canceled)

24. The display panel according to claim 1, wherein the one of the pixel driving circuits further comprises:
a driving transistor;
a first transistor, wherein a first electrode of the first transistor is connected to a first initialization signal line, and a second electrode of the first transistor is connected to a second electrode of the driving transistor;
a second transistor, wherein a first electrode of the second transistor is connected to a gate of the driving transistor, and a second electrode of the second transistor is connected to a second electrode of the driving transistor;
a fourth transistor, wherein a first electrode of the fourth transistor is connected to a data line, and a second electrode of the fourth transistor is connected to a first electrode of the driving transistor;
a fifth transistor, wherein a first electrode of the fifth transistor is connected to the first power supply line, and a second electrode of the fifth transistor is connected to the first electrode of the driving transistor;
a sixth transistor, wherein a first electrode of the sixth transistor is connected to the second electrode of the driving transistor, and a second electrode of the sixth transistor is connected to a first electrode of the corresponding light-emitting unit;
an eighth transistor, wherein a first electrode of the eighth transistor is connected to a third initialization signal line, and a second electrode of the eighth transistor is connected to the first electrode of the driving transistor;
a capacitor, wherein a first electrode of the capacitor is connected to the gate of the driving transistor, and a second electrode of the capacitor is connected to the first power supply line;
wherein the first transistor, the driving transistor, the fourth transistor, the fifth transistor, the sixth transistor, the seventh transistor and the eighth transistor are P-type transistors, and the second transistor is an N-type transistor.

25. The display panel according to claim 24, further comprising:
a first active layer located at a side of the base substrate, wherein at least a partial structure of the first active layer is used to form channel regions of the first transistor, the driving transistor, the fourth transistor, the fifth transistor, the sixth transistor, the seventh transistor, and the eighth transistor;
a first conductive layer located at a side of the first active layer away from the base substrate, wherein at least a partial structure of the first conductive layer is used to form gates of the first transistor, the driving transistor, the fourth transistor, the fifth transistor, the sixth transistor, the seventh transistor, and the eighth transistor;
a second active layer located at a side of the first conductive layer away from the base substrate, wherein at least a partial structure of the second active layer is used to form a channel region of the second transistor; and
a third conductive layer located at a side of the second active layer away from the base substrate, wherein at least a partial structure of the third conductive layer is used to form a top gate of the second transistor.

26. A display device, wherein the display device comprises display 25a display panel;
wherein the display panel comprises:
a base substrate;
at least one pixel driving circuit row group, wherein one of the at least one pixel driving circuit row group comprises two pixel driving circuit rows which are adjacent in a column direction, and one of the two pixel driving circuit rows comprises a plurality of pixel driving circuits distributed in a row direction;
light-emitting units, wherein one of the pixel driving circuits is used to drive a corresponding light-emitting unit in the light-emitting units, the one of pixel driving circuits comprises a seventh transistor, a first electrode of the seventh transistor is connected to a second initialization signal line, a second electrode of the seventh transistor is connected to a first electrode of the corresponding light-emitting unit, a gate of the seventh transistor is formed by a partial structure of a second reset signal line, and an orthographic projection of the second reset signal line on the base substrate extends along the row direction;
wherein orthographic projections of two pixel driving circuit rows which are adjacent in a same pixel driving circuit row group on the base substrate are at least partially arranged in mirror symmetry with respect to a first symmetry axis, the first symmetry axis extends along the row direction, and the two pixel driving circuit rows which are adjacent in the same pixel driving circuit row group share a same second initialization signal line.
